(19) United States
(12) Patent Application Publication
(10) Pub. No.: US 2025/0268100 A1
(43) Pub. Date: Aug. 21, 2025

(54) LIGHT-EMITTING ELEMENT AND DISPLAY DEVICE INCLUDING THE SAME

(71) Applicant: Samsung Display Co., Ltd., Yongin-si (KR)

(72) Inventors: BEOMJIN KIM, Yongin-si (KR); EUN JEONG JANG, Yongin-si (KR); JUNGMIN MOON, Yongin-si (KR); HYE JEONG PARK, Yongin-si (KR); GYEONGHEON KIM, Yongin-si (KR); YOUNGTAK LEE, Yongin-si (KR)

(21) Appl. No.: 18/943,584

(22) Filed: Nov. 11, 2024

(30) Foreign Application Priority Data
Feb. 15, 2024 (KR) 10-2024-0021935

(51) Int. Cl. H10K 85/60; H10K 50/15; H10K 50/858

(52) U.S. Cl. CPC H10K 85/633; H10K 50/156; H10K 50/858; H10K 85/624; H10K 85/626

(57) ABSTRACT

Provided is a light-emitting element including a first electrode, a hole transport region on the first electrode, a light-emitting layer on the hole transport region, an electron transport region on the light-emitting layer, and a second electrode on the electron transport region. The hole transport region includes a first hole transport layer between the first electrode and the light-emitting layer, and including a first compound represented by Chemical Formula 1, and a second compound different from the first compound, and represented by Chemical Formula 2-1 and Chemical Formula 2-2, and a second hole transport layer between the first hole transport layer and the light-emitting layer, and including the second compound, thereby improving luminous efficiency and element lifespan of the light-emitting element.

### CROSS-REFERENCE TO RELATED APPLICATION

The present application claims priority to and the benefit of Korean Patent Application No. 10-2024-0021935, filed on Feb. 15, 2024, in the Korean Intellectual Property Office, the entire content of which is hereby incorporated by reference.

### BACKGROUND

### 1. Field

Embodiments of the present disclosure herein relate to a light-emitting element and a display device including the same, and for example, to a light-emitting element having improved luminous efficiency and element lifespan, and a display device including the same.

### 2. Description of the Related Art

Recently, development of an organic electroluminescence display device as an image display device has been actively carried out. Unlike a liquid crystal display device, the organic electroluminescence display device is a so-called self-luminous display device that performs displaying by recombining, in a light-emitting layer, holes and electrons injected from a first electrode and a second electrode, and emitting light from a light-emitting material, including an organic compound, of the light-emitting layer.

When a light-emitting element is applied for the display device, high luminous efficiency and long lifespan of the light-emitting element are desired or required, and in order to stably realize such requirements, development of a material and a structure of the light-emitting element is continuously being investigated.

### SUMMARY

Embodiments of the present disclosure provide a light-emitting element having improved luminous efficiency and element lifespan.

Embodiments of the present disclosure also provide a display device including a light-emitting element having improved luminous efficiency and element lifespan.

An embodiment of the present disclosure provides a light-emitting element including a first electrode, a hole transport region on the first electrode, a light-emitting layer on the hole transport region, an electron transport region on the light-emitting layer, and a second electrode on the electron transport region, wherein the hole transport region includes a first hole transport layer between the first electrode and the light-emitting layer, and including a first compound represented by Chemical Formula 1 below, and a second compound different from the first compound, and represented by Chemical Formula 2-1 or Chemical Formula 2-2 below, and a second hole transport layer between the first hole transport layer and the light-emitting layer, and including the second compound.

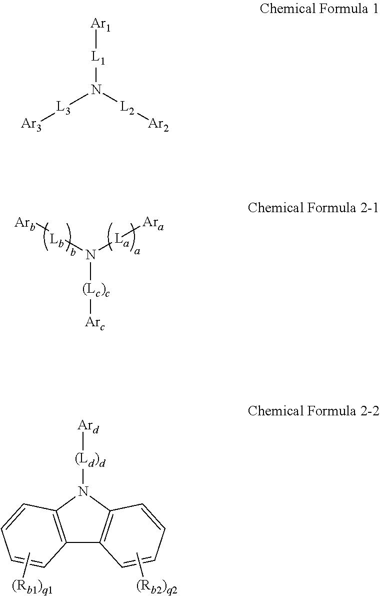

In Chemical Formula 1, Chemical Formula 2-1, and Chemical Formula 2-2 above, Ar₁ to Ar₃, and Arₐ to Ar_{c} are each independently a substituted or unsubstituted amine group, a substituted or unsubstituted aryl group having a ring-forming carbon number of 6 to 30, or a substituted or unsubstituted heteroaryl group having a ring-forming carbon number of 2 to 30, Ar_{d} is a substituted or unsubstituted aryl group having a ring-forming carbon number of 6 to 30, or a substituted or unsubstituted heteroaryl group having a ring-forming carbon number of 2 to 30, R_{b1} and R_{b2} are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or bonded to an adjacent group to form a ring, q1 and q2 are each independently an integer of 0 to 4, L₁ to L₃, and Lₐ to L_{d} are each independently a direct linkage (e.g., a covalent bond), a substituted or unsubstituted arylene group having a ring-forming carbon number of 6 to 30, or a substituted or unsubstituted heteroarylene group having a ring-forming carbon number of 2 to 30, a to d are each independently an integer of 0 to 10, in Chemical Formula 1, at least one among L₁ to L₃ is a phenylene group represented by Chemical Formula A-1 below, or Chemical Formula A-2 below, or a substituted or unsubstituted divalent naphthyl group, or at least one among Ar₁ to Ar₃ is substituted for (e.g., is or is substituted with) a substituted or unsubstituted cycloalkyl group having a carbon number of 3 to 20.

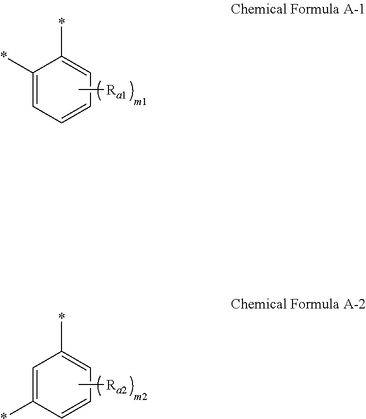

In Chemical Formula A-1 and Chemical Formula A-2 above, Rₐ₁ and Rₐ₂ are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and m1 and m2 are each independently an integer of 0 to 4.

In an embodiment, the first compound may have a first refractive index, and the second compound may have a second refractive index greater than the first refractive index.

In an embodiment, the first refractive index may be about 1.20 to about 1.85 at a wavelength of about 460 nm, and the second refractive index may be about 1.90 to about 2.50 at a wavelength of about 460 nm.

In an embodiment, a difference between the first refractive index and the second refractive index may be greater than about 0.1.

In an embodiment, the first hole transport layer may be directly on the first electrode.

In an embodiment, the first electrode may be a reflective electrode, and the second electrode may be a transmissive electrode or a semi-transmissive electrode.

In an embodiment, in the first hole transport layer, a content (e.g., amount) of the first compound may be equal to or more than about 10% by weight of the total weight of the first compound and the second compound.

In an embodiment, the first hole transport layer may include the first compound and the second compound.

In an embodiment, an absolute value of a difference between a HOMO energy level of the first compound and a HOMO energy level of the second compound may be equal to or less than about 0.5 eV.

In an embodiment, the first compound may be represented by Chemical Formula 1-1 or Chemical Formula 1-2 below.

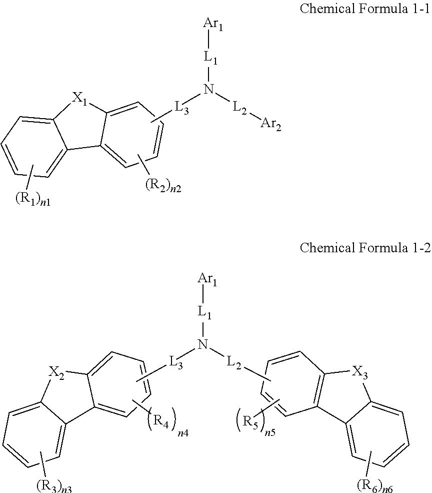

In Chemical Formula 1-1 and Chemical Formula 1-2 above, X₁ to X₃ are each independently CR₇R₈, NR₉, O, S, or Se, R₁ to R₉ are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, or bonded to an adjacent group to form a ring, n1, n3, and n6 are each independently an integer of 0 to 4, and n2, n4, and n5 are each independently an integer of 0 to 3.

In Chemical Formula 1-1 and Chemical Formula 1-2 above, Ar₁, Ar₂, and L₁ to L₃ are the same as what is defined with respect to Chemical Formula 1 above.

In an embodiment, the first compound may be represented by any one among Chemical Formula 1-4 to Chemical Formula 1-6 below.

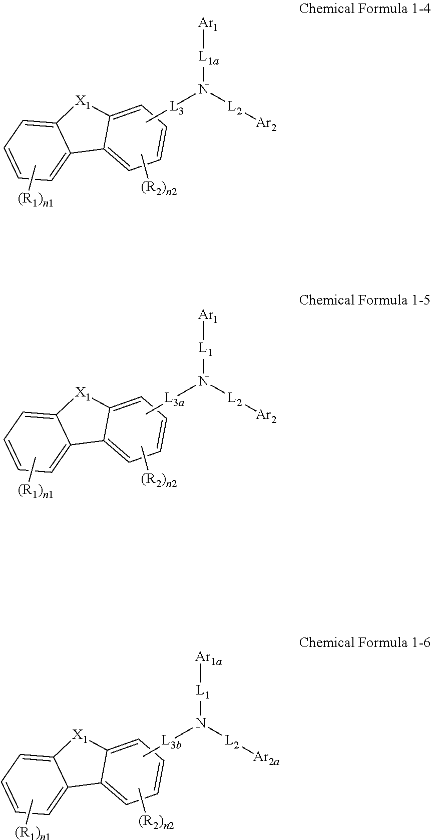

In Chemical Formula 1-4 to Chemical Formula 1-6 above, X₁ is CR₇R₈, NR₉, O, S, or Se, R₁, R₂, and R₇ to R₉ are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, or bonded to an adjacent group to form a ring, L₁ₐ and L₃ₐ are each independently represented by Chemical Formula A-1 above, L₃b is a saturated or unsaturated arylene group having a ring-forming carbon number of 6 to 30, or a saturated or unsaturated heteroarylene group having a ring-forming carbon number of 2 to 30, Ar₁ₐ and Ar₂ₐ are each independently a saturated or unsaturated aryl group having a ring-forming carbon number of 6 to 30, or a saturated or unsaturated heteroaryl group having a ring-forming carbon number of 2 to 30, at least one among Ar₁ₐ and Ar₂ₐ is substituted for (e.g., is or is substituted with) a saturated or unsaturated cyclohexyl group, a saturated or unsaturated bicycloheptyl group, or a saturated or unsaturated adamantyl group, n1 is an integer of 0 to 4, and n2 is an integer of 0 to 3.

In Chemical Formula 1-4 to Chemical Formula 1-6 above, Ar₁, Ar₂, and L₁ to L₃ are the same as what is defined with respect to Chemical Formula 1 above.

In an embodiment, in Chemical Formula 1 above, Ar₁ may be represented by Chemical Formula B-1 below, L₁ may be a direct linkage (e.g., a covalent bond), L₂ and L₃ may be each independently a saturated or unsaturated phenylene group, and at least one among L₂ and L₃ may be represented by Chemical Formula A-1 above.

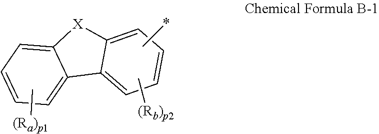

In Chemical Formula B-1 above, Rₐ and R_{b} are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, p1 is an integer of 0 to 4, and p2 is an integer of 0 to 3.

In an embodiment, in Chemical Formula 1 above, Ar₁ to Ar₃ may be each independently a saturated or unsaturated arylamine group, a saturated or unsaturated phenyl group, a saturated or unsaturated biphenyl group, a saturated or unsaturated naphthyl group, or a saturated or unsaturated fluorenyl group, and at least one among Ar₁ to Ar₃ may be substituted for (e.g., may be or may be substituted with) a saturated or unsaturated cyclohexyl group.

In an embodiment of the present disclosure, a light-emitting element includes a first electrode, a first hole transport layer on the first electrode, a second hole transport layer on the first hole transport layer, a light-emitting layer on the second hole transport layer, an electron transport region on the light-emitting layer, and a second electrode on the electron transport region, wherein the first hole transport layer includes a first compound having a first refractive index, and a second compound different from the first compound, and having a second refractive index greater than the first refractive index, the second hole transport layer includes the second compound, the first refractive index is about 1.50 to about 1.85 at a wavelength of about 460 nm, and the second refractive index is about 1.90 to about 2.50 at a wavelength of about 460 nm.

In an embodiment, the first compound may include a core nitrogen atom, a first substituent, a second substituent, and a third substituent, each of the first substituent, the second substituent, and the third substituent being connected to the core nitrogen atom, the first substituent to the third substituent may be each independently a saturated or unsaturated aryl group having a ring-forming carbon number of 6 to 30, or a saturated or unsaturated heteroaryl group having a ring-forming carbon number of 2 to 30, at least one among the first substituent to the third substituent may be substituted for (e.g., may be or may be substituted with) a saturated or unsaturated cycloalkyl group having a carbon number of 3 to 20, or may be connected to the core nitrogen atom through a first linker, and the first linker may be a phenylene group represented by Chemical Formula A-1 or Chemical Formula A-2 below, or a saturated or unsaturated naphthylene group.

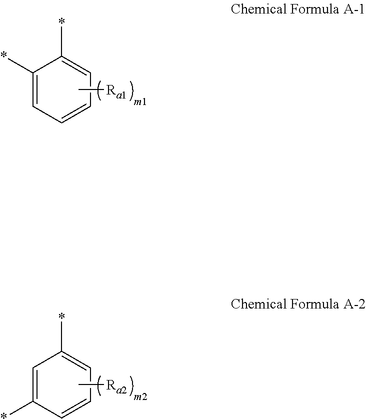

In Chemical Formula A-1 and Chemical Formula A-2 above, Rₐ₁ and Rₐ₂ are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, and m1 and m2 are each independently an integer of 0 to 4.

In an embodiment, the first substituent may be directly bonded to the core nitrogen atom, at least one among the second substituent or the third substituent may be connected to the core nitrogen atom through the first linker, and the first linker may be represented by Chemical Formula A-1 above.

In an embodiment, the first compound may include, in a molecular structure thereof, 1 to 5 of at least one substituent selected from a saturated or unsaturated cyclohexyl group, a saturated or unsaturated bicyclohexyl group, and a saturated or unsaturated adamantyl group.

In an embodiment of the present disclosure, a display device includes a base layer including a plurality of light-emitting regions, and a non-light-emitting region adjacent to the plurality of light-emitting regions, and a plurality of light-emitting elements on the base layer, and respectively corresponding to the plurality of light-emitting regions, wherein at least some of the plurality of light-emitting elements includes a first electrode, a hole transport region on the first electrode, a light-emitting layer on the hole transport region, an electron transport region on the light-emitting layer, and a second electrode on the electron transport region, the hole transport region includes a first hole transport layer between the first electrode and the light-emitting layer, and including a first compound represented by Chemical Formula 1 above, and a second compound different from the first compound and represented by Chemical Formula 2-1 or Chemical Formula 2-2 above, and a second hole transport layer between the first hole transport layer and the light-emitting layer, and including the second compound.

### BRIEF DESCRIPTION OF THE DRAWINGS

The accompanying drawings are included to provide a further understanding of the subject matter of the present disclosure, and are incorporated in and constitute a part of this specification. The drawings illustrate embodiments of the present disclosure and, together with the description, serve to explain principles of the subject matter of the present disclosure. In the drawings:

FIG. 1 is a plan view of a display device according to an embodiment of the present disclosure;

FIG. 2 is a cross-sectional view of a display device according to an embodiment of the present disclosure;

FIG. 3 is a cross-sectional view schematically illustrating a light-emitting element according to an embodiment of the present disclosure;

FIG. 4 is a cross-sectional view schematically illustrating a light-emitting element according to an embodiment of the present disclosure;

FIG. 5 is a cross-sectional view schematically illustrating a light-emitting element according to an embodiment of the present disclosure;

FIG. 6 is a cross-sectional view schematically illustrating a light-emitting element according to an embodiment of the present disclosure;

FIG. 7 is a cross-sectional view schematically illustrating a light-emitting element according to an embodiment of the present disclosure;

FIGS. 8-9 are cross-sectional views of a display device according to an embodiment of the present disclosure, respectively;

FIG. 10 is a cross-sectional view illustrating a display device according to an embodiment of the present disclosure;

FIG. 11 is a cross-sectional view illustrating a display device according to an embodiment of the present disclosure; and

FIG. 12 is a diagram illustrating a vehicle in which a display device according to an embodiment is provided.

### DETAILED DESCRIPTION

The subject matter of the present disclosure may be modified in various suitable manners and have many forms, and thus example embodiments will be illustrated in the drawings and described in more detail in the detailed description of the present disclosure. It should be understood, however, that it is not intended to limit the present disclosure to the particular forms disclosed, but rather, is intended to cover all modifications, equivalents, and alternatives falling within the spirit and scope of the present disclosure.

When explaining each of drawings, like reference numbers are used for referring to like elements. In the accompanying drawings, the dimensions of each structure may be exaggeratingly illustrated for clarity of the present disclosure. It will be understood that, although the terms “first,” “second,” etc., may be used herein to describe various components, these components should not be limited by these terms. These terms are only used to distinguish one component from another. For example, a first component could be termed a second component, and, similarly, a second component could be termed a first component, without departing from the scope of example embodiments of the present disclosure. As used herein, the singular forms, “a,” “an,” and “the” are intended to include the plural forms as well, unless the context clearly indicates otherwise.

In the present disclosure, it will be understood that the terms “include,” “have” or the like specify the presence of features, numbers, steps, operations, component, parts, or combinations thereof disclosed in the specification, but do not exclude the possibility of presence or addition of one or more other features, numbers, steps, operations, component, parts, or combinations thereof.

In the present disclosure, when a layer, a film, a region, or a plate is referred to as being “on” or “in an upper portion of” another layer, film, region, or plate, it may be not only “directly on” the layer, film, region, or plate, but intervening layers, films, regions, and/or plates may also be present. In embodiments, when a layer, a film, a region, or a plate is referred to as being “below”, “in a lower portion of” another layer, film, region, or plate, it can be not only directly under the layer, film, region, or plate, but intervening layers, films, regions, and/or plates may also be present. In embodiments, it will be understood that when a part is referred to as being “on” another part, it can be above the other part, or under the other part as well.

In the specification, the term “substituted or unsubstituted” may mean substituted or unsubstituted with at least one substituent selected from the group consisting of a deuterium atom, a halogen atom, a cyano group, a nitro group, an amino group, a silyl group, an oxy group, a thio group, a sulfinyl group, a sulfonyl group, a carbonyl group, a boron group, a phosphine oxide group, a phosphine sulfide group, an alkyl group, an alkenyl group, an alkynyl group, a hydrocarbon ring group, an aryl group, and a heterocyclic group. In embodiments, each of the substituents exemplified above may be substituted or unsubstituted. For example, a biphenyl group may be interpreted as an aryl group or a phenyl group substituted with a phenyl group.

In the specification, the phrase “bonded to an adjacent group to form a ring” may mean that a group is bonded to an adjacent group to form a substituted or unsubstituted hydrocarbon ring, or a substituted or unsubstituted heterocycle. The hydrocarbon ring includes an aliphatic hydrocarbon ring and an aromatic hydrocarbon ring. The heterocycle includes an aliphatic heterocycle and an aromatic heterocycle. The hydrocarbon ring and the heterocycle may be monocyclic or polycyclic. In embodiments, the rings formed by being bonded to each other may be connected to another ring to form a spiro structure.

In the specification, the term “adjacent group” may mean a substituent substituted for (e.g., that is or is substituted with) an atom which is directly linked to an atom substituted with a corresponding substituent, another substituent substituted for (e.g., that is or is substituted with) an atom which is substituted with a corresponding substituent, or a substituent sterically provided at the nearest position to a corresponding substituent. For example, two methyl groups in 1,2-dimethylbenzene may be interpreted as “adjacent groups” to each other and two ethyl groups in 1,1-diethylcyclopentane may be interpreted as “adjacent groups” to each other. In embodiments, two methyl groups in 4,5-dimethylphenanthrene may be interpreted as “adjacent groups” to each other.

In the specification, examples of the halogen atom may include a fluorine atom, a chlorine atom, a bromine atom, and/or an iodine atom.

In the specification, the alkyl group may be linear, branched, or cyclic alkyl group. The number of carbons in the alkyl group is 1 to 50, 1 to 30, 1 to 20, 1 to 10, or 1 to 6. Examples of the alkyl group may include a methyl group, an ethyl group, an n-propyl group, an isopropyl group, a cyclopropyl group, an n-butyl group, an s-butyl group, a t-butyl group, an i-butyl group, a 2-ethylbutyl group, a 3,3-dimethylbutyl group, a cyclobutyl group, an n-pentyl group, an i-pentyl group, a neopentyl group, a t-pentyl group, a cyclopentyl group, a 1-methylpentyl group, a 3-methylpentyl group, a 2-ethylpentyl group, a 4-methyl-2-pentyl group, an n-hexyl group, a 1-methylhexyl group, a 2-ethylhexyl group, a 2-butylhexyl group, a cyclohexyl group, a 4-methylcyclohexyl group, a 4-t-butylcyclohexyl group, an n-heptyl group, a 1-methylheptyl group, a 2,2-dimethylheptyl group, a 2-ethylheptyl group, a 2-butylheptyl group, a cycloheptyl group, an n-octyl group, a t-octyl group, a 2-ethyloctyl group, a 2-butyloctyl group, a 2-hexyloctyl group, a 3,7-dimethyloctyl group, a cyclooctyl group, an n-nonyl group, a cyclononyl group, an n-decyl group, a cyclodecyl group, a norbornyl group, a 1-adamantyl group, a 2-adamantyl group, a 2-ethyldecyl group, a 2-butyldecyl group, a 2-hexyldecyl group, a 2-octyldecyl group, an n-undecyl group, an n-dodecyl group, a 2-ethyldodecyl group, a 2-butyldodecyl group, a 2-hexyldocecyl group, a 2-octyldodecyl group, an n-tridecyl group, an n-tetradecyl group, an n-pentadecyl group, an n-hexadecyl group, a 2-ethylhexadecyl group, a 2-butylhexadecyl group, a 2-hexylhexadecyl group, a 2-octylhexadecyl group, an n-heptadecyl group, an n-octadecyl group, an n-nonadecyl group, an n-eicosyl group, a 2-ethyleicosyl group, a 2-butyleicosyl group, a 2-hexyleicosyl group, a 2-octyleicosyl group, an n-henicosyl group, an n-docosyl group, an n-tricosyl group, an n-tetracosyl group, an n-pentacosyl group, an n-hexacosyl group, an n-heptacosyl group, an n-octacosyl group, an n-nonacosyl group, an n-triacontyl group, an isobornyl group, a bicycloheptyl group etc., but an embodiment of the present disclosure is not limited thereto.

In the specification, an alkenyl group means a hydrocarbon group including at least one carbon double bond in a main chain (e.g., the middle) or a terminal end (e.g., the terminus) of an alkyl group having 2 or more carbon atoms. The alkenyl group may be linear or branched. The number of carbon atoms in the alkenyl group is not specifically limited, but is 2 to 30, 2 to 20, or 2 to 10. Examples of the alkenyl group include a vinyl group, a 1-butenyl group, a 1-pentenyl group, a 1,3-butadienyl aryl group, a styrenyl group, a styryl vinyl group, etc., but an embodiment of the present disclosure is not limited thereto.

In the specification, an alkynyl group means a hydrocarbon group including at least one carbon triple bond in a main chain (e.g., the middle) or a terminal end (e.g., the terminus) of an alkyl group having 2 or more carbon atoms. The alkynyl group may be linear or branched. Although the number of carbon atoms is not specifically limited, it may be 2 to 30, 2 to 20, or 2 to 10. Examples of the alkynyl group may include an ethynyl group, a propynyl group, etc., but are not limited thereto.

In the specification, the hydrocarbon ring group means any suitable functional group or substituent derived from an aliphatic hydrocarbon ring. The hydrocarbon ring group may be a saturated hydrocarbon ring group having 5 to 20 ring-forming carbon atoms.

In the specification, an aryl group means any suitable functional group or substituent derived from an aromatic hydrocarbon ring. The aryl group may be a monocyclic aryl group or a polycyclic aryl group. The number of ring-forming carbon atoms in the aryl group may be 6 to 60, 6 to 50, 6 to 40, 6 to 30, 6 to 20, or 6 to 15. Examples of the aryl group may include a phenyl group, a naphthyl group, a fluorenyl group, an anthracenyl group, a phenanthryl group, a biphenyl group, a terphenyl group, a quaterphenyl group, a quinquephenyl group, a sexiphenyl group, a triphenylenyl group, a pyrenyl group, a benzofluoranthenyl group, a chrysenyl group, etc., but an embodiment of the present disclosure is not limited thereto.

In the specification, the fluorenyl group may be substituted, and two substituents may be bonded to each other to form a spiro structure. Examples of the substituted fluorenyl group are as follows. However, an embodiment of the present disclosure is not limited thereto.

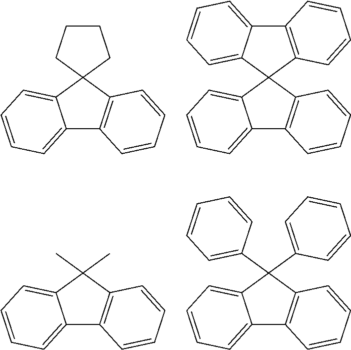

The heterocyclic group herein means any suitable functional group or substituent derived from a ring containing at least one of B, O, N, P, Si, or Se as a heteroatom. The heterocyclic group includes an aliphatic heterocyclic group and an aromatic heterocyclic group. The aromatic heterocyclic group may be a heteroaryl group. The aliphatic heterocycle and the aromatic heterocycle may be monocyclic or polycyclic.

In the specification, the heterocyclic group may contain at least one of B, O, N, P, Si or S as a heteroatom. If the heterocyclic group contains two or more heteroatoms, the two or more heteroatoms may be the same as or different from each other. The heterocyclic group may be a monocyclic heterocyclic group or a polycyclic heterocyclic group, and includes a heteroaryl group. The number of ring-forming carbon atoms in the heterocyclic group may be 2 to 60, 2 to 50, 2 to 40, 2 to 30, 2 to 20, or 2 to 10.

In the specification, the aliphatic heterocyclic group may include at least one of B, O, N, P, Si, or S as a heteroatom. The number of ring-forming carbon atoms in the aliphatic heterocyclic group may be 2 to 30, 2 to 20, or 2 to 10. Examples of the aliphatic heterocyclic group may include an oxirane group, a thiirane group, a pyrrolidine group, a piperidine group, a tetrahydrofuran group, a tetrahydrothiophene group, a thiane group, a tetrahydropyran group, a 1,4-dioxane group, etc., but an embodiment of the present disclosure is not limited thereto.

In the specification, the heteroaryl group may contain at least one of B, O, N, P, Si, or S as a heteroatom. If the heteroaryl group contains two or more heteroatoms, the two or more heteroatoms may be the same as or different from each other. The heteroaryl group may be a monocyclic heterocyclic group or a polycyclic heterocyclic group. The number of ring-forming carbon atoms in the heteroaryl group may be 2 to 60, 2 to 50, 2 to 40, 2 to 30, 2 to 20, or 2 to 10. Examples of the heteroaryl group may include a thiophene group, a furan group, a pyrrole group, an imidazole group, a pyridine group, a bipyridine group, a pyrimidine group, a triazine group, a triazole group, an acridyl group, a pyridazine group, a pyrazinyl group, a quinoline group, a quinazoline group, a quinoxaline group, a phenoxazine group, a phthalazine group, a pyrido pyrimidine group, a pyrido pyrazine group, a pyrazino pyrazine group, an isoquinoline group, an indole group, a carbazole group, an N-arylcarbazole group, an N-heteroarylcarbazole group, an N-alkylcarbazole group, a benzoxazole group, a benzoimidazole group, a benzothiazole group, a benzocarbazole group, a benzothiophene group, a dibenzothiophene group, a thienothiophene group, a benzofuran group, a phenanthroline group, a thiazole group, an isoxazole group, an oxazole group, an oxadiazole group, a thiadiazole group, a phenothiazine group, a dibenzosilole group, a dibenzofuran group, etc., but an embodiment of the present disclosure is not limited thereto.

In the specification, the above description of the aryl group may be applied to an arylene group except that the arylene group is a divalent group. The above description of the heteroaryl group may be applied to a heteroarylene group except that the heteroarylene group is a divalent group.

In the specification, the silyl group includes an alkylsilyl group and an arylsilyl group. Examples of the silyl group may include a trimethylsilyl group, a triethylsilyl group, a t-butyldimethylsilyl group, a vinyldimethylsilyl group, a propyldimethylsilyl group, a triphenylsilyl group, a diphenylsilyl group, a phenylsilyl group, etc., but an embodiment of the present disclosure is not limited thereto.

In the specification, the number of carbon atoms in the acyl group is not particularly limited, but may be 1 to 40, 1 to 30, 1 to 20, or 1 to 10. Examples of the acyl group may include acetyl, ethylcarbonyl, isopropylcarbonyl, naphthylenecarbonyl, cyclopentylcarbonyl, cyclohexylcarbonyl, phenylcarbonyl, etc., but an embodiment of the present disclosure is not limited thereto. For example, the acyl group may have the following structure, but an embodiment of the present disclosure is not limited thereto.

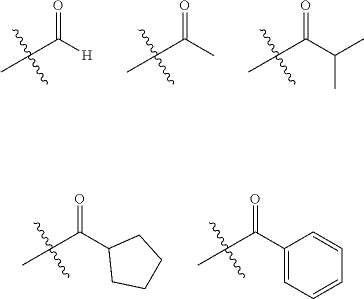

In the specification, the number of carbon atoms in the sulfinyl group and the sulfonyl group is not particularly limited, but may be 1 to 30. The sulfinyl group may include an alkyl sulfinyl group and/or an aryl sulfinyl group. The sulfonyl group may include an alkyl sulfonyl group and/or an aryl sulfonyl group.

In the specification, the thio group may include an alkylthio group and/or an arylthio group. The thio group may mean that a sulfur atom is bonded to the alkyl group and/or the aryl group as defined above. Examples of the thio group may include a methylthio group, an ethylthio group, a propylthio group, a pentylthio group, a hexylthio group, an octylthio group, a dodecylthio group, a cyclopentylthio group, a cyclohexylthio group, a phenylthio group, a naphthylthio group, but an embodiment of the present disclosure is not limited thereto.

In the specification, an oxy group may mean that an oxygen atom is bonded to the alkyl group and/or the aryl group as defined above. The oxy group may include an alkoxy group and/or an aryl oxy group. The alkoxy group may be a linear chain, a branched chain and/or a ring chain. The number of carbon atoms in the alkoxy group is not specifically limited, but may be, for example, 1 to 20 or 1 to 10. Examples of the oxy group may include methoxy, ethoxy, n-propoxy, isopropoxy, butoxy, pentyloxy, hexyloxy, octyloxy, nonyloxy, decyloxy, benzyloxy, etc., but an embodiment of the present disclosure is not limited thereto.

The boron group herein may mean that a boron atom is bonded to the alkyl group and/or the aryl group as defined above. The boron group includes an alkyl boron group and/or an aryl boron group. Examples of the boron group may include a dimethylboron group, a trimethylboron group, a t-butyldimethylboron group, a diphenylboron group, a phenylboron group, etc., but an embodiment of the present disclosure is not limited thereto.

In the specification, the number of carbon atoms in an amine group is not specifically limited, but may be 1 to 30. The amine group may include an alkyl amine group and an aryl amine group. Examples of the amine group may include a methylamine group, a dimethylamine group, a phenylamine group, a diphenylamine group, a naphthylamine group, a 9-methyl-anthracenylamine group, etc., but an embodiment of the present disclosure is not limited thereto.

In the specification, the alkyl group among an alkylthio group, an alkylsulfoxy group, an alkylaryl group, an alkylamino group, an alkyl boron group, an alkyl silyl group, and an alkyl amine group is the same as the examples of the alkyl group described above.

In the specification, the aryl group among an aryloxy group, an arylthio group, an arylsulfoxy group, an arylamino group, an arylboron group, an arylsilyl group, an arylamine group is the same as the examples of the aryl group described above.

In the specification, the carbazole group may be substituted, and adjacent substituents may be bonded to each other to form a condensed ring structure. For example, the carbazole group may be substituted, and two adjacent substituents may be bonded to each other to form a condensed ring structure as the following structure. However, an embodiment of the present disclosure is not limited thereto.

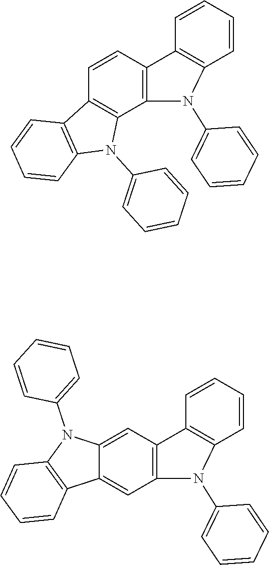 [SMILES: c1ccc(-n2c3ccccc3c3ccc4c5ccccc5n(-c5ccccc5)c4c32)cc1 ; c1ccc(-n2c3ccccc3c3cc4c(cc32)c2ccccc2n4-c2ccccc2)cc1]

In the specification, a direct linkage may mean a single bond (e.g., a single covalent bond).

In the specification, “ [symbol] ” and “ [symbol] ” mean a position to be connected.

Hereinafter, embodiments of the present disclosure will be described with reference to the accompanying drawings.

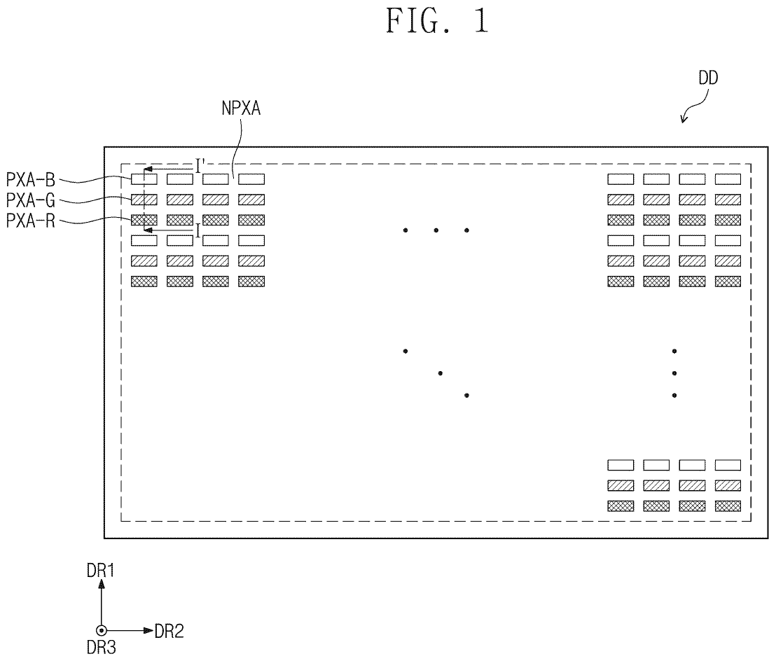

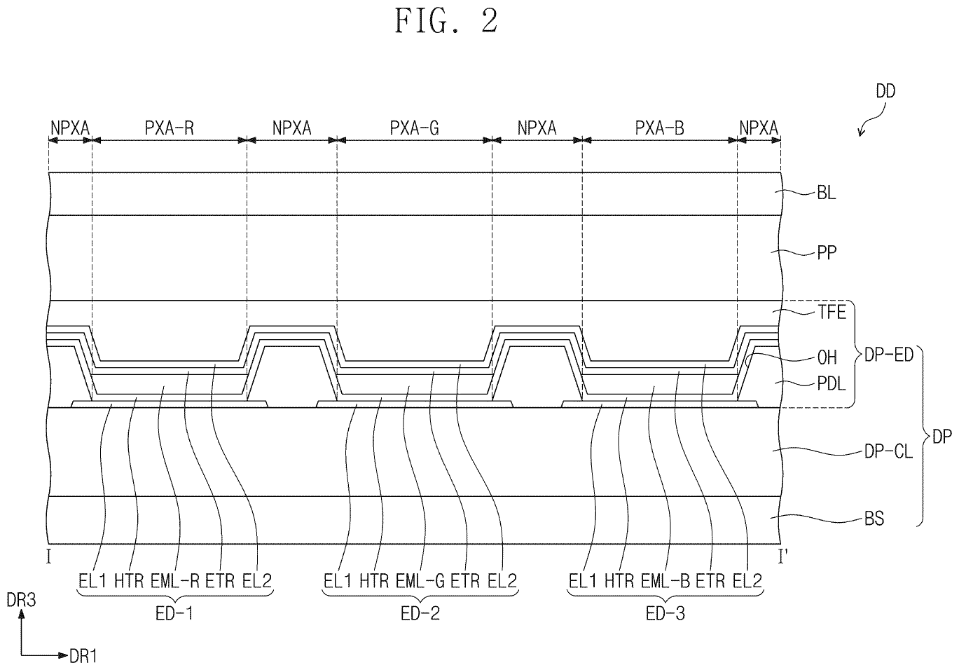

FIG. 1 is a plan view illustrating an embodiment of a display device DD. FIG. 2 is a cross-sectional view of the display device DD of an embodiment. FIG. 2 is a cross-sectional view illustrating a part taken along line I-I′ of FIG. 1.

The display device DD may include a display panel DP and an optical layer PP on the display panel DP. The display panel DP includes light emitting elements ED-1, ED-2, and ED-3. The display device DD may include a plurality of light emitting elements ED-1, ED-2, and ED-3. The optical layer PP may be on the display panel DP to control reflected light in the display panel DP due to external light. The optical layer PP may include, for example, a polarization layer and/or a color filter layer. Unlike the configuration illustrated in the drawing, the optical layer PP may be omitted from the display device DD of an embodiment.

A base substrate BL may be on the optical layer PP. The base substrate BL may be a member which provides a base surface on which the optical layer PP is provided. The base substrate BL may be a glass substrate, a metal substrate, a plastic substrate, etc. However, an embodiment of the present disclosure is not limited thereto, and the base substrate BL may be an inorganic layer, an organic layer, or a composite material layer (e.g., including an inorganic material and an organic material). In embodiments, unlike the configuration illustrated, the base substrate BL may be omitted.

The display device DD according to an embodiment may further include a filling layer. The filling layer may be between a display device layer DP-ED and the base substrate BL. The filling layer may be an organic material layer. The filling layer may include at least one of an acrylic-based resin, a silicone-based resin, or an epoxy-based resin.

The display panel DP may include a base layer BS, a circuit layer DP-CL provided on the base layer BS, and the display device layer DP-ED. The display device layer DP-ED may include a pixel defining film PDL, the light emitting elements ED-1, ED-2, and ED-3 between portions of the pixel defining film PDL, and an encapsulation layer TFE on the light emitting elements ED-1, ED-2, and ED-3.

The base layer BS may be a member which provides a base surface on which the display device layer DP-ED is provided. The base layer BS may be a glass substrate, a metal substrate, a plastic substrate, etc. However, an embodiment is not limited thereto, and the base layer BS may be an inorganic layer, an organic layer, or a composite material layer (e.g., including an inorganic material and an organic material).

In an embodiment, the circuit layer DP-CL is on the base layer BS, and the circuit layer DP-CL may include a plurality of transistors. Each of the transistors may include a control electrode, an input electrode, and an output electrode. For example, the circuit layer DP-CL may include a switching transistor and a driving transistor that drives the light emitting elements ED-1, ED-2, and ED-3 of the display device layer DP-ED.

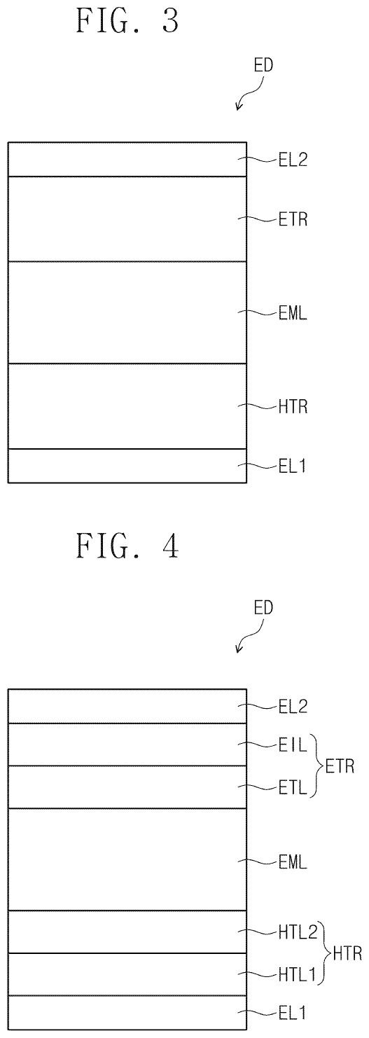

Each of the light emitting elements ED-1, ED-2, and ED-3 may have a structure of each light emitting element ED of embodiments according to FIGS. 3-6, which will be further described below. Each of the light emitting elements ED-1, ED-2, and ED-3 may include a first electrode EL1, a hole transport region HTR, light-emitting layers EML-R, EML-G, and EML-B, an electron transport region ETR, and a second electrode EL2.

FIG. 2 illustrates an embodiment in which the light-emitting layers EML-R, EML-G, and EML-B of the light emitting elements ED-1, ED-2, and ED-3 are provided in openings OH defined in the pixel defining film PDL, and the hole transport region HTR, the electron transport region ETR, and the second electrode EL2 are provided as a common layer in the entire light emitting elements ED-1, ED-2, and ED-3. However, an embodiment of the present disclosure is not limited thereto, and unlike the configuration illustrated in FIG. 2, the hole transport region HTR and the electron transport region ETR in an embodiment may be provided by being patterned inside the openings OH defined in the pixel defining film PDL. For example, the hole transport region HTR, the light-emitting layers EML-R, EML-G, and EML-B, and the electron transport region ETR of the light emitting elements ED-1, ED-2, and ED-3 in an embodiment may be provided by being patterned in an inkjet printing method.

The encapsulation layer TFE may cover the light emitting elements ED-1, ED-2 and ED-3. The encapsulation layer TFE may seal the display device layer DP-ED. The encapsulation layer TFE may be a thin film encapsulation layer. The encapsulation layer TFE may be formed by laminating one layer or a plurality of layers. The encapsulation layer TFE includes at least one insulation layer (e.g., at least one electrical insulation layer). The encapsulation layer TFE according to an embodiment may include at least one inorganic film (hereinafter, an encapsulation-inorganic film). The encapsulation layer TFE according to an embodiment may also include at least one organic film (hereinafter, an encapsulation-organic film) and at least one encapsulation-inorganic film.

The encapsulation-inorganic film protects the display device layer DP-ED from moisture/oxygen, and the encapsulation-organic film protects the display device layer DP-ED from foreign substances such as dust particles. The encapsulation-inorganic film may include silicon nitride, silicon oxynitride, silicon oxide, titanium oxide, aluminum oxide, and/or the like, but an embodiment of the present disclosure is not particularly limited thereto. The encapsulation-organic film may include an acrylic-based compound, an epoxy-based compound, and/or the like. The encapsulation-organic film may include a photopolymerizable organic material, but an embodiment of the present disclosure is not particularly limited thereto.

The encapsulation layer TFE may be on the second electrode EL2 and may fill the opening OH.

Referring to FIGS. 1-2, the display device DD may include a non-light emitting region NPXA and light emitting regions PXA-R, PXA-G, and PXA-B. The light emitting regions PXA-R, PXA-G, and PXA-B may be regions in which light generated by the respective light emitting elements ED-1, ED-2, and ED-3 is emitted. The light emitting regions PXA-R, PXA-G, and PXA-B may be spaced apart from each other on a plane.

Each of the light emitting regions PXA-R, PXA-G, and PXA-B may be a region divided by the pixel defining film PDL. The non-light emitting areas NPXA may be areas between the adjacent light emitting areas PXA-R, PXA-G, and PXA-B, which correspond to the pixel defining film PDL. In the specification, the light emitting regions PXA-R, PXA-G, and PXA-B may respectively correspond to pixels. The pixel defining film PDL may divide the light emitting elements ED-1, ED-2, and ED-3. The light-emitting layers EML-R, EML-G, and EML-B of the light emitting elements ED-1, ED-2, and ED-3 may be provided in openings OH defined in the pixel defining film PDL and separated from each other.

The light emitting regions PXA-R, PXA-G, and PXA-B may be divided into a plurality of groups according to the color of light generated from the light emitting elements ED-1, ED-2, and ED-3. In the display device DD of an embodiment illustrated in FIGS. 1-2, three light emitting regions PXA-R, PXA-G, and PXA-B, which emit red light, green light, and blue light, respectively, are illustrated as examples. For example, the display device DD of an embodiment may include the red light emitting region PXA-R, the green light emitting region PXA-G, and the blue light emitting region PXA-B that are separated from each other.

In the display device DD according to an embodiment, the plurality of light emitting elements ED-1, ED-2 and ED-3 may respectively emit light beams having wavelengths different from each other. For example, in an embodiment, the display device DD may include a first light emitting element ED-1 that emits red light, a second light emitting element ED-2 that emits green light, and a third light emitting element ED-3 that emits blue light. For example, the red light emitting region PXA-R, the green light emitting region PXA-G, and the blue light emitting region PXA-B of the display device DD may correspond to the first light emitting element ED-1, the second light emitting element ED-2, and the third light emitting element ED-3, respectively.

However, an embodiment of the present disclosure is not limited thereto, and the first to third light emitting elements ED-1, ED-2, and ED-3 may respectively emit light beams in the same wavelength range or at least one light emitting element may emit a light beam in a wavelength range different from the others. For example, the first to third light emitting elements ED-1, ED-2, and ED-3 may all emit blue light.

The light emitting regions PXA-R, PXA-G, and PXA-B in the display device DD according to an embodiment may be provided in a stripe form. Referring to FIG. 1, the plurality of red light emitting regions PXA-R, the plurality of green light emitting regions PXA-G, and the plurality of blue light emitting regions PXA-B each may be provided along a second directional axis DR2. In embodiments, the red light emitting region PXA-R, the green light emitting region PXA-G, and the blue light emitting region PXA-B may be alternately provided in this order along a first directional axis DR1.

FIGS. 1-2 illustrate that all the light emitting regions PXA-R, PXA-G, and PXA-B have similar area, but an embodiment of the present disclosure is not limited thereto. Thus, the light emitting regions PXA-R, PXA-G, and PXA-B may have different areas from each other according to the wavelength range of the emitted light. In embodiments, the areas of the light emitting regions PXA-R, PXA-G, and PXA-B may mean areas when viewed on a plane defined by the first directional axis DR1 and the second directional axis DR2.

In embodiments, an arrangement form of the light emitting regions PXA-R, PXA-G, and PXA-B is not limited to the configuration illustrated in FIG. 1, and the order in which the red light emitting region PXA-R, the green light emitting region PXA-G, and the blue light emitting region PXA-B are provided may be provided in various suitable combinations according to the characteristics of display quality desired or required in the display device DD. For example, the arrangement form of the light emitting regions PXA-R, PXA-G, and PXA-B may be a pentile (PENTILE®) arrangement form (e.g., an RGBG matrix, RGBG structure, or RGBG matrix structure) or a diamond (DIAMOND PIXEL™) arrangement form. PENTILE® and DIAMOND PIXEL™ are trademarks of Samsung Display Co., Ltd.

In embodiments, the areas of the light emitting regions PXA-R, PXA-G, and PXA-B may be different from each other. For example, in an embodiment, the area of the green light emitting region PXA-G may be smaller than that of the blue light emitting region PXA-B, but an embodiment of the present disclosure is not limited thereto.

Hereinafter, FIG. 3 to FIG. 6 are cross-sectional views schematically showing light emitting elements according to embodiments. The light emitting element ED according to an embodiment may include a first electrode EL1, a second electrode EL2 oppositely provided to the first electrode EL1, and at least one functional layer between the first electrode EL1 and the second electrode EL2.

In the light emitting element ED according to an embodiment, A hole transport region HTR may include a first hole transport layer HTL1 adjacent to the first electrode EL1, and a second hole transport layer HTL2 adjacent to the light-emitting layer EML. In an embodiment, the first hole transport layer HTL1 may be a layer having a smaller refractive index than the second hole transport later HTL2. In light emitting element ED according to an embodiment, the first hole transport layer HTL1 may include a first compound and a second compound of an embodiment, which will be further explained below, and the second transport later HTL2 may include the second compound. The first hole transport layer HTL1 in the light emitting element ED according to an embodiment may be a mixed layer in which the first compound and the second compound are mixed together.

Referring to FIG. 3, the light emitting element ED of an embodiment may include a first electrode EL1, a hole transport region HTR, a light-emitting layer EML, an electron transport region ETR, and a second electrode EL2, stacked in order.

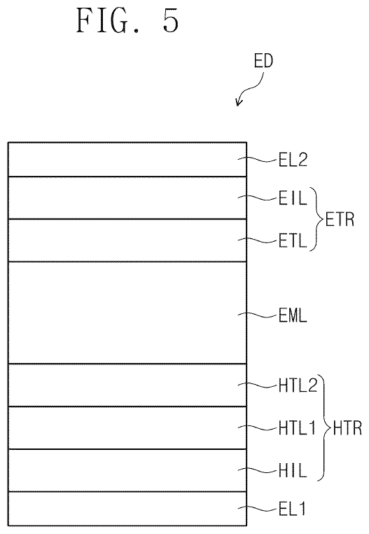

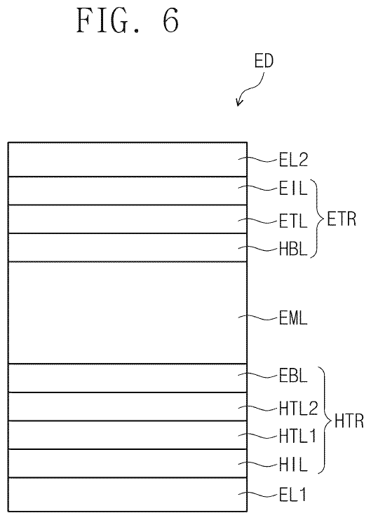

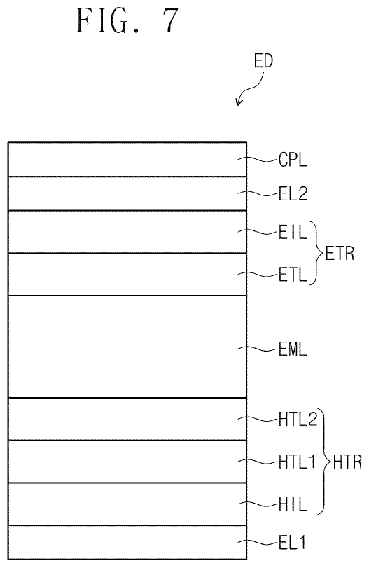

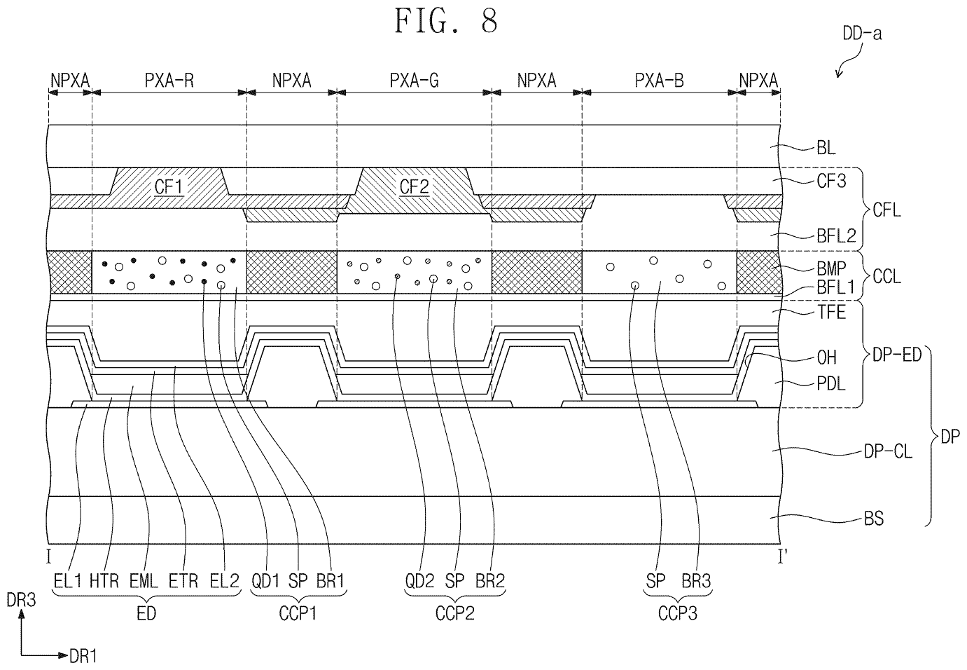

Compared with FIG. 3, FIG. 4 illustrates a cross-sectional view of a light emitting element ED of an embodiment, in which a hole transport region HTR includes a first hole transport layer HTL1 and a second hole transport layer HTL2, and an electron transport region ETR includes an electron injection layer EIL and an electron transport layer ETL. Compared with FIG. 4, FIG. 5 illustrates a cross-sectional view of a light emitting element ED of an embodiment including a hole injection layer HIL between a first electrode EL1 and a first hole transport later HTL1. Compared with FIG. 4, FIG. 6 illustrates a cross-sectional view of a light emitting element ED of an embodiment, in which a hole transport region HTR includes a hole injection layer HIL, a first hole transport layer HTL1, a second hole transport layer HTL2, and an electron blocking layer EBL, and an electron transport region ETR includes an electron injection layer EIL, an electron transport layer ETL, and a hole blocking layer HBL. Compared with FIG. 4, FIG. 7 illustrates a cross-sectional view of a light emitting element ED of an embodiment including a capping layer CPL on a second electrode EL2.

The first electrode EL1 has conductivity (e.g., electrical conductivity). The first electrode EL1 may be formed of a metal material, a metal alloy, and/or a conductive compound (e.g., an electrically conductive compound). The first electrode EL1 may be an anode or a cathode. However, an embodiment of the present disclosure is not limited thereto. In embodiments, the first electrode EL1 may be a pixel electrode. The first electrode EL1 may be a transmissive electrode, a transflective electrode, or a reflective electrode. The first electrode EL1 may include at least one selected from among Ag, Mg, Cu, Al, Pt, Pd, Au, Ni, Nd, Ir, Cr, Li, Ca, LiF, Mo, Ti, W, In, Sn, and Zn, a compound of two or more selected from among these, a mixture of two or more selected from among these, and/or an oxide thereof.

If the first electrode EL1 is the transmissive electrode, the first electrode EL1 may include a transparent metal oxide such as indium tin oxide (ITO), indium zinc oxide (IZO), zinc oxide (ZnO), and/or indium tin zinc oxide (ITZO). If the first electrode EL1 is the transflective electrode or the reflective electrode, the first electrode EL1 may include Ag, Mg, Cu, Al, Pt, Pd, Au, Ni, Nd, Ir, Cr, Li, Ca, LiF/Ca (a stacked structure of LiF and Ca), LiF/Al (a stacked structure of LiF and Al), Mo, Ti, W, a compound or mixture thereof (e.g., a mixture of Ag and Mg). In embodiments, the first electrode EL1 may have a multilayer structure including a reflective film or a transflective film formed of the above-described materials, and a transparent conductive film formed of ITO, IZO, ZnO, ITZO, etc. For example, the first electrode EL1 may have a three-layer structure of ITO/Ag/ITO, but an embodiment of the present disclosure is not limited thereto. In embodiments, an embodiment of the present disclosure is not limited thereto, and the first electrode EL1 may include the above-described metal materials, combinations of at least two metal materials of the above-described metal materials, oxides of the above-described metal materials, and/or the like. The thickness of the first electrode EL1 may be from about 700 Å to about 10,000 Å. For example, the thickness of the first electrode EL1 may be from about 1,000 Å to about 3,000 Å.

A hole transport region HTR is provided on a first electrode EL1. The hole transport region HTR may include a first hole transport layer HTL1 and a second hole transport layer HTL2. The first hole transport layer HTL1 may be on the first electrode EL1, and the second hole transport layer HTL2 may be on the first hole transport layer HTL1. The first hole transport layer HTL1 having a relatively lower refractive index than the second hole transport layer HTL2 may be adjacent to the first electrode EL1, and the second hole transport layer HTL2 may be on the first hole transport layer HTL1. In a light-emitting element ED according to an embodiment, the hole transport region HTR may include a plurality of hole transport layers HTL1 and HTL2 provided in a sequence of a low refractive index hole transport layer/a high refractive index hole transport layer in a thickness direction.

The first hole transport layer HTL1 may have a refractive index of about 1.20 to about 1.85 at a wavelength of about 460 nm. In embodiments, the second hole transport layer HTL2 may have a refractive index of about 1.90 to about 2.50 at a wavelength of about 460 nm. A difference between the refractive index of the first hole transport layer HTL1 and the refractive index of the second hole transport layer HTL2 may be greater than about 0.1 at a wavelength of about 460 nm. For example, the difference between the refractive index of the first hole transport layer HTL1 and the refractive index of the second hole transport layer HTL2 may be equal to or greater than about 0.2 at a wavelength of about 460 nm.

For convenience of description, FIGS. 3-7 illustrate that the first hole transport layer HTL1 and the second hole transport layer HTL2 have the same thickness, but an embodiment is not limited thereto, and the first hole transport layer HTL1 and the second hole transport layer HTL2 may have different thicknesses. Thicknesses of the first hole transport layer HTL1 and the second hole transport layer HTL2 may be controlled to a suitable or optimal range according to a wavelength region of light emitted from a light-emitting layer EML, display quality desired or required in the display device DD (see FIG. 1), and a type (or kind) of a hole transport material used in each of the hole transport layers HTL1 and HTL2 of the hole transport region HTR.

The light-emitting element ED according to an embodiment may include the first hole transport layer HTL1 and the second hole transport layer HTL2 provided in a stack sequence of the low refractive index hole transport layer/the high refractive index hole transport layer to show improved luminous efficiency characteristics. The light-emitting element ED according to an embodiment may include the first hole transport layer HTL1 and the second hole transport layer HTL2 having a refractive index difference to minimize or reduce destructive interference and extinction of light emitted from internal functional layers, and to cause constructive interference by the hole transport layers HTL1 and HTL2 having the refractive index difference, thereby showing high light extraction efficiency.

The first hole transport layer HTL1 may be on the first electrode EL1. The hole transport region HTR according to an embodiment may include the first hole transport layer HTL1 on the first electrode EL1, and the second hole transport layer HTL2 on the first hole transport layer HTL1. In an embodiment, the first hole transport layer HTL1 may be directly on the first electrode EL1. However, an embodiment is not limited thereto, and an additional layer such as a hole injection layer HIL may be further between the first electrode EL1 and the first hole transport layer HTL1. The second hole transport layer HTL2 may be directly on the first hole transport layer HTL1. In embodiments, the second hole transport layer HTL2 may be directly under the light-emitting layer EML. However, an embodiment is not limited thereto, and an additional layer such as an electron-blocking layer EBL may be further between the second hole transport layer HTL2 and the light-emitting layer EML.

In the light-emitting element ED according to an embodiment, as illustrated in FIGS. 5-7, the hole transport region HTR may include at least one of the hole injection layer HIL, a buffer layer and/or auxiliary light-emitting layer, and/or the electron-blocking layer EBL, as well as the first and second hole transport layers HTL1 and HTL2, but an embodiment is not limited thereto.

The hole transport region HTR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The hole transport region HTR may have a structure of the first hole transport layer HTL1/the second hole transport layer HTL2 sequentially stacked from the first electrode EL1. In embodiments, the hole transport region HTR may have a structure of the hole injection layer HIL/the first hole transport layer HTL1/the second hole transport layer HTL2, or the hole injection layer HIL/the first hole transport layer HTL1/the second hole transport layer HTL2/the electron-blocking layer EBL sequentially stacked from the first electrode EL1, but is not limited thereto. The hole transport region HTR may have a thickness, for example, of about 50 Å to about 15000 Å.

The light-emitting element ED according to an embodiment may include, in the first hole transport layer HTL1, a first compound represented by Chemical Formula 1 below, and a second compound represented by Chemical Formula 2-1 or Chemical Formula 2-2 below. The first compound represented by Chemical Formula 1 may have a refractive index of about 1.20 to about 1.85 at a wavelength of about 460 nm. The second compound represented by Chemical Formula 2-1 and Chemical Formula 2-2 may have a refractive index of about 1.90 to about 2.50 at a wavelength of about 460 nm. The first hole transport layer HTL1 may be formed of a mixture of the first compound represented by Chemical Formula 1 below and the second compound represented by Chemical Formula 2-1 or Chemical Formula 2-2 below. The first hole transport layer HTL1 may include the first compound and the second compound. The second compound included in the first hole transport layer HTL1 may be different from the first compound.

The first compound according to an embodiment includes an amine group, and a first substituent, a second substituent, and a third substituent connected to the amine group. For example, the first compound according to an embodiment may include the amine group, for example, a core nitrogen atom, and may include a structure in which the first substituent, the second substituent, and the third substituent are connected to the core nitrogen atom. The first to third substituents may be an aryl group and/or a heteroaryl group connected to the core nitrogen atom through an arylene linker and/or a heteroarylene linker, or directly connected to the core nitrogen atom without a separate linker. In an embodiment, the first to third substituents may be a substituted or unsubstituted aryl group having a ring-forming carbon number of 6 to 30, or a substituted or unsubstituted heteroaryl group having a ring-forming carbon number of 2 to 30.

In an embodiment, at least one among the first to third substituents may be substituted for (e.g., may be or may be substituted with) a substituted or unsubstituted cycloalkyl group having a ring-forming carbon number of 3 to 20, or may be connected to the core nitrogen atom through a first linker. In an embodiment, the first linker may be a phenylene group represented by Chemical Formula A-1 or Chemical Formula A-2 below, or a substituted or unsubstituted divalent naphthyl group. For example, at least one among the first to third substituents may be substituted for (e.g., may be or may be substituted with) a substituted or unsubstituted cyclohexyl group, a substituted or unsubstituted bicycloheptyl group, or a substituted or unsubstituted adamantyl group. In embodiments, at least one among the first to third substituents may be connected to a substituted or unsubstituted phenylene group, and may be substituted for (e.g., may be or may be substituted with) the core nitrogen atom through the phenylene linker so as to have an ortho relation or a meta relation with the core nitrogen atom. The first compound according to an embodiment may include a cycloalkyl group in a molecular structure thereof, or may include a structure in which the core nitrogen atom is connected to the substituent so as to have an ortho relation or a meta relation to reduce interaction between molecules, and thus may have a low packing density. Accordingly, the first compound according to an embodiment may have low refractive index characteristics, and may change a molecular refractive index by variously, suitably changing a combination with the substituent.

In an embodiment, the first compound may include, in a molecular structure thereof, one to five of a substituted or unsubstituted cycloalkyl group having a ring-forming carbon number of 3 to 20. For example, the first compound may include, in the molecular structure thereof, one or two of a substituted or unsubstituted cycloalkyl group having a ring-forming carbon number of 3 to 20. For example, one among the first to third substituents in the first compound may be substituted for (e.g., may be or may be substituted with) a substituted or unsubstituted cycloalkyl group having a ring-forming carbon number of 3 to 20. In embodiments, two among the first to third substituents in the first compound may be each substituted for (e.g., may be or may be substituted with) a substituted or unsubstituted cycloalkyl group having a ring-forming carbon number of 3 to 20.

In an embodiment, the first compound may include, in the molecular structure thereof, one to five of at least one substituent selected from a substituted or unsubstituted cyclohexyl group, a substituted or unsubstituted bicyclohexyl group, and a substituted or unsubstituted adamantyl group. For example, the first compound may include, in the molecular structure, one or two substituents selected from a substituted or unsubstituted cyclohexyl group, a substituted or unsubstituted bicyclohexyl group, and a substituted or unsubstituted adamantyl group.

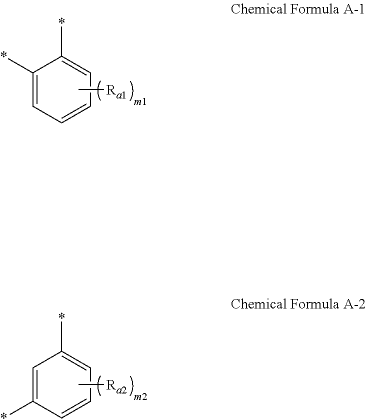

In Chemical Formula A-1 and Chemical Formula A-2, Rₐ₁ and Rₐ₂ are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. For example, Rₐ₁ and Rₐ₂ may be each independently a hydrogen atom or a deuterium atom.

In Chemical Formula A-1 and Chemical Formula A-2, m1 and m2 are each independently an integer of 0 to 4. In Chemical Formula A-1 and Chemical Formula A-2, when m1 and m2 are each 0, the first compound according to an embodiment may not be substituted for (e.g., may not be substituted with) each of Rₐ₁ and Rₐ₂. In Chemical Formula A-1 and Chemical Formula A-2, a case in which m1 and m2 are each 4, and Rₐ₁ and Rₐ₂ are each a hydrogen atom may be the same as a case in which m1 and m2 are each 0 in Chemical Formula A-1 and Chemical Formula A-2. When m1 and m2 are each an integer equal to or more than 2, Rₐ₁ and Rₐ₂ provided in plurality may be the same as each other, or at least one among a plurality of Rₐ₁ and Rₐ₂ may be different from each other.

In embodiments, the second compound may not include a substituted or unsubstituted cycloalkyl group. The second compound may not include, in a molecular structure thereof, the substituted or unsubstituted cycloalkyl group.

In an embodiment, the first compound is represented by Chemical Formula 1 below.

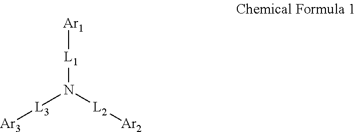

In Chemical Formula 1, N may correspond to the core nitrogen atom described above, and Ar₁ to Ar₃ may respectively correspond to the first to third substituents.

In Chemical Formula 1, Ar₁ to Ar₃ are each independently a substituted or unsubstituted amine group, a substituted or unsubstituted aryl group having a ring-forming carbon number of 6 to 30, or a substituted or unsubstituted heteroaryl group having a ring-forming carbon number of 2 to 30. For example, Ar₁ to Ar₃ may be each independently a substituted or unsubstituted arylamine group, a substituted or unsubstituted phenyl group, a substituted or unsubstituted biphenyl group, a substituted or unsubstituted naphthyl group, or a substituted or unsubstituted fluorenyl group.

In Chemical Formula 1, L₁ to L₃ are each independently a direct linkage (e.g., a covalent bond), substituted or unsubstituted arylene group having a ring-forming carbon number of 6 to 30, or a substituted or unsubstituted heteroarylene group having a ring-forming carbon number of 2 to 30. For example, L₁ to L₃ may be each independently a direct linkage (e.g., a covalent bond), substituted or unsubstituted phenylene group, or a substituted or unsubstituted divalent naphthyl group.

In Chemical Formula 1, at least one among L₁ to L₃ is a phenylene group represented by Chemical Formula A-1 above or Chemical Formula A-2 above, or a substituted or unsubstituted divalent naphthyl group, or at least among Ar₁ to Ar₃ is substituted for (e.g., may be or may be substituted with) a substituted or unsubstituted cycloalkyl group having a ring-forming carbon number of 3 to 20.

In an embodiment, in Chemical Formula 1, at least one among L₁ to L₃ may be a phenylene group represented by Chemical Formula A-1 above, or Chemical Formula A-2 above, or a substituted or unsubstituted divalent naphthyl group.

In an embodiment, in Chemical Formula 1, Ar₁ to Ar₃ may be each independently a substituted or unsubstituted arylamine group, a substituted or unsubstituted phenyl group, a substituted or unsubstituted biphenyl group, a substituted or unsubstituted naphthyl group, or a substituted or unsubstituted fluorenyl group, and at least one among Ar₁ to Ar₃ may be substituted for (e.g., may be or may be substituted with) a substituted or unsubstituted cyclohexyl group. For example, at least one among Ar₁ to Ar₃ may be an aryl amine group substituted for (e.g., substituted with) a cyclohexyl group, a phenyl group substituted for (e.g., substituted with) a cyclohexyl group, a biphenyl group substituted for (e.g., substituted with) a cyclohexyl group, or a naphthyl group substituted for (e.g., substituted with) a cyclohexyl group, and the rest thereof may be each independently a substituted or unsubstituted arylamine group, a substituted or unsubstituted phenyl group, a substituted or unsubstituted naphthyl group, or a substituted or unsubstituted fluorenyl group.

In an embodiment, the first compound may be represented by Chemical Formula 1-1 or Chemical Formula 1-2 below.

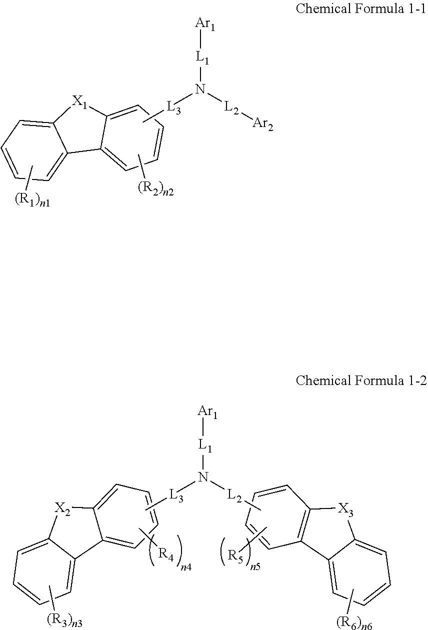

In Chemical Formula 1-1 and Chemical Formula 1-2, X₁ to X₃ may be each independently CR₇R₈, NR₉, O, S, or Se. For example, X₁ to X₃ may be each independently CR₇R₈.

In chemical Formula 1-1 and Chemical Formula 1-2, R₁ to R₉ may be each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. In embodiments, R₁ to R₉ may be each bonded to an adjacent group to form a ring. For example, R₁ to R₆ may be each independently a hydrogen atom, a deuterium atom, a substituted or unsubstituted phenyl group, or a substituted or unsubstituted naphthyl group. In embodiments, R₇ to R₉ may be a hydrogen atom, a substituted or unsubstituted methyl group, or a substituted or unsubstituted phenyl group. In embodiments, R₇ and R₈ may be bonded to each other to form a ring. When R₇ and R₈ are bonded to each other to from a ring, the fluorenyl group included in the first compound represented by Chemical Formula 1-1 and Chemical Formula 1-2 may have a spiro structure.

In Chemical Formula 1-1 and Chemical Formula 1-2, n1, n3, and n6 are each independently an integer of 0 to 4, and n2, n4, and n5 are each independently an integer of 0 to 3.

When n1, n3, and n6 are each 0, the first compound according to an embodiment may not be substituted for (e.g., may not be or may not be substituted with) each of R₁, R₃, and R₆. A case in which n1, n3, and n6 are each 4, and R₁, R₃, and R₆ are each a hydrogen atom may be the same as a case in which n1, n3, and n6 are each 0. When n1, n3, and n6 are each an integer equal to or more than 2, R₁, R₃, and R₆ supplied in plurality may be the same, or at least one among a plurality of R₁, R₃, and R₆ may be different from the rest thereof.

When n2, n4, and n5 are each 0, the first compound according to an embodiment may not be substituted for (e.g., may not be substituted with) each of R₂, R₄, and R₅. A case in which n2, n4, and n5 are each 3, and R₂, R₄, and R₅ are each a hydrogen atom may be the same as a case in which n2, n4, and n5 are each 0. When n2, n4, and n5 are each an integer equal to or more than 2, R₂, R₄, and R₅ supplied in plurality may be the same, or at least one among a plurality of R₂, R₄, and R₅ may be different from the rest thereof.

In Chemical Formula 1-1, and Chemical Formula 1-2, the description provided with respect to Chemical Formula 1 above may be also identically applied to Ar₁, Ar₂, and L₁ to L₃.

In an embodiment, the first compound may be represented by any one among Chemical Formula 1-4 to Chemical Formula 1-6 below.

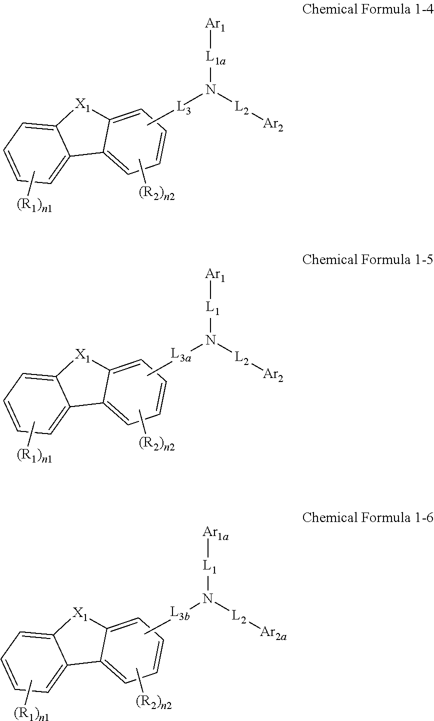

In Chemical Formula 1-4 to Chemical Formula 1-6, X₁ may be CR₇R₈, NR₉, O, S, or Se. For example, X₁ may be CR₇R₈.

In Chemical Formula 1-4 to Chemical Formula 1-6, R₁, R₂, and R₇ to R₉ may be each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. In embodiments, R₁, R₂, and R₇ to R₉ may be each bonded to an adjacent group to form a ring. For example, R₁, and R₂ may be each independently a hydrogen atom, a deuterium atom, a substituted or unsubstituted phenyl group, or a substituted or unsubstituted naphthyl group. In embodiments, R₇ to R₉ may be each a hydrogen atom, a substituted or unsubstituted methyl group, or a substituted or unsubstituted phenyl group. In embodiments, R₇ and R₈ may be bonded to each other to form a ring. When R₇ and R₈ are bonded to each other to form a ring, the fluorenyl group included in the first compound represented by Chemical Formula 1-4 to Chemical Formula 1-6 may have a spiro structure.

In Chemical Formula 1-4 to Chemical Formula 1-6, L₁ₐ and L₃ₐ may be each independently represented by Chemical Formula A-1.

In Chemical Formula 1-4 to Chemical Formula 1-6, L₃b may be a substituted or unsubstituted arylene group having a ring-forming carbon number of 6 to 30, or a substituted or unsubstituted heteroarylene group having a ring-forming carbon number of 2 to 30. For example, L₃b may be a substituted or unsubstituted phenylene group.

In Chemical Formula 1-4 to Chemical Formula 1-6, Ar₁ₐ and Ar₂ₐ may be each independently a substituted or unsubstituted aryl group having a ring-forming carbon number of 6 to 30, or a substituted or unsubstituted heteroaryl group having a ring-forming carbon number of 2 to 30. For example, Ar₁ₐ and Ar₂ₐ may be a substituted or unsubstituted phenyl group, a substituted or unsubstituted biphenyl group, a substituted or unsubstituted naphthyl group, or a substituted or unsubstituted fluorenyl group.

In Chemical Formula 1-4 to Chemical Formula 1-6, at least one among Ar₁ₐ and Ar₂ₐ may be substituted for (e.g., may be or may be substituted with) a substituted or unsubstituted cyclohexyl group, a substituted or unsubstituted bicycloheptyl group, or a substituted or unsubstituted adamantyl group. For example, any one among Ar₁ₐ and Ar₂ₐ may be substituted for (e.g., may be or may be substituted with) a substituted or unsubstituted cyclohexyl group. In embodiments, Ar₁ₐ and Ar₂ₐ may be substituted for (e.g., may be or may be substituted with) a substituted or unsubstituted cyclohexyl group. In an embodiment, at least one among Ar₁ₐ and Ar₂ₐ may be a phenyl group substituted for (e.g., substituted with) a cyclohexyl group, or a biphenyl group substituted for (e.g., substituted with) a cyclohexyl group.

In Chemical Formula 1-4 to Chemical Formula 1-6, n1 is an integer of 0 to 4. In Chemical Formula 1-4 to Chemical Formula 1-6, when n1 is 0, the first compound according to an embodiment may not be substituted for (e.g., may not be substituted with) R₁. In Chemical Formula 1-4 to Chemical Formula 1-6, a case in which n1 is 4, and R₁ are all hydrogen atoms may be the same as a case in which n1 is 0 in Chemical Formula 1-4 and Chemical Formula 1-6. When n1 is an integer equal to or more than 2, R₁ supplied in plurality may be all the same, or at least one among a plurality of R₁ may be different from the rest thereof.

In Chemical Formula 1-4 to Chemical Formula 1-6, n2 is an integer of 0 to 3. In Chemical Formula 1-4 to Chemical Formula 1-6, when n2 is 0, the first compound according to an embodiment may not be substituted for (e.g., may not be substituted with) R₂. In Chemical Formula 1-4 to Chemical Formula 1-6, a case in which n2 is 3 and R₂ are all hydrogen atoms may be the same as a case in which n2 is 0 in Chemical Formula 1-4 to Chemical Formula 1-6. When n2 is an integer equal to or more than 2, R₂ supplied in plurality may be all the same, or at least one among a plurality of R₂ may be different from the rest thereof.

In Chemical Formula 1-4 to Chemical Formula 1-6, description provided with respect to Chemical Formula 1 above may be also identically applied to Ar₁, Ar₂, and L₁ to L₃.

In an embodiment, in Chemical Formula 1, Ar₁ may be represented by Chemical Formula B-1 below, L₁ may be a direct linkage (e.g., a covalent bond), L₂ and L₃ may be each independently a substituted or unsubstituted phenylene group, and at least one among L₂ and L₃ may be represented by Chemical Formula A-1 above.

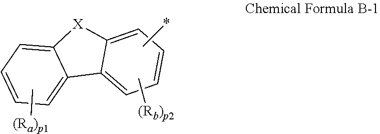

In Chemical Formula B-1, Rₐ and R_{b} may be each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. For example, Rₐ and R_{b} may be each independently a hydrogen atom or a deuterium atom.

In Chemical Formula B-1, p1 is an integer of 0 to 4. In Chemical Formula B-1, when p1 is 0, the first compound according to an embodiment may not be substituted for (e.g., may not be substituted with) Rₐ. In Chemical Formula B-1, a case in which p1 is 4, and Rₐ are all hydrogen atoms may be the same as a case in which p1 is 0 in Chemical Formula B-1. When p1 is an integer equal to or more than 2, Rₐ provided in plurality may be all the same, or at least one among a plurality of Rₐ may be different from the rest thereof.

In Chemical Formula B-1, p2 is an integer of 0 to 3. In Chemical Formula B-1, when p2 is 0, the first compound according to an embodiment may not be substituted for (e.g., may not be substituted with) R_{b}. In Chemical Formula B-1, a case in which p2 is 3 and R_{b} are all hydrogen atoms may be the same as a case in which p2 is 0 in Chemical Formula B-1. When p2 is an integer equal to or more than 2, R_{b} supplied in plurality may be all the same, or at least one among a plurality of R_{b} may be different from the rest thereof.

The first compound included in the first hole transport layer HTL1 according to an embodiment may be represented by one among compounds of Compound Group 1 below. The first hole transport layer HTL1 of the light-emitting element ED according to an embodiment may include at least one among the compounds disclosed in Compound Group 1 below.

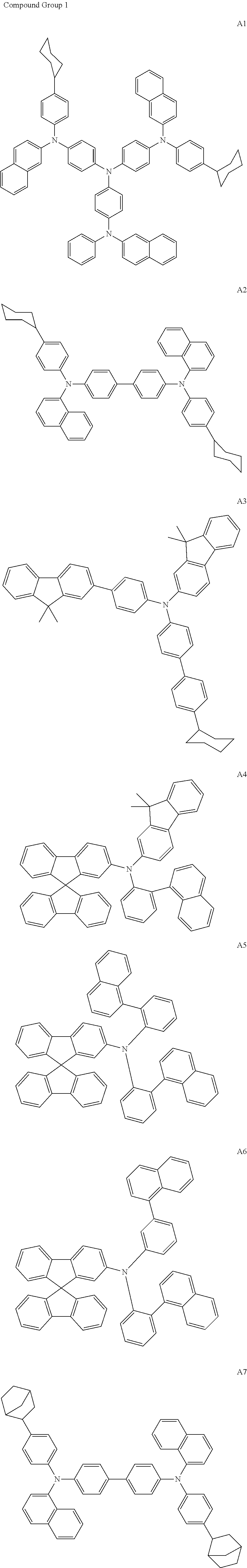

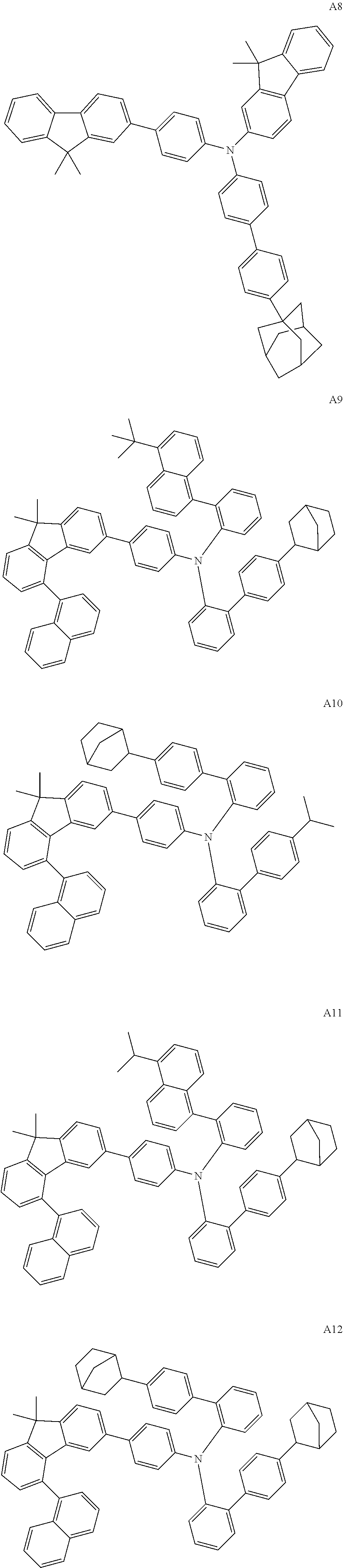

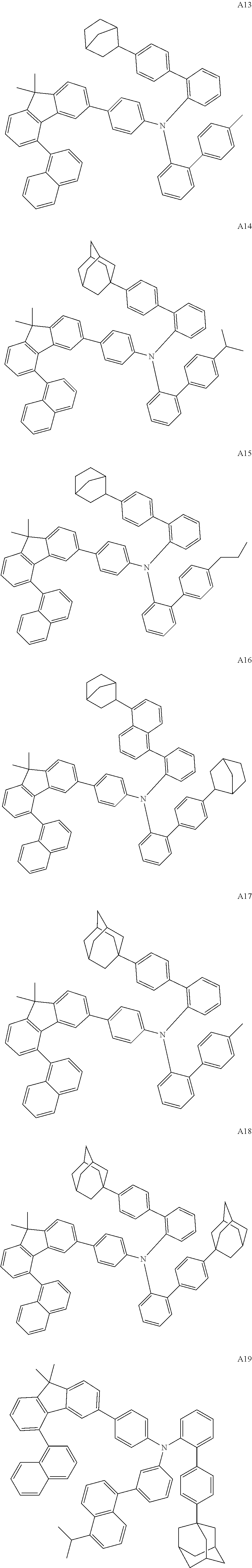

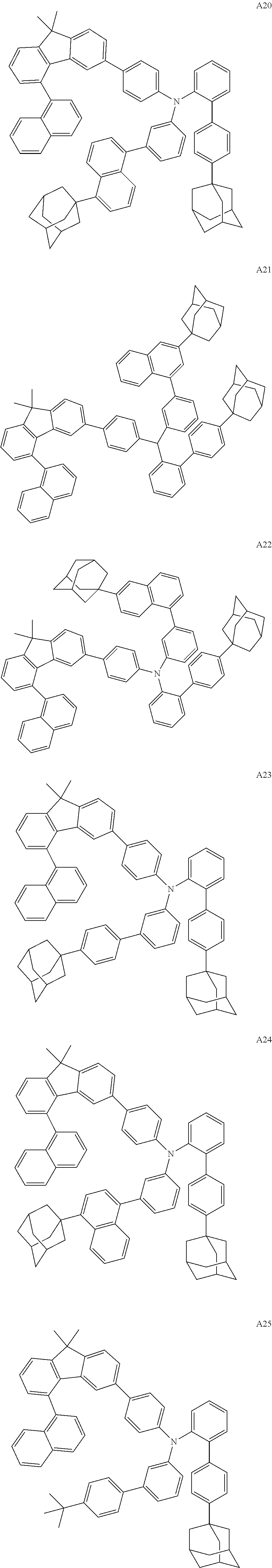

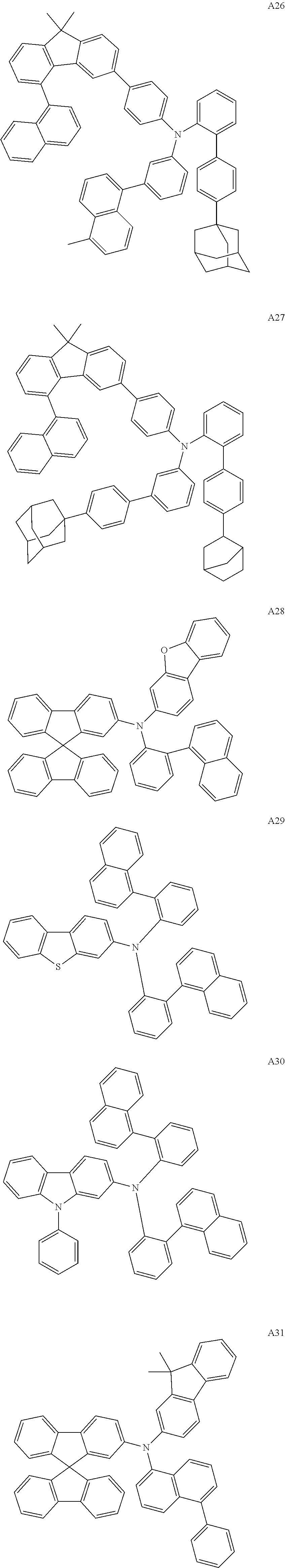

In an embodiment, the second compound may be represented by Chemical Formula 2-1 or Chemical Formula 2-2 below. The first hole transport layer HTL1 and the second hole transport layer HTL2 may each include a compound represented by Chemical Formula 2-1 or Chemical Formula 2-2 below. The second compound represented by Chemical Formula 2-1 or Chemical Formula 2-2 may have a refractive index of about 1.90 to about 2.50 at a wavelength of about 460 nm. The first hole transport layer HTL1 and the second hole transport layer HTL2 may be each formed of any one among the second compounds represented by Chemical Formula 2-1 or Chemical Formula 2-2 below, or a mixture thereof. The second compound included in the first hole transport layer HTL1 and the second compound included in the second hole transport layer HTL2 may be different from or the same as each other.

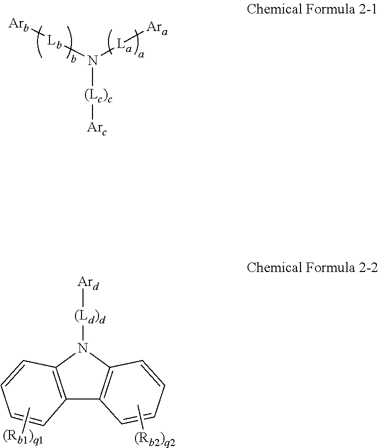

In Chemical Formula 2-1, Arₐ to Ar_{c} are each independently a substituted or unsubstituted aryl group having a ring-forming carbon number of 6 to 30, or a substituted or unsubstituted heteroaryl group having a ring-forming carbon number of 2 to 30.

In Chemical Formula 2-1 and Chemical Formula 2-2, Lₐ to L_{d} are each independently a direct linkage (e.g., a covalent bond), a substituted or unsubstituted arylene group having a ring-forming carbon number of 6 to 30, or a substituted or unsubstituted heteroarylene group having a ring-forming carbon number of 2 to 30.

In Chemical Formula 2-1 and Chemical Formula 2-2, a to d are each independently an integer of 0 to 10. In embodiments, when a to d are integers equal to or more than 2, a plurality of Lₐ to L_{d} may be each independently a substituted or unsubstituted arylene group having a ring-forming carbon number of 6 to 30, or a substituted or unsubstituted heteroarylene group having a ring-forming carbon number of 2 to 30.

In Chemical Formula 2-2, Ar_{d} is a substituted or unsubstituted aryl group having a ring-forming carbon number of 6 to 30, or a substituted or unsubstituted heteroaryl group having a ring-forming carbon number of 2 to 30.

In Chemical Formula 2-2, R_{b1} and R_{b2} may be each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30. In embodiments, R_{b1} and R_{b2} may be each bonded to an adjacent group to form a ring.

In Chemical Formula 2-2, q1 means the number of R_{b1}, and q2 means the number of R_{b2}. In an embodiment, q1 and q2 are each independently an integer of 0 to 4. In Chemical Formula 2-2, when q1 and q2 are each 0, the second compound according to an embodiment may not be substituted for (e.g., may not be substituted with) each of R_{b1} and R_{b2}. In Chemical Formula 2-2, a case in which q1 and q2 are each 4, and R_{b1} and R_{b2} are each all hydrogen atoms may be the same as a case in which q1 and q2 are each 0 in Chemical Formula 2-2. When q1 and q2 are each an integer equal to more than 2, R_{b1} and R_{b2} supplied in plurality may be each all the same, or at least one among a plurality of R_{b1} and R_{b2} may be different from the rest thereof.

The second compound included in each of the first hole transport layer HTL1 and the second hole transport layer HTL2 according to an embodiment may be represented by one among compounds of Compound Group 2-1 and Compound Group 2-2 below. The first hole transport layer HTL1 and the second hole transport layer HTL2 of the light-emitting element ED according to an embodiment may include at least one among the compounds of Compound Group 2-1 and Compound Group 2-2 below.

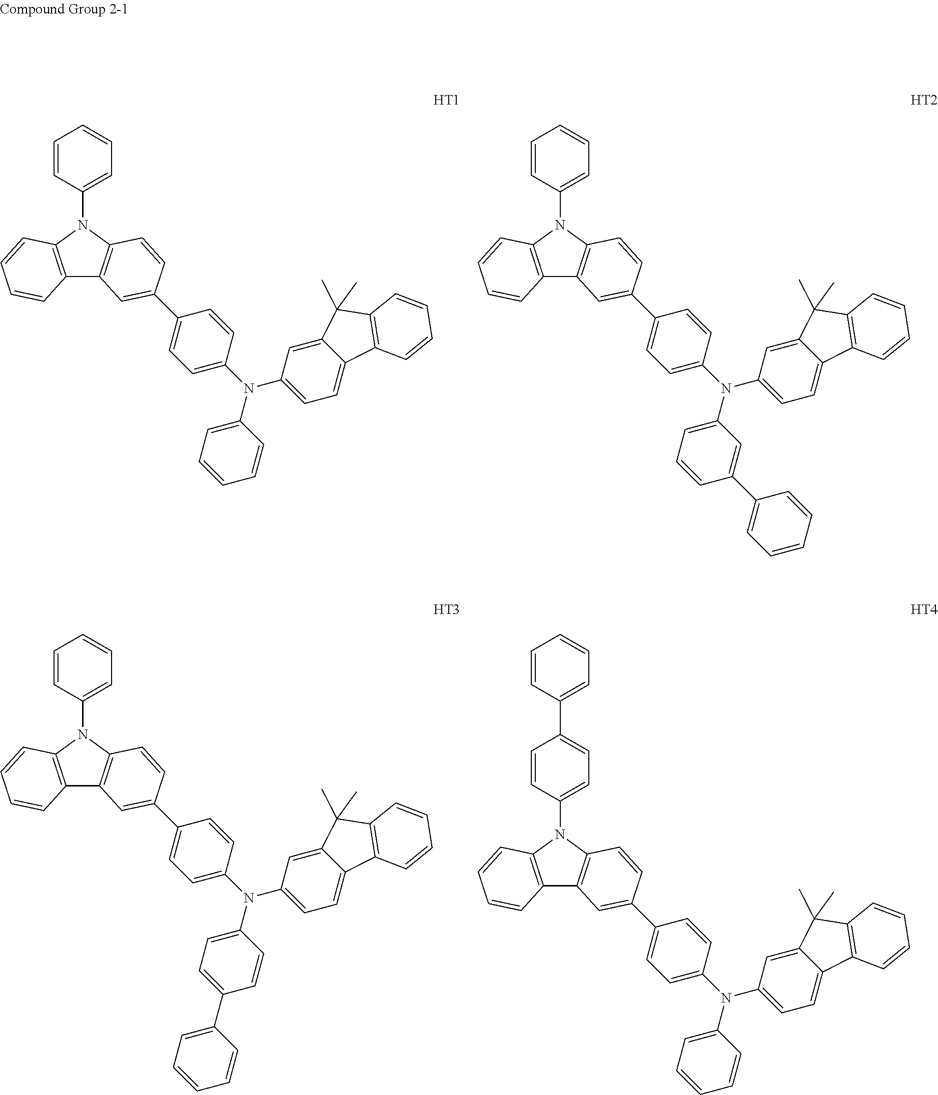 [SMILES: CC1(C)c2ccccc2-c2ccc(N(c3ccccc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4ccccc4)c3)cc21 ; CC1(C)c2ccccc2-c2ccc(N(c3ccc(-c4ccccc4)cc3)c3ccc(-c4ccc5c(c4)c4ccccc4n5-c4ccccc4)cc3)cc21 ; CC1(C)c2ccccc2-c2ccc(N(c3ccccc3)c3ccc(-c4ccc5c(c4)c4ccccc4n5-c4ccc(-c5ccccc5)cc4)cc3)cc21]

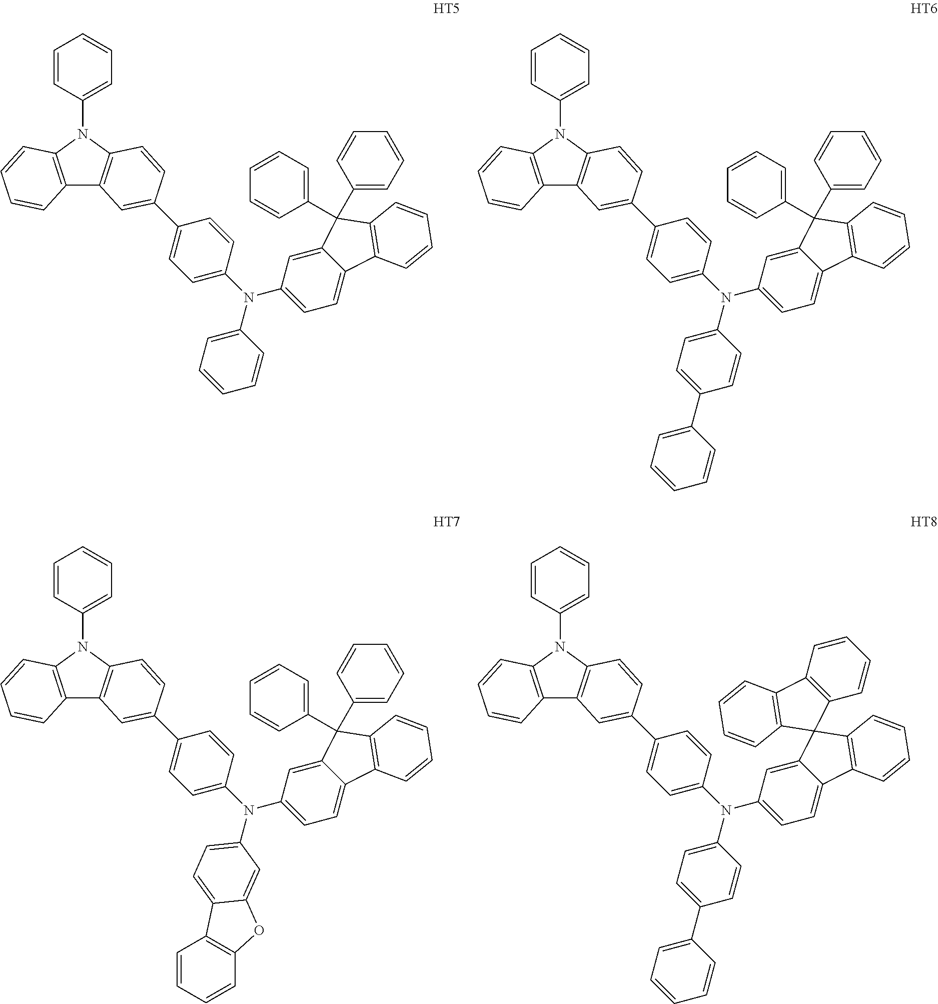 [SMILES: c1ccc(N(c2ccc(-c3ccc4c(c3)c3ccccc3n4-c3ccccc3)cc2)c2ccc3c(c2)C(c2ccccc2)(c2ccccc2)c2ccccc2-3)cc1 ; c1ccc(-c2ccc(N(c3ccc(-c4ccc5c(c4)c4ccccc4n5-c4ccccc4)cc3)c3ccc4c(c3)C(c3ccccc3)(c3ccccc3)c3ccccc3-4)cc2)cc1 ; c1ccc(-n2c3ccccc3c3cc(-c4ccc(N(c5ccc6c(c5)C(c5ccccc5)(c5ccccc5)c5ccccc5-6)c5ccc6c(c5)oc5ccccc56)cc4)ccc32)cc1 ; c1ccc(-c2ccc(N(c3ccc(-c4ccc5c(c4)c4ccccc4n5-c4ccccc4)cc3)c3ccc4c(c3)C3(c5ccccc5-c5ccccc53)c3ccccc3-4)cc2)cc1]

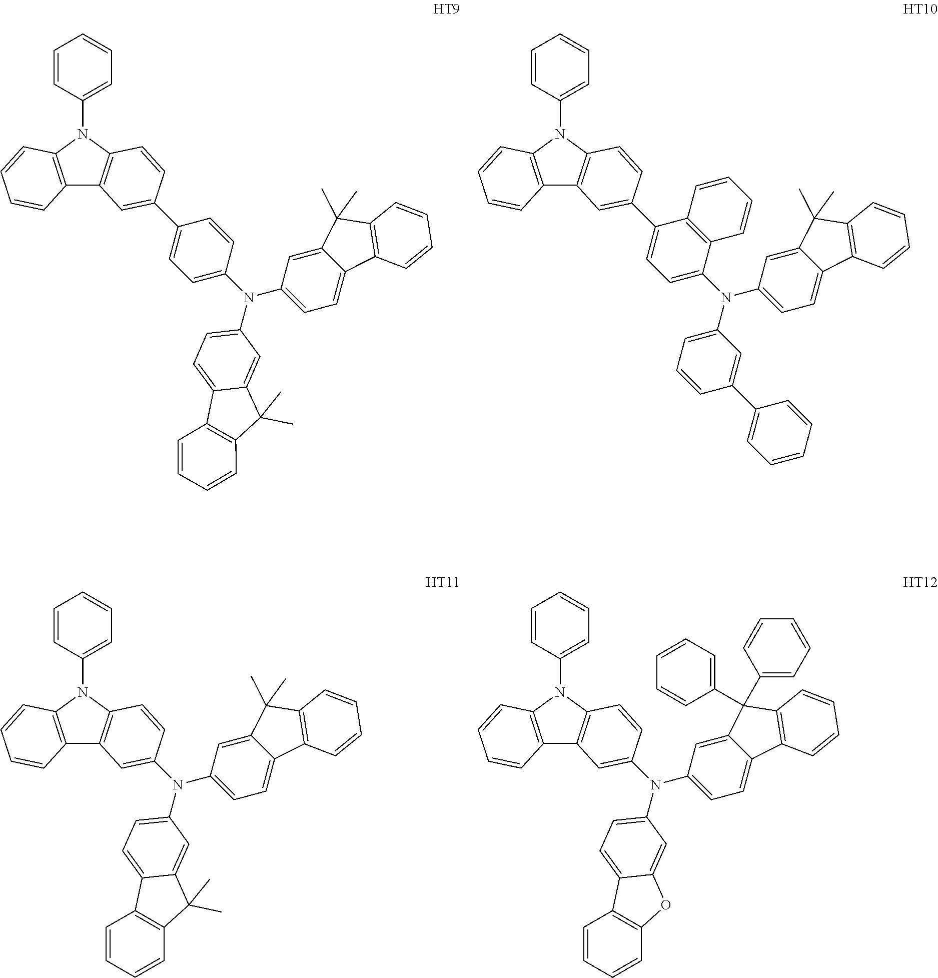 [SMILES: CC1(C)c2ccccc2-c2ccc(N(c3ccc(-c4ccc5c(c4)c4ccccc4n5-c4ccccc4)cc3)c3ccc4c(c3)C(C)(C)c3ccccc3-4)cc21 ; CC1(C)c2ccccc2-c2ccc(N(c3cccc(-c4ccccc4)c3)c3ccc(-c4ccc5c(c4)c4ccccc4n5-c4ccccc4)c4ccccc34)cc21 ; CC1(C)c2ccccc2-c2ccc(N(c3ccc4c(c3)C(C)(C)c3ccccc3-4)c3ccc4c(c3)c3ccccc3n4-c3ccccc3)cc21 ; c1ccc(-n2c3ccccc3c3cc(N(c4ccc5c(c4)C(c4ccccc4)(c4ccccc4)c4ccccc4-5)c4ccc5c(c4)oc4ccccc45)ccc32)cc1]

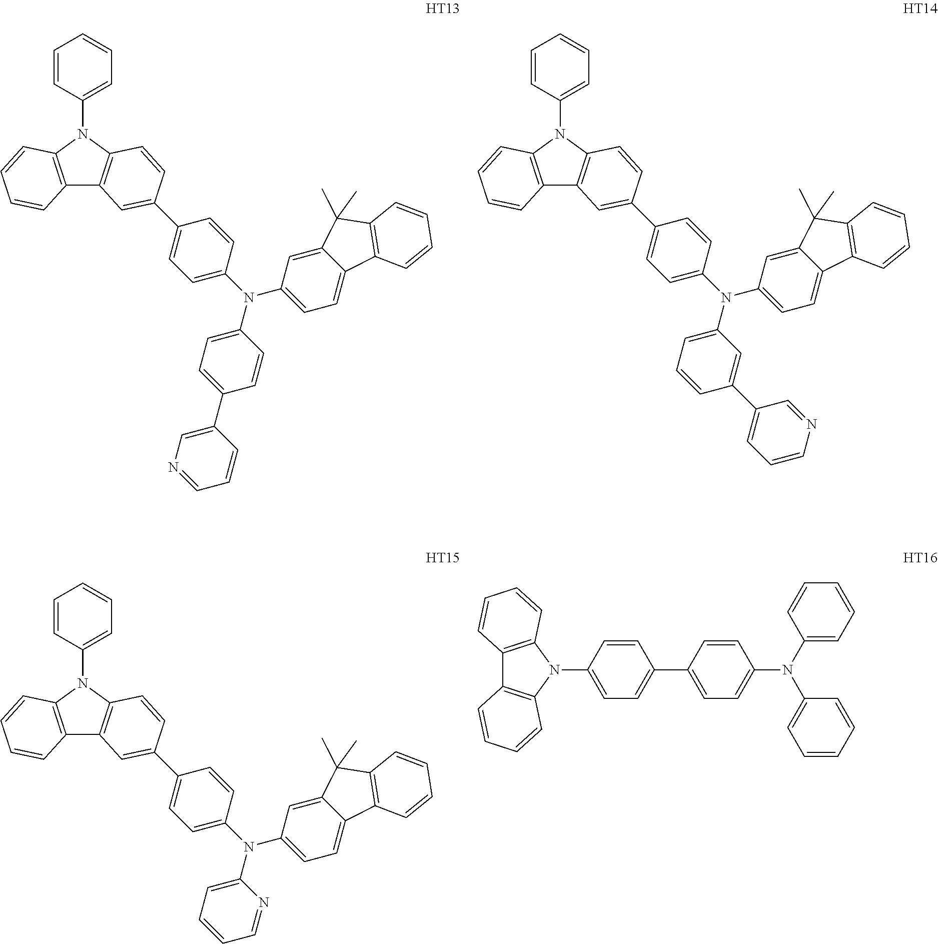 [SMILES: CC1(C)c2ccccc2-c2ccc(N(c3ccc(-c4cccnc4)cc3)c3ccc(-c4ccc5c(c4)c4ccccc4n5-c4ccccc4)cc3)cc21 ; CC1(C)c2ccccc2-c2ccc(N(c3ccc(-c4ccc5c(c4)c4ccccc4n5-c4ccccc4)cc3)c3cccc(-c4cccnc4)c3)cc21 ; CC1(C)c2ccccc2-c2ccc(N(c3ccc(-c4ccc5c(c4)c4ccccc4n5-c4ccccc4)cc3)c3ccccn3)cc21 ; c1ccc(N(c2ccccc2)c2ccc(-c3ccc(-n4c5ccccc5c5ccccc54)cc3)cc2)cc1]

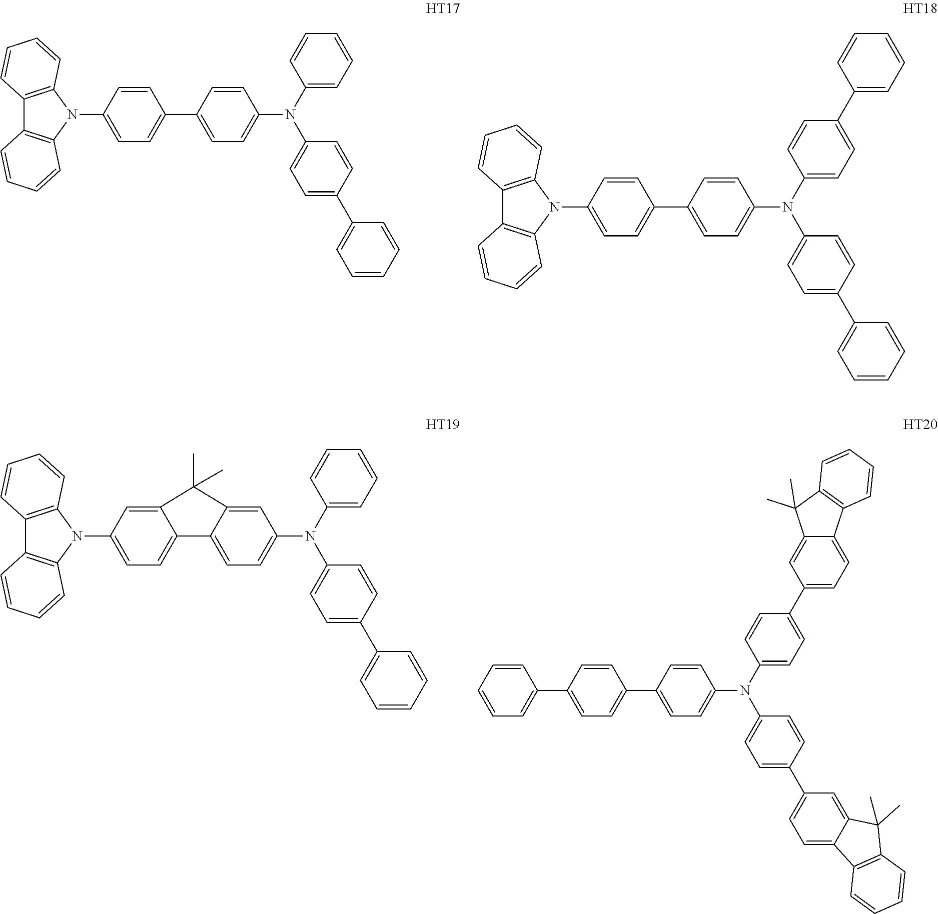 [SMILES: c1ccc(-c2ccc(N(c3ccccc3)c3ccc(-c4ccc(-n5c6ccccc6c6ccccc65)cc4)cc3)cc2)cc1 ; c1ccc(-c2ccc(N(c3ccc(-c4ccccc4)cc3)c3ccc(-c4ccc(-n5c6ccccc6c6ccccc65)cc4)cc3)cc2)cc1 ; CC1(C)c2cc(N(c3ccccc3)c3ccc(-c4ccccc4)cc3)ccc2-c2ccc(-n3c4ccccc4c4ccccc43)cc21 ; CC1(C)c2ccccc2-c2ccc(-c3ccc(N(c4ccc(-c5ccc(-c6ccccc6)cc5)cc4)c4ccc(-c5ccc6c(c5)C(C)(C)c5ccccc5-6)cc4)cc3)cc21]

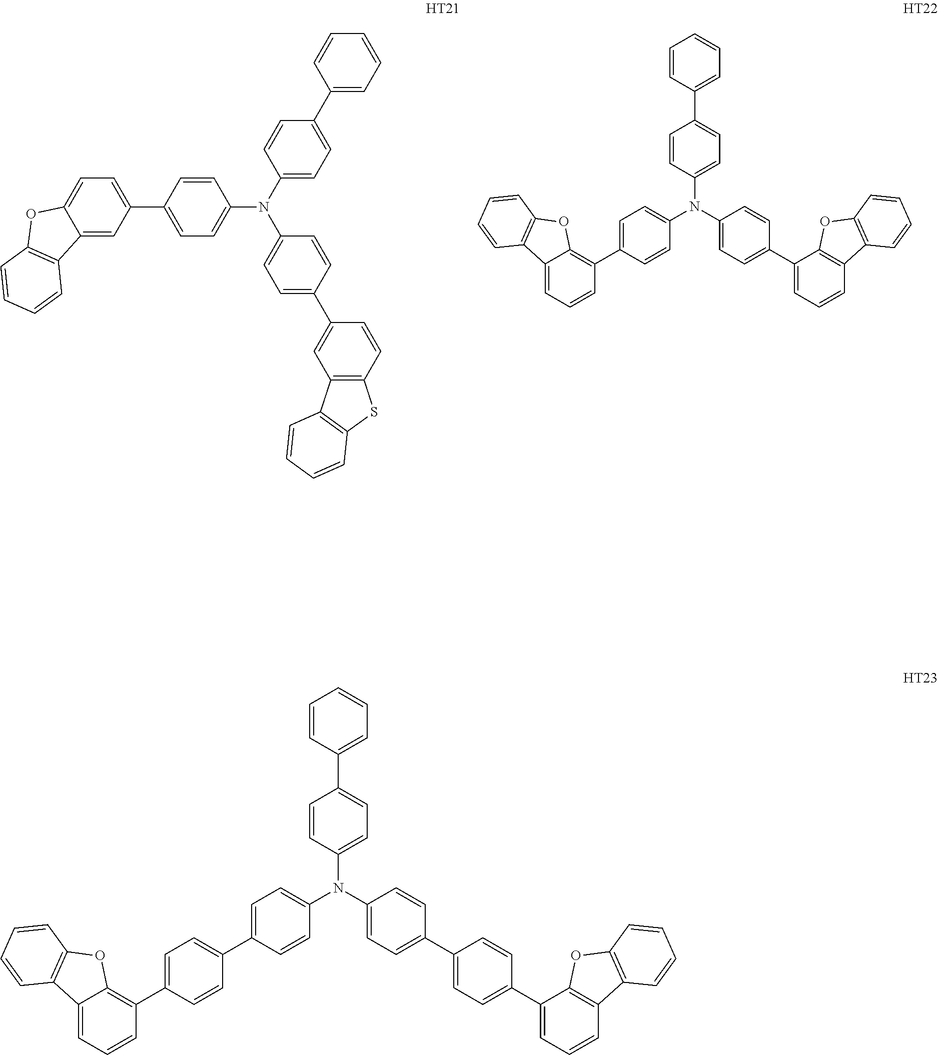 [SMILES: c1ccc(-c2ccc(N(c3ccc(-c4ccc5oc6ccccc6c5c4)cc3)c3ccc(-c4ccc5sc6ccccc6c5c4)cc3)cc2)cc1 ; c1ccc(-c2ccc(N(c3ccc(-c4cccc5c4oc4ccccc45)cc3)c3ccc(-c4cccc5c4oc4ccccc45)cc3)cc2)cc1 ; c1ccc(-c2ccc(N(c3ccc(-c4ccc(-c5cccc6c5oc5ccccc56)cc4)cc3)c3ccc(-c4ccc(-c5cccc6c5oc5ccccc56)cc4)cc3)cc2)cc1]

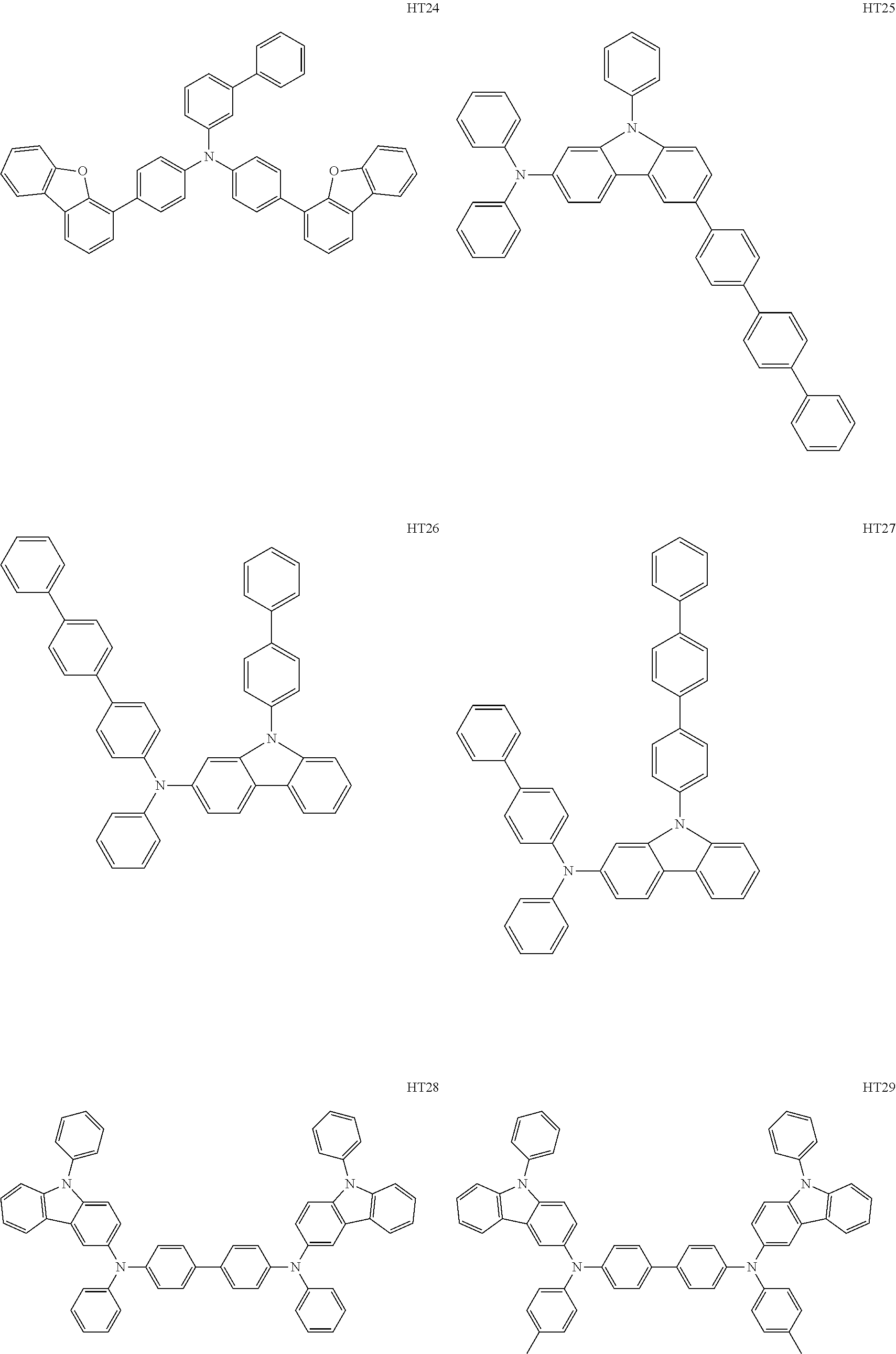

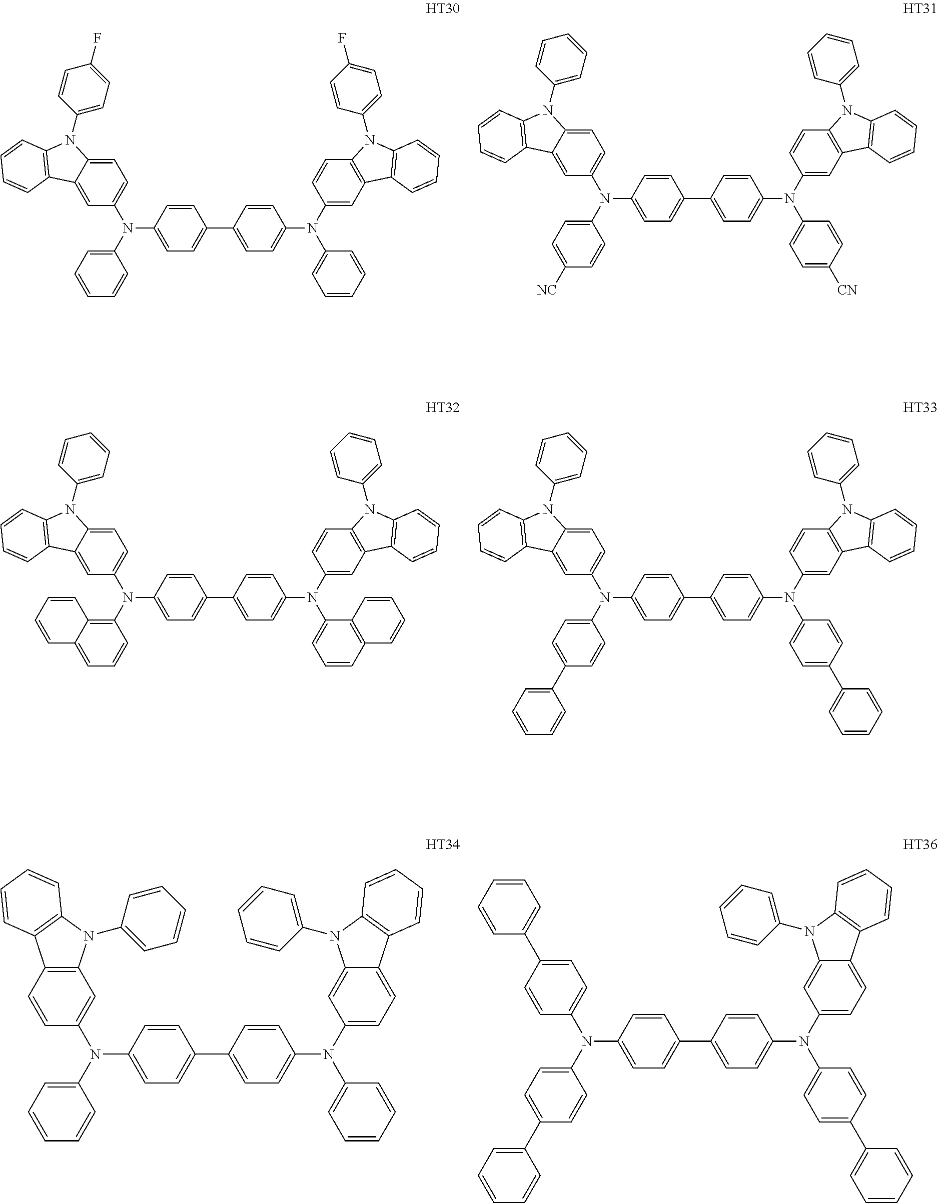

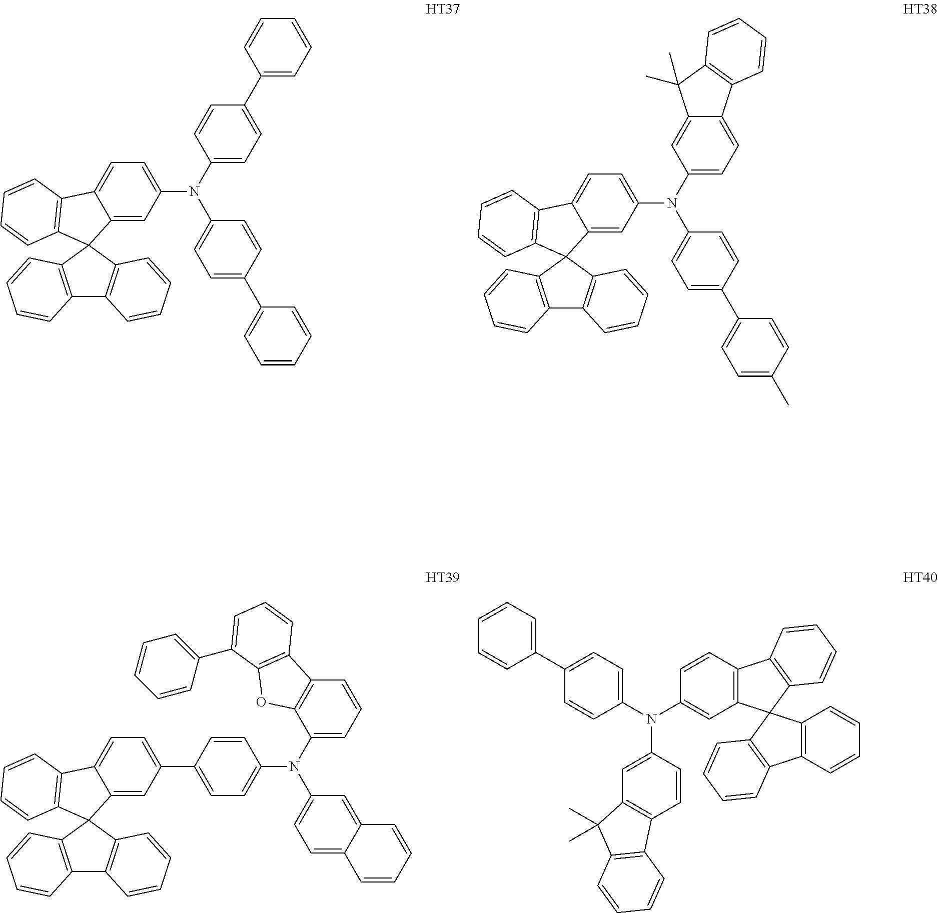 [SMILES: c1ccc(-c2ccc(N(c3ccc(-c4ccccc4)cc3)c3ccc4c(c3)C3(c5ccccc5-c5ccccc53)c3ccccc3-4)cc2)cc1 ; Cc1ccc(-c2ccc(N(c3ccc4c(c3)C(C)(C)c3ccccc3-4)c3ccc4c(c3)C3(c5ccccc5-c5ccccc53)c3ccccc3-4)cc2)cc1 ; c1ccc(-c2cccc3c2oc2c(N(c4ccc(-c5ccc6c(c5)C5(c7ccccc7-c7ccccc75)c5ccccc5-6)cc4)c4ccc5ccccc5c4)cccc23)cc1 ; CC1(C)c2ccccc2-c2ccc(N(c3ccc(-c4ccccc4)cc3)c3ccc4c(c3)C3(c5ccccc5-c5ccccc53)c3ccccc3-4)cc21]

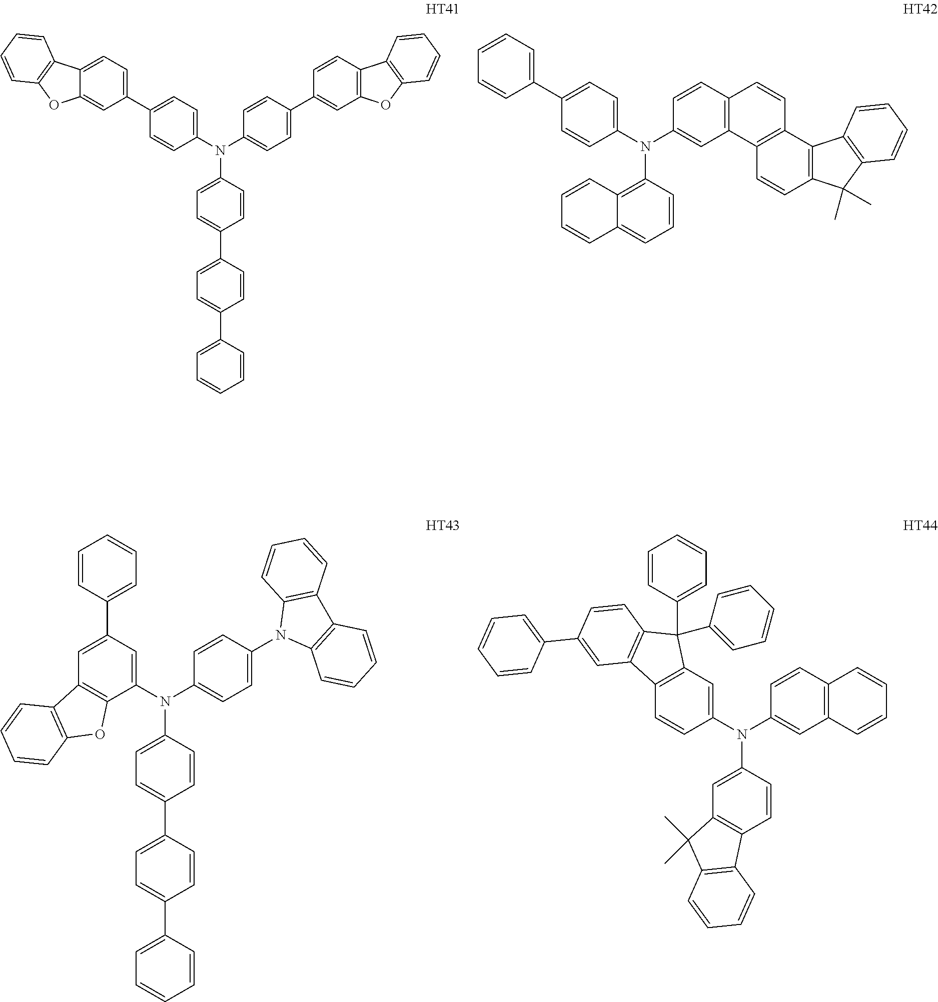

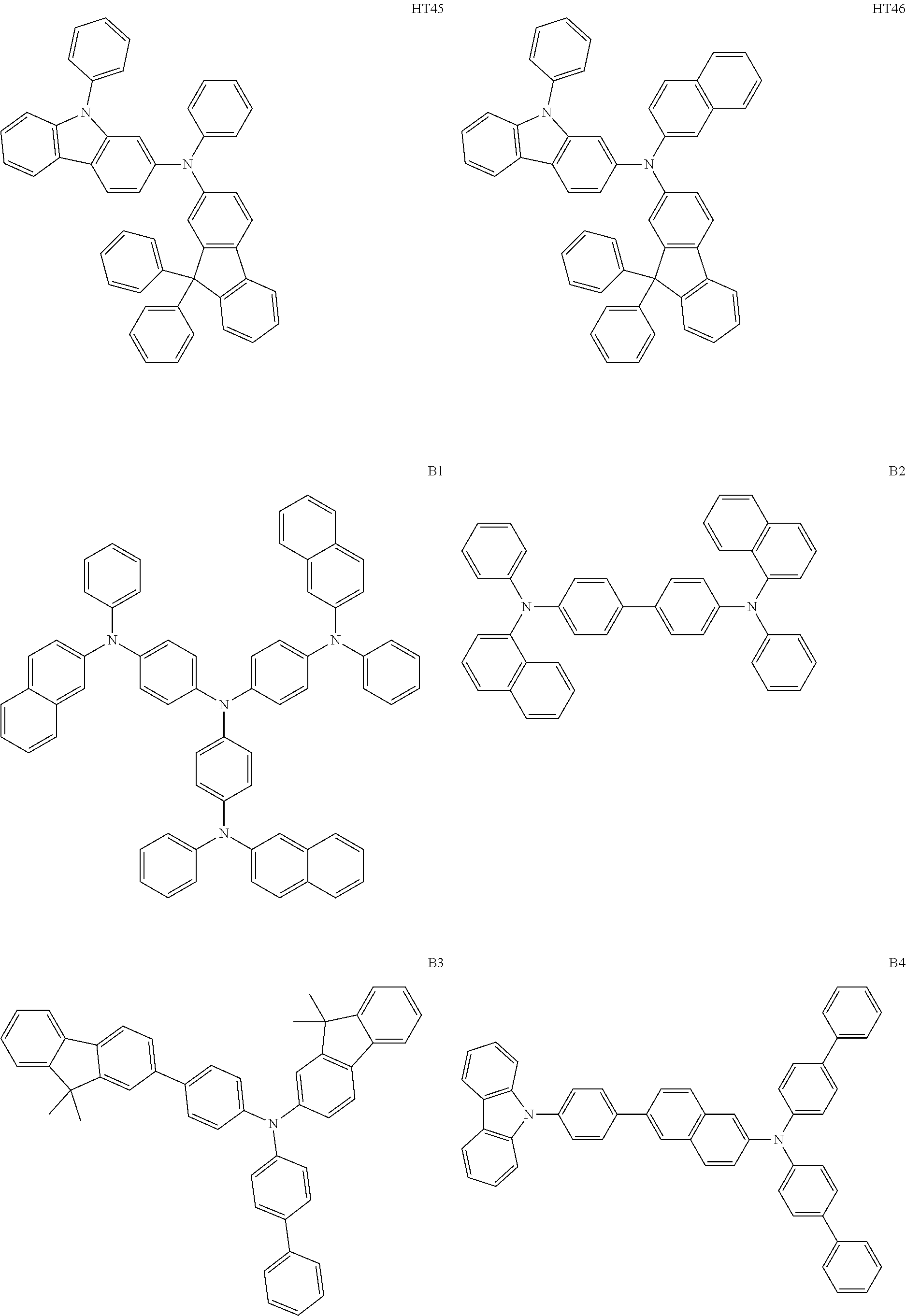

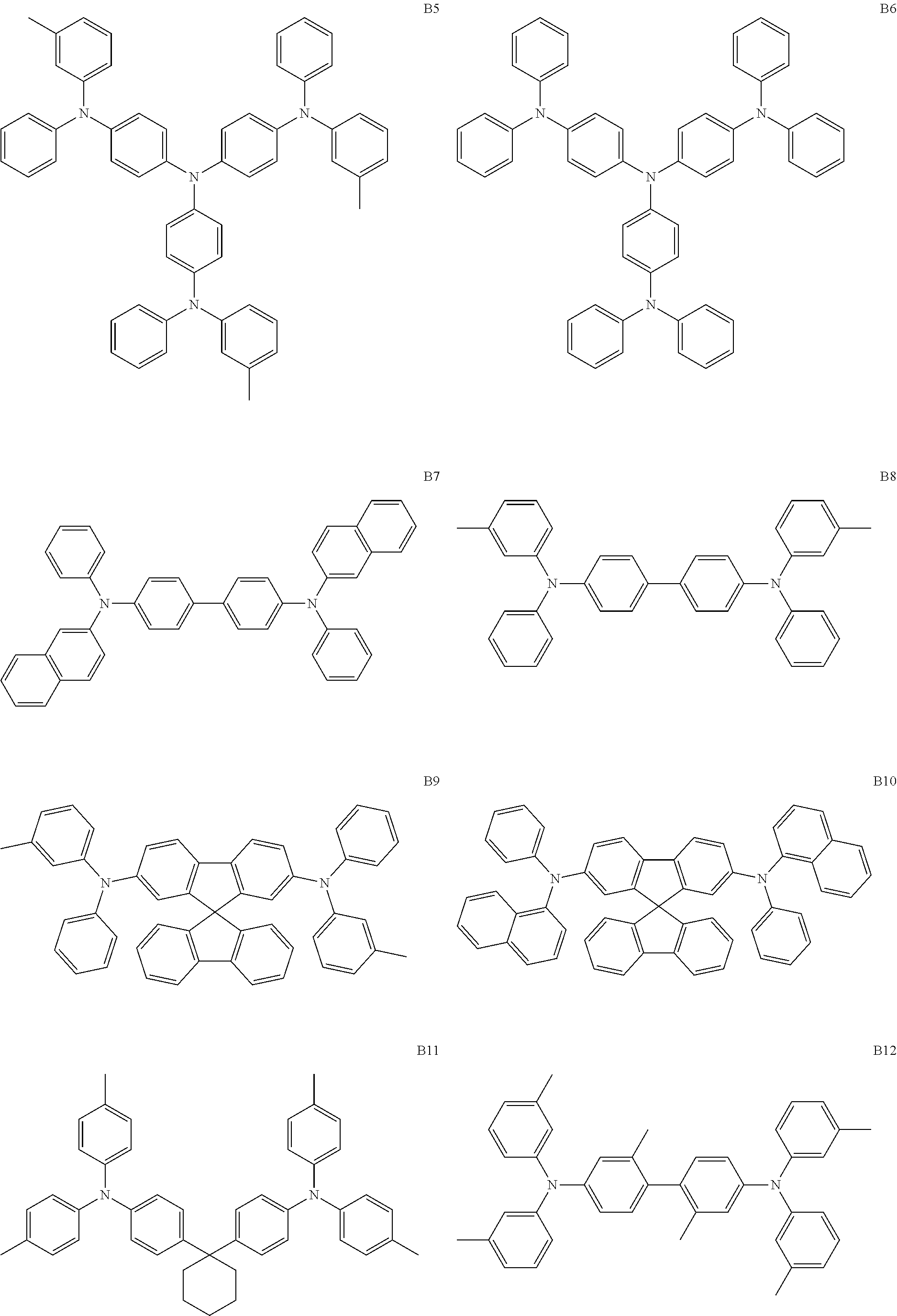

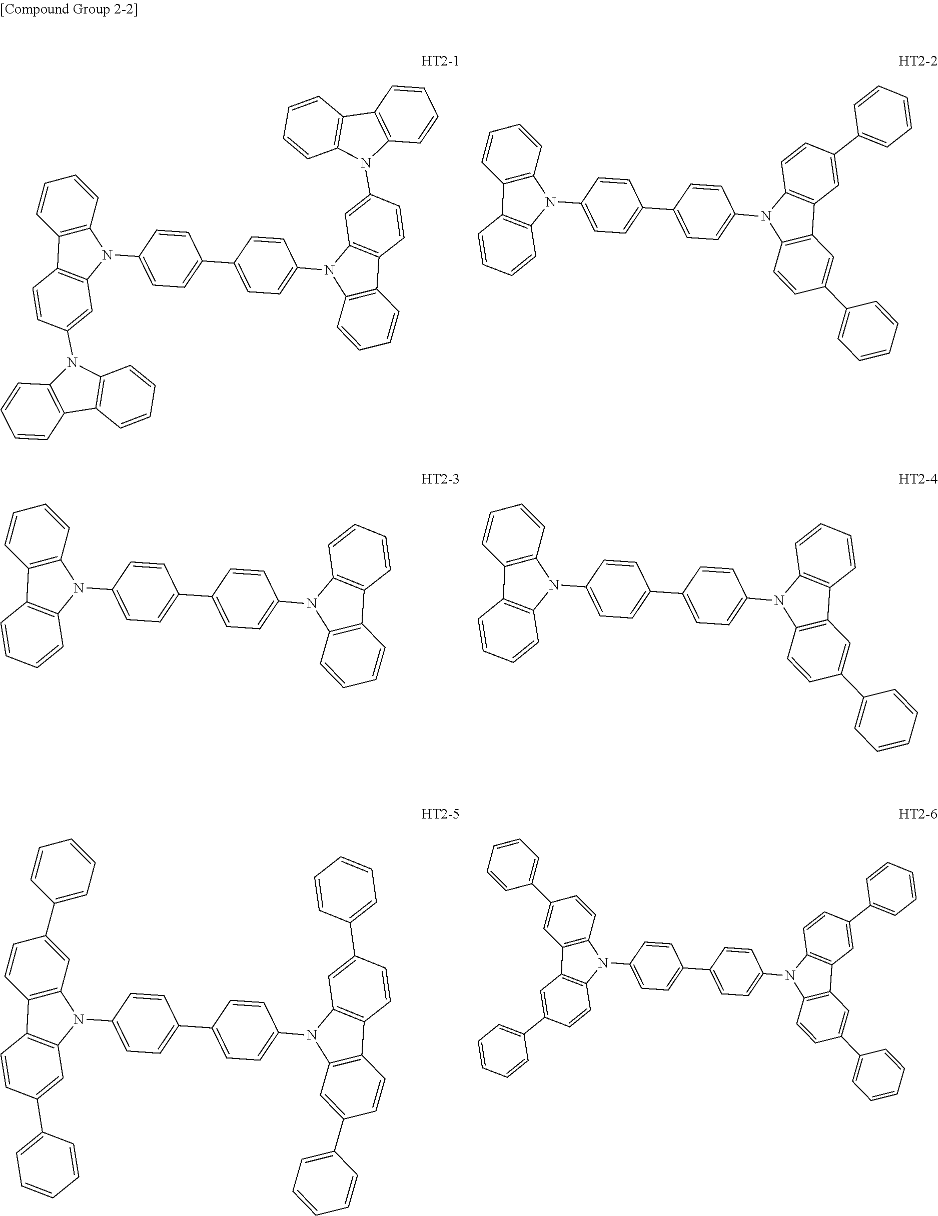

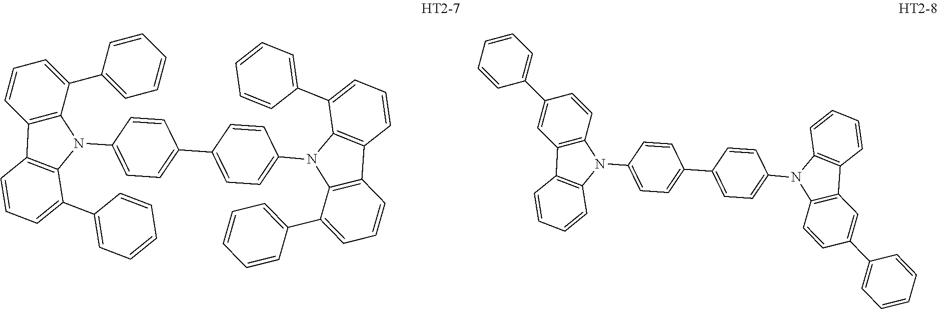 [SMILES: c1ccc(-c2cccc3c4cccc(-c5ccccc5)c4n(-c4ccc(-c5ccc(-n6c7c(-c8ccccc8)cccc7c7cccc(-c8ccccc8)c76)cc5)cc4)c23)cc1 ; c1ccc(-c2ccc3c(c2)c2ccccc2n3-c2ccc(-c3ccc(-n4c5ccccc5c5cc(-c6ccccc6)ccc54)cc3)cc2)cc1]

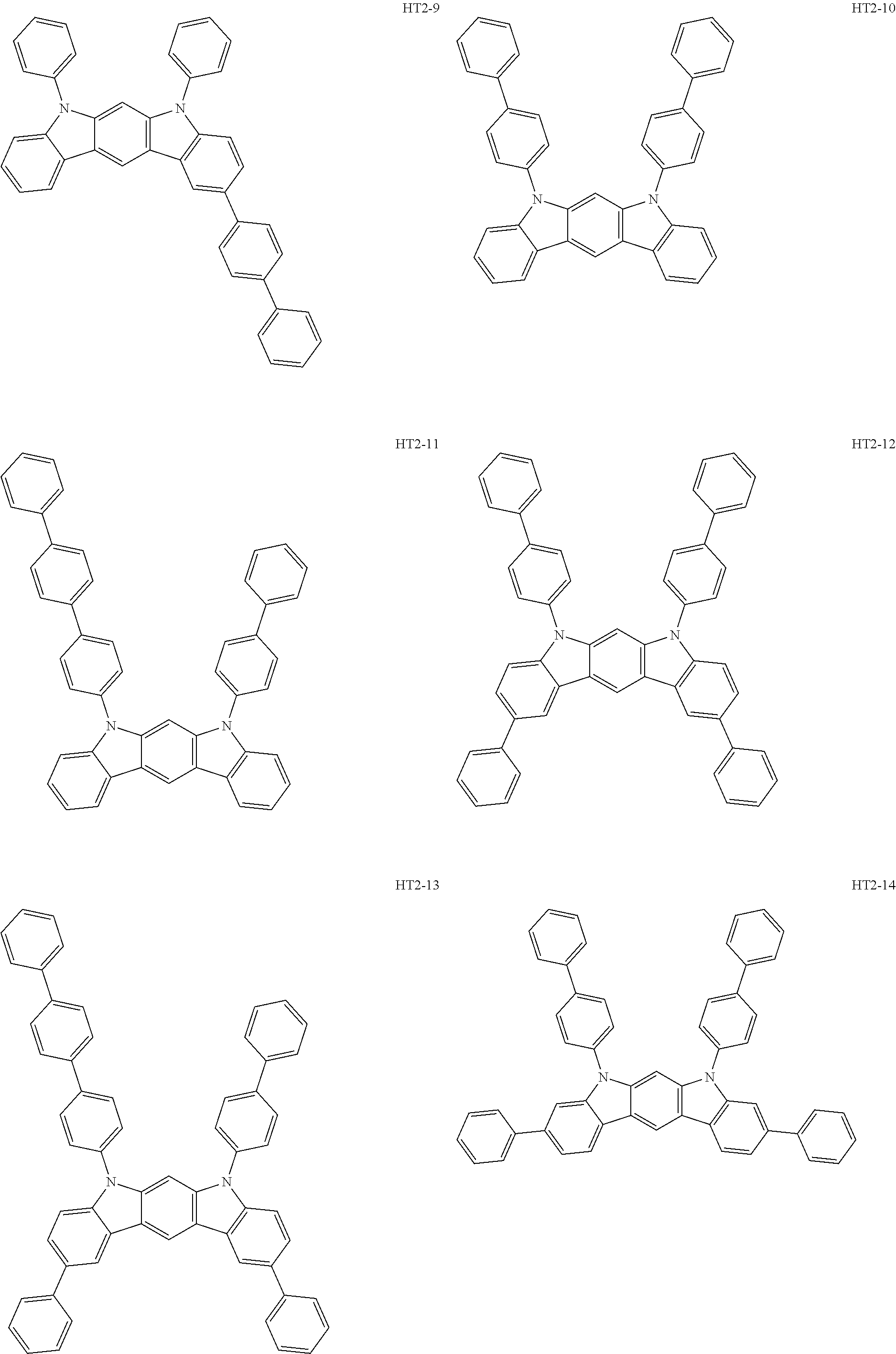

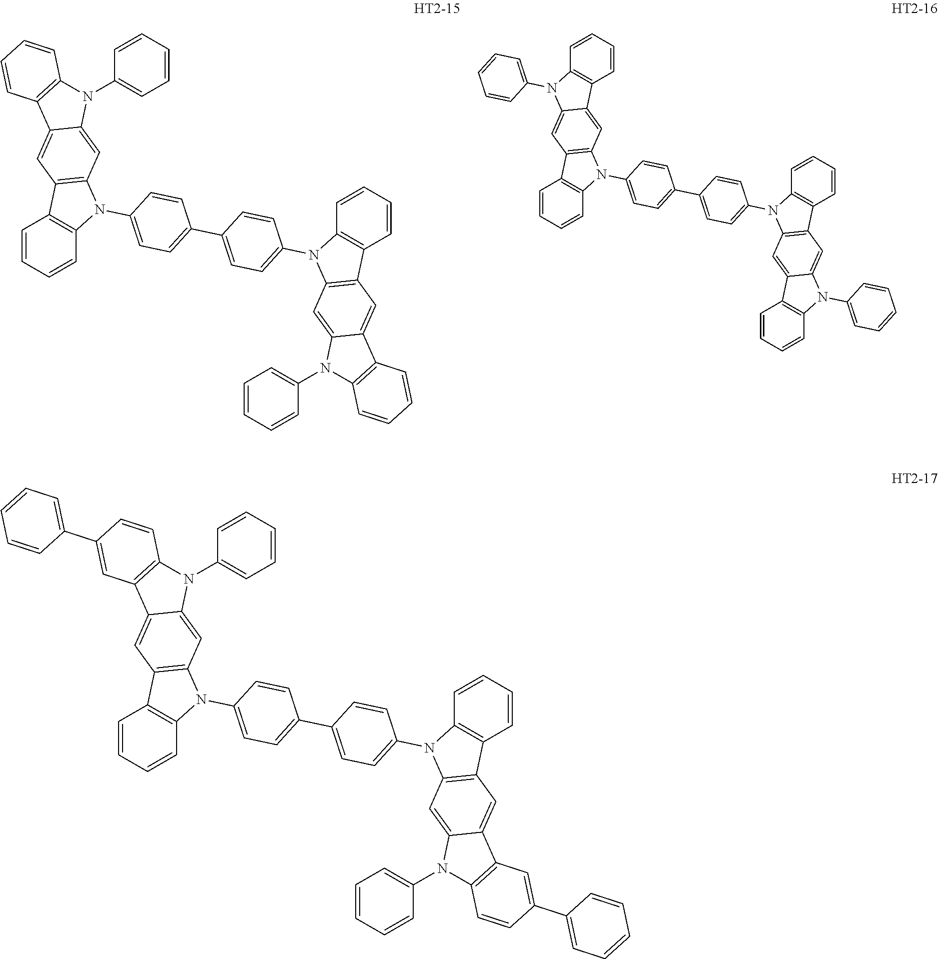 [SMILES: c1ccc(-n2c3ccccc3c3cc4c5ccccc5n(-c5ccc(-c6ccc(-n7c8ccccc8c8cc9c%10ccccc%10n(-c%10ccccc%10)c9cc87)cc6)cc5)c4cc32)cc1 ; c1ccc(-n2c3ccccc3c3cc4c(cc32)c2ccccc2n4-c2ccc(-c3ccc(-n4c5ccccc5c5cc6c(cc54)c4ccccc4n6-c4ccccc4)cc3)cc2)cc1 ; c1ccc(-c2ccc3c(c2)c2cc4c5ccccc5n(-c5ccc(-c6ccc(-n7c8ccccc8c8cc9c%10cc(-c%11ccccc%11)ccc%10n(-c%10ccccc%10)c9cc87)cc6)cc5)c4cc2n3-c2ccccc2)cc1]

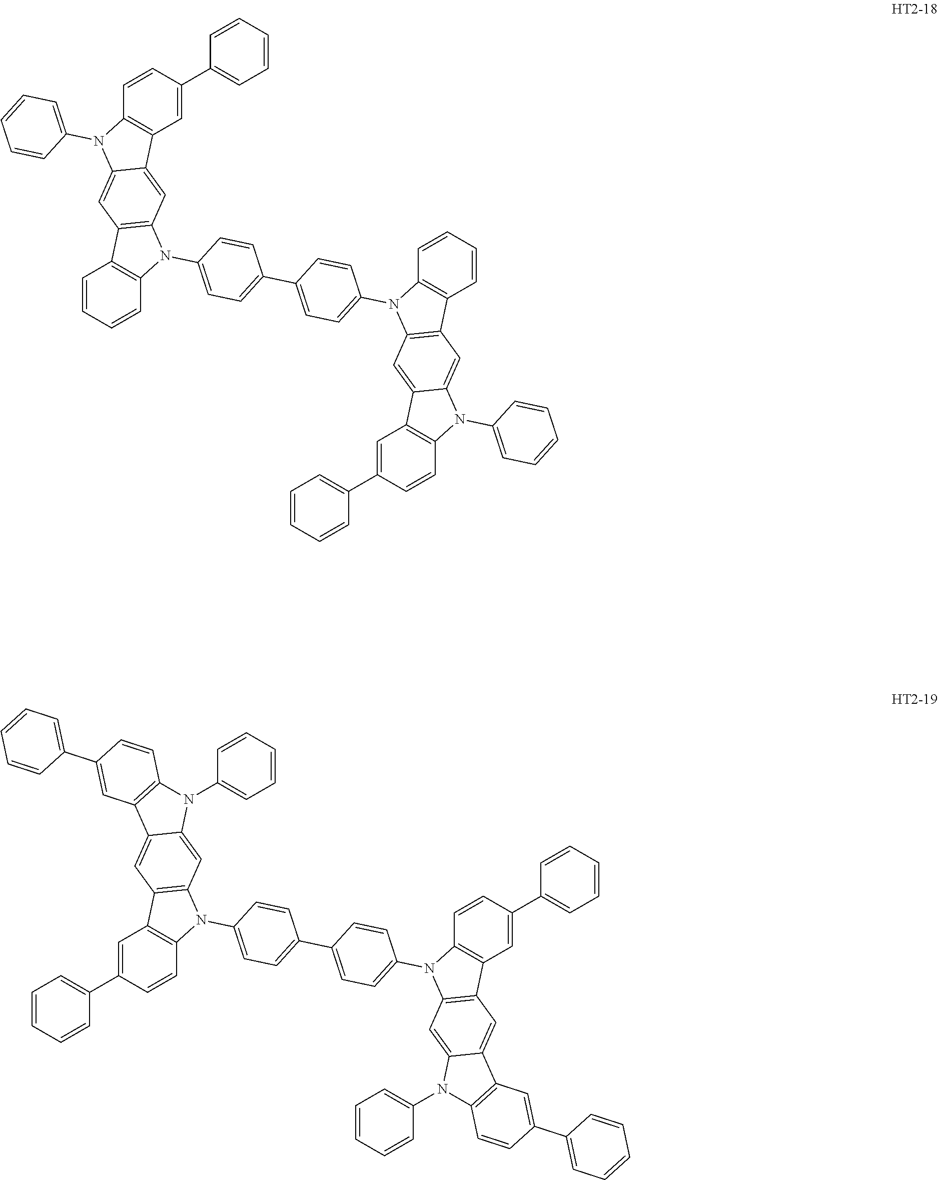 [SMILES: c1ccc(-c2ccc3c(c2)c2cc4c(cc2n3-c2ccccc2)c2ccccc2n4-c2ccc(-c3ccc(-n4c5ccccc5c5cc6c(cc54)c4cc(-c5ccccc5)ccc4n6-c4ccccc4)cc3)cc2)cc1 ; c1ccc(-c2ccc3c(c2)c2cc4c5cc(-c6ccccc6)ccc5n(-c5ccc(-c6ccc(-n7c8ccc(-c9ccccc9)cc8c8cc9c%10cc(-c%11ccccc%11)ccc%10n(-c%10ccccc%10)c9cc87)cc6)cc5)c4cc2n3-c2ccccc2)cc1]

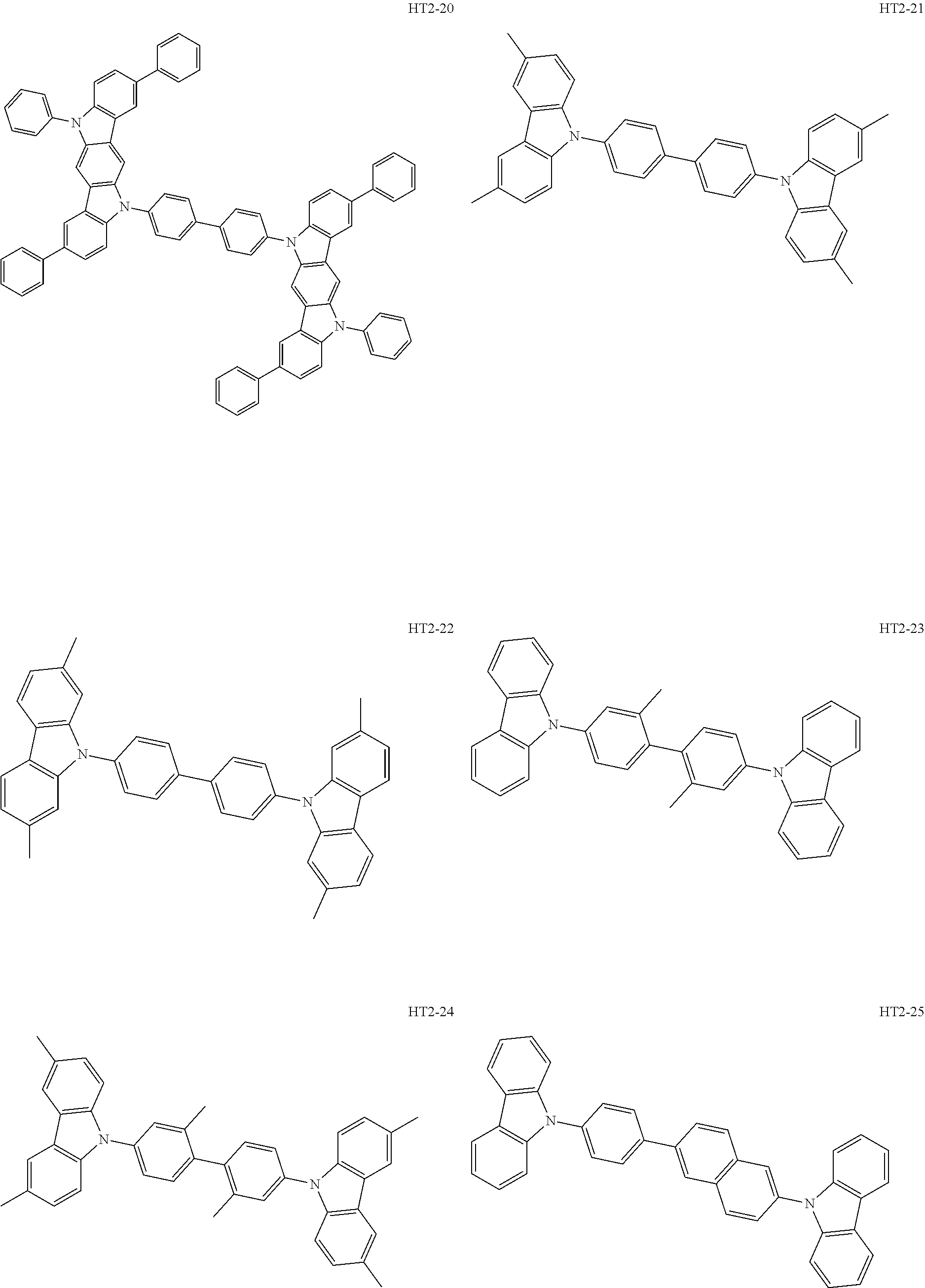

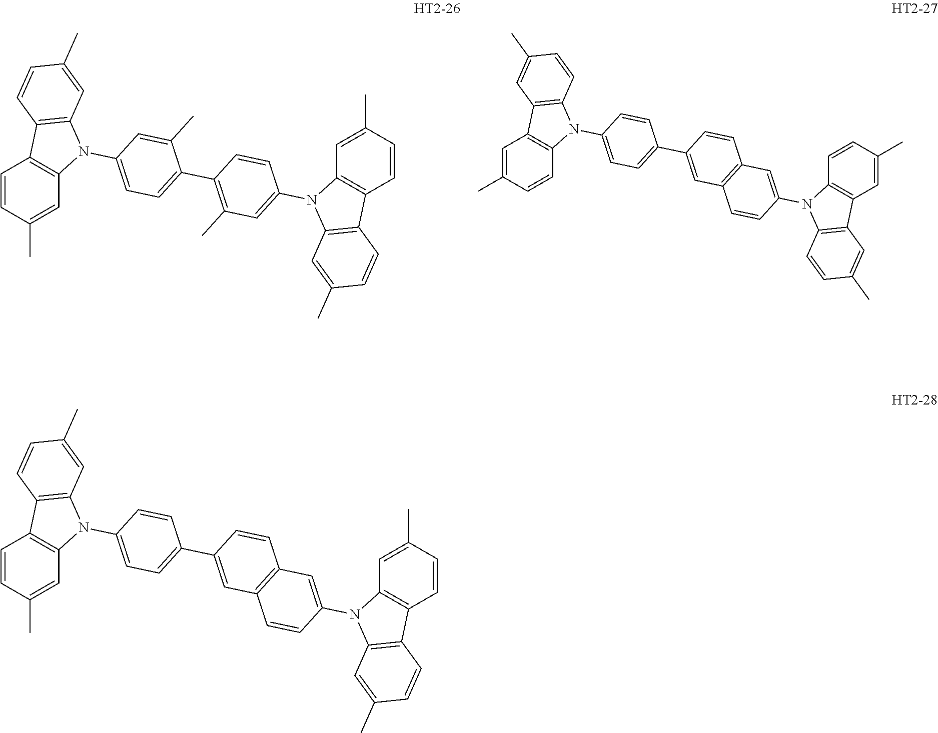

The hole transport region HTR of the light-emitting element ED according to an embodiment may include the first hole transport layer HTL1 including the first compound and the second compound, and the second hole transport layer HTL2 including the second compound.

The first compound included in the first hole transport layer HTL1 according to an embodiment may have a structure which includes a core nitrogen atom, and first to third substituents connected to the core nitrogen atom, and in which at least one among the first to third substituents is substituted for (e.g., may be or may be substituted with) a cycloalkyl group, or a structure in which the first to third substituents are connected to the core nitrogen atom through a phenylene linker so as to be in an ortho relation or a meta relation with the core nitrogen atom. The first compound having such a structure may have low refractive index characteristics due to low stacking density caused by reduced molecular interaction. Accordingly, the first hole transport layer HTL1 in which the first compound and the second compound are all applied may show high hole transport characteristics, and a lower refractive index than the first hole transport layer HTL1 in which only the second compound is applied. Accordingly, a refractive index difference between the first electrode EL1 and the first hole transport layer HTL1 may become small, and thus light loss caused by the total reflection and/or a refraction phenomenon caused by the refractive index difference between thin films in the light extraction process may be prevented or reduced. The light-emitting element ED in which the first hole transport layer HTL1 including the first compound is applied may have improved luminous efficiency and lifespan.

In embodiments, the light-emitting element ED according to an embodiment may include the second hole transport layer HTL2 including the second compound on the first hole transport layer HTL1 to change a refractive index and a light extraction mode between the first electrode and the second electrode, thereby increasing external quantum efficiency. Accordingly, the light-emitting element ED according to an embodiment may include, between the first electrode EL1 and the light-emitting layer EML, hole transport layers stacked in a sequence of the first hole transport layer HTL1/the second hole transport layer HTL2 to realize high efficiency and long lifespan.

The first compound may have a content equal to or more than about 10% by weight in the first hole transport layer HTL1 with respect to the total weight of the first compound and the second compound. For example, the first compound may have a content of about 10% to about 95% by weight, but an embodiment is not limited thereto. When the content (e.g., amount) of the first compound satisfies the ratio described above, hole transport characteristics may be improved while minimizing or reducing the refractive index difference between the first hole transport layer HTL1 and the first electrode EL1 to increase luminous efficiency and element lifespan.

In an embodiment, an absolute value of a difference between a highest occupied molecular orbital (HOMO) energy level of the first compound and a highest occupied molecular orbital (HOMO) energy level of the second compound may be equal to or less than about 0.5 eV, but an embodiment is not limited thereto. For example, the absolute value of a difference between a highest occupied molecular orbital (HOMO) energy level of the first compound and a highest occupied molecular orbital (HOMO) energy level of the second compound may be about 0.05 eV to about 0.3 eV. Because when the absolute value of a difference between a highest occupied molecular orbital (HOMO) energy level of the first compound and a highest occupied molecular orbital (HOMO) energy level of the second compound satisfies the range described above, a highest occupied molecular orbital (HOMO) energy level difference between the first compound and the second compound becomes small, the hole transport characteristics of the first hole transport layer HTL1 in which the first compound and the second compound are mixed together may be improved to exhibit excellent luminous efficiency and improved element lifespan characteristics.

In an embodiment, an absolute value of a difference between a lowest unoccupied molecular orbital (LUMO) energy level of the first compound and a lowest unoccupied molecular orbital (LUMO) energy level of the second compound may be equal to or less than about 0.5 eV. For example, the absolute value of a difference between a lowest unoccupied molecular orbital (LUMO) energy level of the first compound and a lowest unoccupied molecular orbital (LUMO) energy level of the second compound may be about 0.05 eV to about 0.3 eV, but an embodiment of the present disclosure is not limited thereto.

In embodiments, the light emitting device ED of an embodiment may further include a material of a hole transport region further explained below in the hole transport region HTR in addition to the first compound and the second compound of an embodiment, described above.

The hole transport region HTR may include a phthalocyanine compound such as copper phthalocyanine; N¹,N^{1′}-([1,1′-biphenyl]-4,4′-diyl)bis(N¹-phenyl-N⁴,N⁴-di-m-tolylbenzene-1,4-diamine) (DNTPD), 4,4′,4″-[tris(3-methylphenyl)phenylamino]triphenylamine (m-MTDATA), 4,4′,4″-tris(N,N-diphenylamino)triphenylamine (TDATA), 4,4′,4″-tris[N(2-naphthyl)-N-phenylamino]-triphenylamine (2-TNATA), poly(3,4-ethylenedioxythiophene)/poly(4-styrenesulfonate) (PEDOT/PSS), polyaniline/dodecylbenzenesulfonic acid (PANI/DBSA), polyaniline/camphor sulfonic acid (PANI/CSA), polyaniline/poly(4-styrenesulfonate) (PANI/PSS), N,N′-di(naphthalene-1-yl)-N,N′-diphenyl-benzidine (NPB), triphenylamine-containing polyetherketone (TPAPEK), 4-isopropyl-4′-methyldiphenyliodonium [tetrakis(pentafluorophenyl)borate], dipyrazino[2,3-f: 2′,3′-h]quinoxaline-2,3,6,7,10,11-hexacarbonitrile (HATCN), etc.

The hole transport region HTR may include a carbazole-based derivative such as N-phenyl carbazole and/or polyvinyl carbazole, a fluorene-based derivative, a triphenylamine-based derivative such as N,N′-bis(3-methylphenyl)-N,N′-diphenyl-[1,1-biphenyl]-4,4′-diamine (TPD) and/or 4,4′,4″-tris(N-carbazolyl)triphenylamine (TCTA), N,N′-di(naphthalene-1-yl)-N,N′-diphenyl-benzidine (NPB), 4,4′-cyclohexylidene bis[N,N-bis(4-methylphenyl]benzenamine] (TAPC), 4,4′-bis[N,N′-(3-tolyl)amino]-3,3′-dimethylbiphenyl (HMTPD), 1,3-bis(N-carbazolyl)benzene (mCP), etc.

In embodiments, the hole transport region HTR may include 9-(4-tert-butylphenyl)-3,6-bis(triphenylsilyl)-9H-carbazole (CzSi), 9-phenyl-9H-3,9′-bicarbazole (CCP), 1,3-bis(1,8-dimethyl-9H-carbazol-9-yl)benzene (mDCP), etc.

The hole transport region HTR may include the above-described compounds of the hole transport region in at least one of a hole injection layer HIL, a first hole transport layer HTL1, a second hole transport layer HTL2, or an electron blocking layer EBL.

The thickness of the hole transport region HTR may be from about 100 Å to about 10,000 Å, for example, from about 100 Å to about 5,000 Å. When the hole transport region HTR includes the hole injection layer HIL, the hole injection layer HIL may have, for example, a thickness of about 30 Å to about 1,000 Å. When the hole transport region HTR includes the hole transport layer HTL, the hole transport layer HTL may have a thickness of about 250 Å to about 1,000 Å. For example, when the hole transport region HTR includes the electron blocking layer EBL, the electron blocking layer EBL may have a thickness of about 10 Å to about 1,000 Å. If the thicknesses of the hole transport region HTR, the hole injection layer HIL, the hole transport layer HTL and the electron blocking layer EBL satisfy the above-described ranges, suitable or satisfactory hole transport properties may be achieved without a substantial increase in driving voltage.

The hole transport region HTR may further include a charge generating material to increase conductivity (e.g., electrical conductivity) in addition to the above-described materials. The charge generating material may be dispersed uniformly or non-uniformly in the hole transport region HTR. The charge generating material may be, for example, a p-dopant. The p-dopant may include at least one of a halogenated metal compound, a quinone derivative, a metal oxide, or a cyano group-containing compound, but an embodiment of the present disclosure is not limited thereto. For example, the p-dopant may include a metal halide compound such as CuI and/or RbI, a quinone derivative such as tetracyanoquinodimethane (TCNQ) and/or 2,3,5,6-tetrafluoro-7,7′8,8-tetracyanoquinodimethane (F4-TCNQ), a metal oxide such as tungsten oxide and/or molybdenum oxide, a cyano group-containing compound such as dipyrazino[2,3-f: 2′,3′-h]quinoxaline-2,3,6,7,10,11-hexacarbonitrile (HATCN) and/or 4-[[2,3-bis[cyano-(4-cyano-2,3,5,6-tetrafluorophenyl)methylidene]cyclopropylidene]-cyanomethyl]-2,3,5,6-tetrafluorobenzonitrile (NDP9), etc., but an embodiment of the present disclosure is not limited thereto.

As described above, the hole transport region HTR may further include at least one of the buffer layer or the electron blocking layer EBL in addition to the hole injection layer HIL and the first and second hole transport layers HTL1 and HTL2. The buffer layer may compensate for a resonance distance according to the wavelength of light emitted from the light-emitting layer EML and may thus increase light emission efficiency. A material that may be included in the hole transport region HTR may be used as a material to be included in the buffer layer. The electron blocking layer EBL is a layer that serves to prevent or reduce electron injection from the electron transport region ETR to the hole transport region HTR.

The light-emitting layer EML is provided on the hole transport region HTR. The light-emitting layer EML may have, for example, a thickness of about 100 Å to about 1000 Å or about 100 Å to about 300 Å. The light-emitting layer EML may have a single layer formed of a single material, a single layer formed of a plurality of different materials, or a multilayer structure having a plurality of layers formed of a plurality of different materials.

In the light emitting element ED according to an embodiment, the light-emitting layer EML may emit blue light. The light emitting element ED according to an embodiment may include the hole transport region HTR including the first hole transport layer HTL1 including above-described the first and second compounds according to an embodiment and the second hole transport layer HTL2 including the second compound to exhibit high luminous efficiency and long lifetime characteristics in the blue light-emitting region. However, an embodiment of the present disclosure is not limited thereto, the light-emitting layer EML may emit green light or red light.

In the light emitting element ED of an embodiment, the light-emitting layer EML may include anthracene derivatives, pyrene derivatives, fluoranthene derivatives, chrysene derivatives, dihydrobenzanthracene derivatives, and/or triphenylene derivatives. In embodiments, the light-emitting layer EML may include anthracene derivatives and/or pyrene derivatives.

In the light emitting elements ED of embodiments, shown in FIG. 3 to FIG. 6, the light-emitting layer EML may include a host and a dopant. For example, the light-emitting layer EML may include a compound represented by Formula E-1 below. The compound represented by Formula E-1 below may be used as a fluorescence host material.

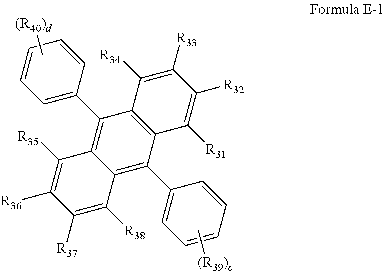

In Formula E-1, R₃₁ to R₄₀ may be each independently a hydrogen atom, a deuterium atom, a halogen atom, a substituted or unsubstituted silyl group, a substituted or unsubstituted thiol group, a substituted or unsubstituted oxy group, a substituted or unsubstituted alkyl group of 1 to 10 carbon atoms, a substituted or unsubstituted alkenyl group of 2 to 10 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring. In embodiments, R₃₁ to R₄₀ may be combined with an adjacent group to form a saturated hydrocarbon ring, an unsaturated hydrocarbon ring, a saturated heterocycle or an unsaturated heterocycle.

In Formula E-1, “c” and “d” may be each independently an integer of 0 to 5.

Formula E-1 may be represented by any one among Compound E1 to Compound E19 below.

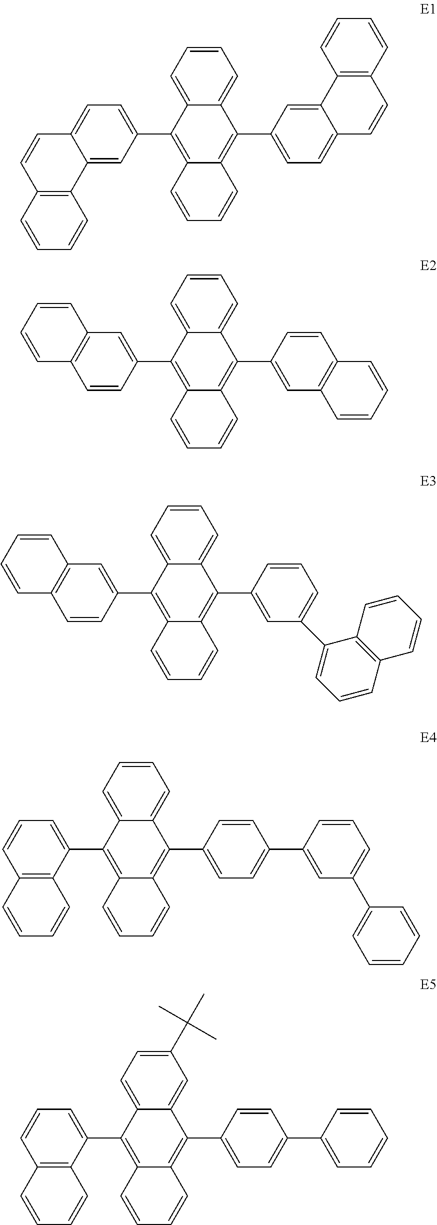

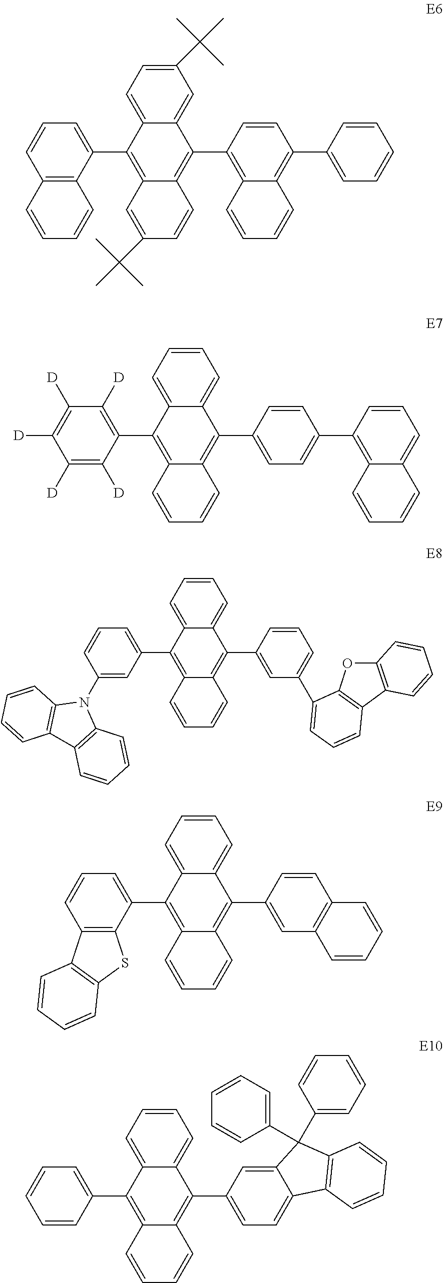

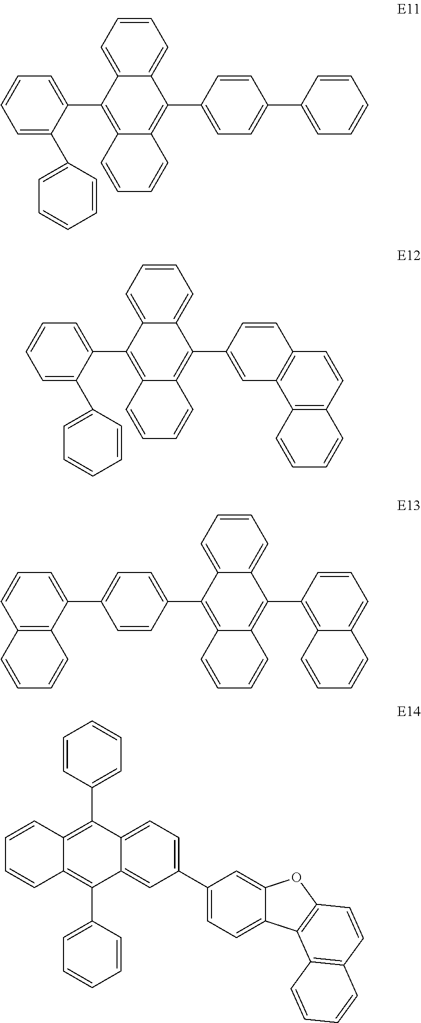

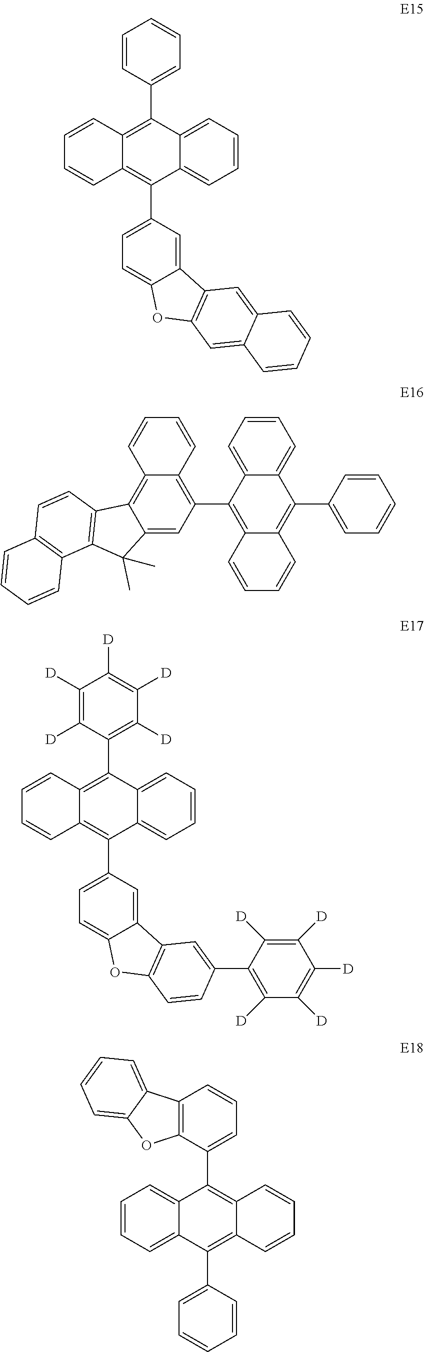

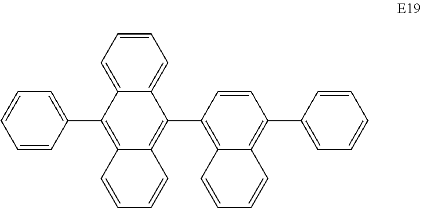 [SMILES: c1ccc(-c2ccc(-c3c4ccccc4c(-c4ccccc4)c4ccccc34)c3ccccc23)cc1]

In an embodiment, the light-emitting layer EML may include a compound represented by Formula E-2a or Formula E-2b below. The compound represented by Formula E-2a or Formula E-2b may be used as a phosphorescence host material.

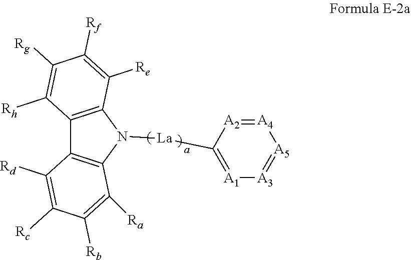

In Formula E-2a, “a” may be an integer of 0 to 10, Lₐ may be a direct linkage, a substituted or unsubstituted arylene group of 6 to 30 ring-forming carbon atoms, or a substituted or unsubstituted heteroarylene group of 2 to 30 ring-forming carbon atoms. In embodiments, if “a” is an integer of 2 or more, a plurality of Lₐ may be each independently a substituted or unsubstituted arylene group of 6 to 30 ring-forming carbon atoms, or a substituted or unsubstituted heteroarylene group of 2 to 30 ring-forming carbon atoms.

In embodiments, in Formula E-2a, A₁ to A₅ may be each independently N or CRi. Rₐ to Rᵢ may be each independently a hydrogen atom, a deuterium atom, a substituted or unsubstituted amine group, a substituted or unsubstituted thiol group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. Rₐ to Rᵢ may be combined with an adjacent group to form a hydrocarbon ring or a heterocycle including N, O, S, etc. as a ring-forming atom.

In embodiments, in Formula E-2a, two or three selected from A₁ to A₅ may be N, and the remainder may be CRᵢ.

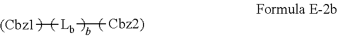

In Formula E-2b, Cbz1 and Cbz2 may be each independently an unsubstituted carbazole group, or a carbazole group substituted with an aryl group of 6 to 30 ring-forming carbon atoms. L_{b} may be a direct linkage (e.g., a covalent bond), a substituted or unsubstituted arylene group of 6 to 30 ring-forming carbon atoms, or a substituted or unsubstituted heteroarylene group of 2 to 30 ring-forming carbon atoms. “b” is an integer of 0 to 10, and if “b” is an integer of 2 or more, a plurality of L_{b} may be each independently a substituted or unsubstituted arylene group of 6 to 30 ring-forming carbon atoms, or a substituted or unsubstituted heteroarylene group of 2 to 30 ring-forming carbon atoms.

The compound represented by Formula E-2a or Formula E-2b may be represented by any one among the compounds in Compound Group E-2 below. However, the compounds shown in Compound Group E-2 are only illustrations, and the compound represented by Formula E-2a or Formula E-2b is not limited to the compounds represented in Compound Group E-2.

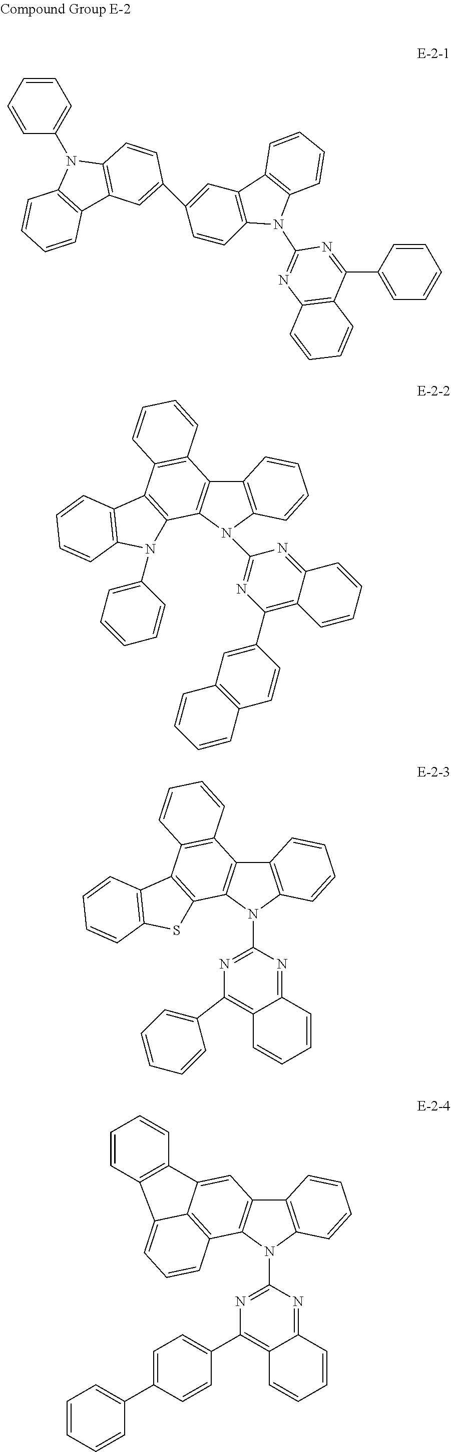

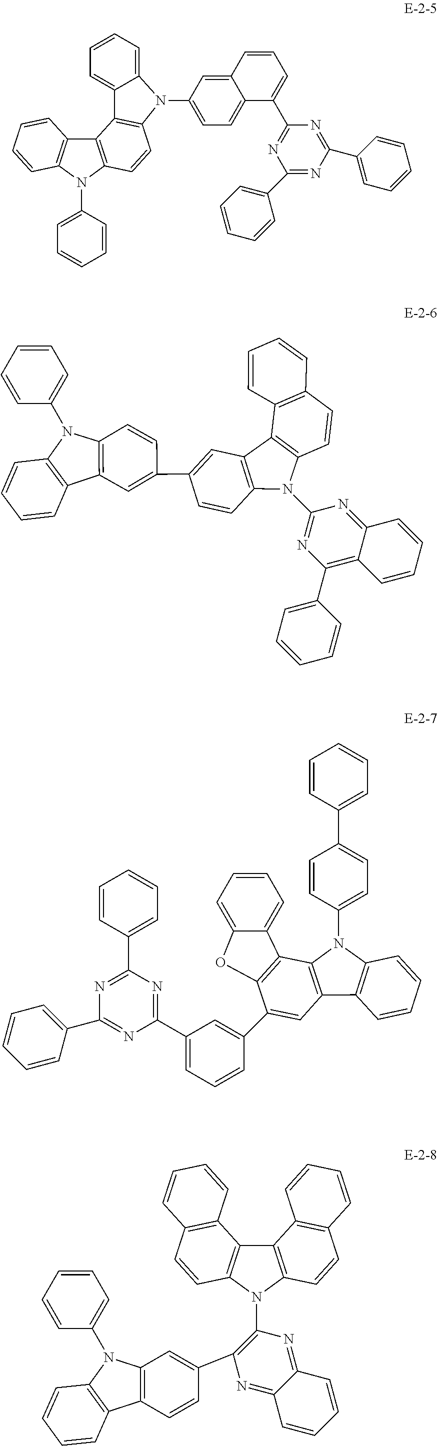 [SMILES: c1ccc(-c2nc(-c3ccccc3)nc(-c3cccc4cc(-n5c6ccccc6c6c7c8ccccc8n(-c8ccccc8)c7ccc65)ccc34)n2)cc1 ; c1ccc(-c2nc(-n3c4ccc(-c5ccc6c(c5)c5ccccc5n6-c5ccccc5)cc4c4c5ccccc5ccc43)nc3ccccc23)cc1 ; c1ccc(-c2ccc(-n3c4ccccc4c4cc(-c5cccc(-c6nc(-c7ccccc7)nc(-c7ccccc7)n6)c5)c5oc6ccccc6c5c43)cc2)cc1 ; c1ccc(-n2c3ccccc3c3ccc(-c4nc5ccccc5nc4-n4c5ccc6ccccc6c5c5c6ccccc6ccc54)cc32)cc1]

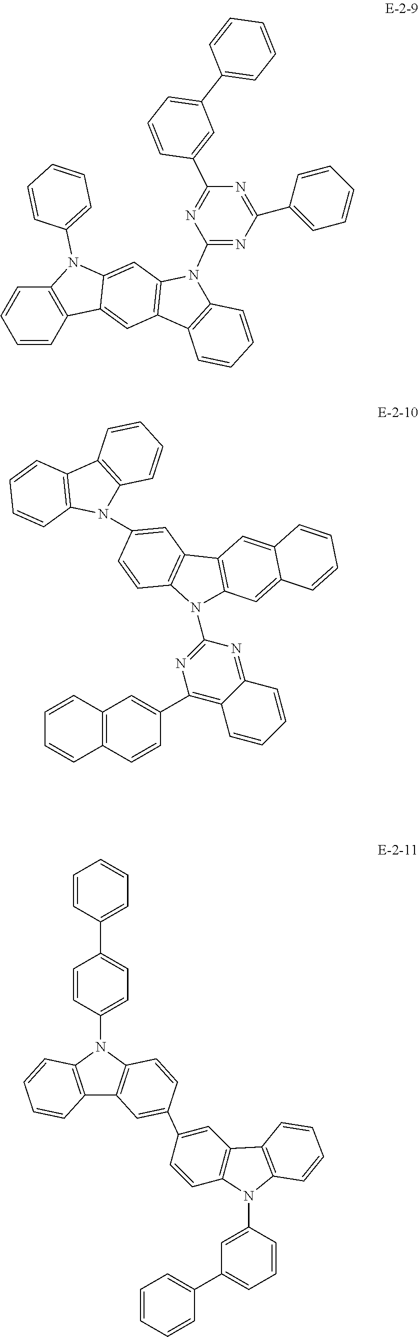 [SMILES: c1ccc(-c2cccc(-c3nc(-c4ccccc4)nc(-n4c5ccccc5c5cc6c7ccccc7n(-c7ccccc7)c6cc54)n3)c2)cc1 ; c1ccc2cc(-c3nc(-n4c5ccc(-n6c7ccccc7c7ccccc76)cc5c5cc6ccccc6cc54)nc4ccccc34)ccc2c1 ; c1ccc(-c2ccc(-n3c4ccccc4c4cc(-c5ccc6c(c5)c5ccccc5n6-c5cccc(-c6ccccc6)c5)ccc43)cc2)cc1]

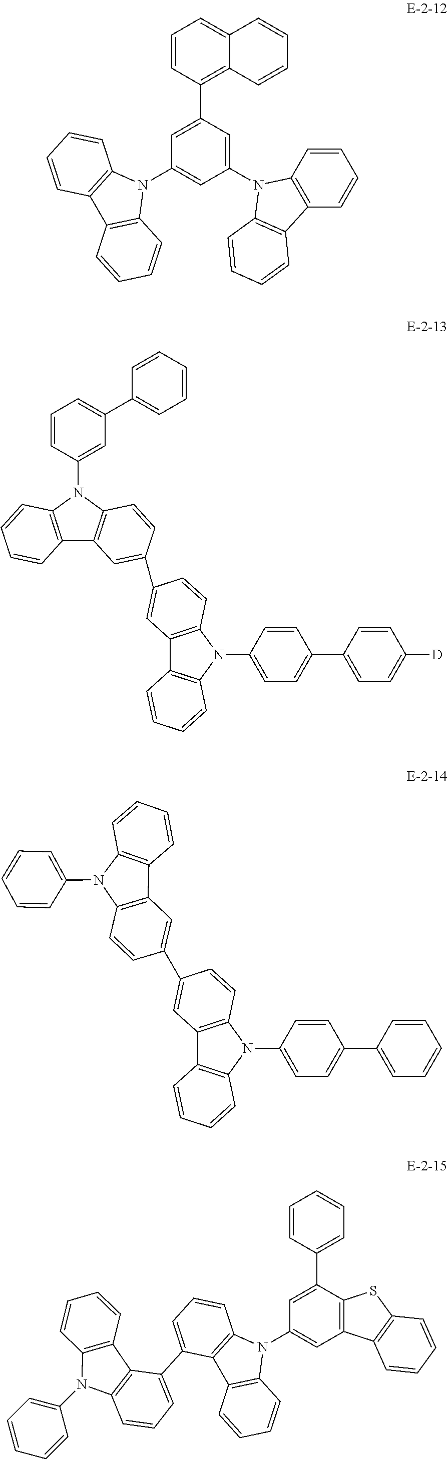 [SMILES: c1ccc2c(-c3cc(-n4c5ccccc5c5ccccc54)cc(-n4c5ccccc5c5ccccc54)c3)cccc2c1 ; [2H]c1ccc(-c2ccc(-n3c4ccccc4c4cc(-c5ccc6c(c5)c5ccccc5n6-c5cccc(-c6ccccc6)c5)ccc43)cc2)cc1 ; c1ccc(-c2ccc(-n3c4ccccc4c4cc(-c5ccc6c(c5)c5ccccc5n6-c5ccccc5)ccc43)cc2)cc1 ; c1ccc(-c2cc(-n3c4ccccc4c4c(-c5cccc6c5c5ccccc5n6-c5ccccc5)cccc43)cc3c2sc2ccccc23)cc1]

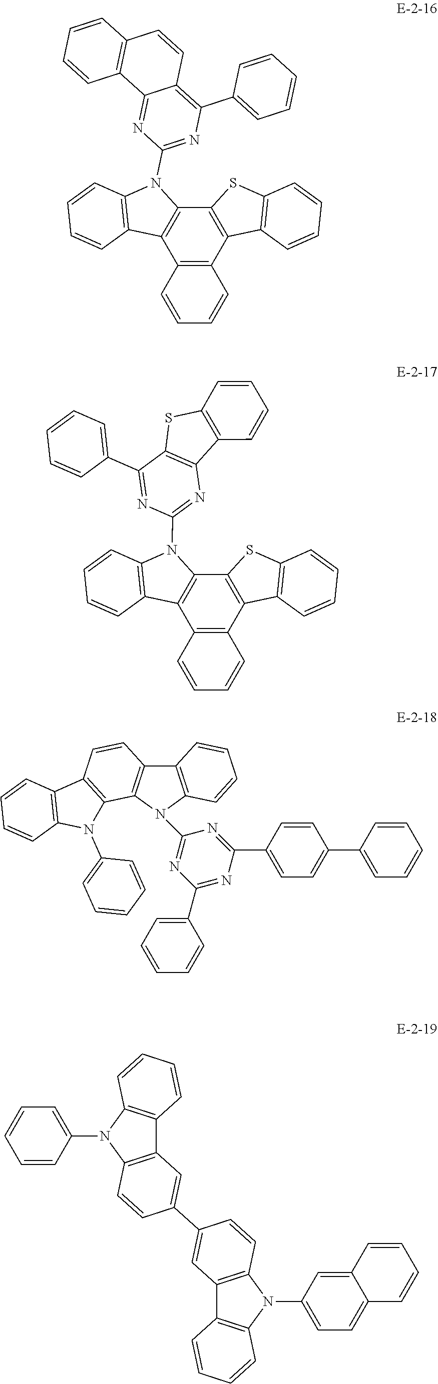 [SMILES: c1ccc(-c2nc(-n3c4ccccc4c4c5ccccc5c5c6ccccc6sc5c43)nc3c2ccc2ccccc23)cc1 ; c1ccc(-c2nc(-n3c4ccccc4c4c5ccccc5c5c6ccccc6sc5c43)nc3c2sc2ccccc23)cc1 ; c1ccc(-c2ccc(-c3nc(-c4ccccc4)nc(-n4c5ccccc5c5ccc6c7ccccc7n(-c7ccccc7)c6c54)n3)cc2)cc1 ; c1ccc(-n2c3ccccc3c3cc(-c4ccc5c(c4)c4ccccc4n5-c4ccc5ccccc5c4)ccc32)cc1]

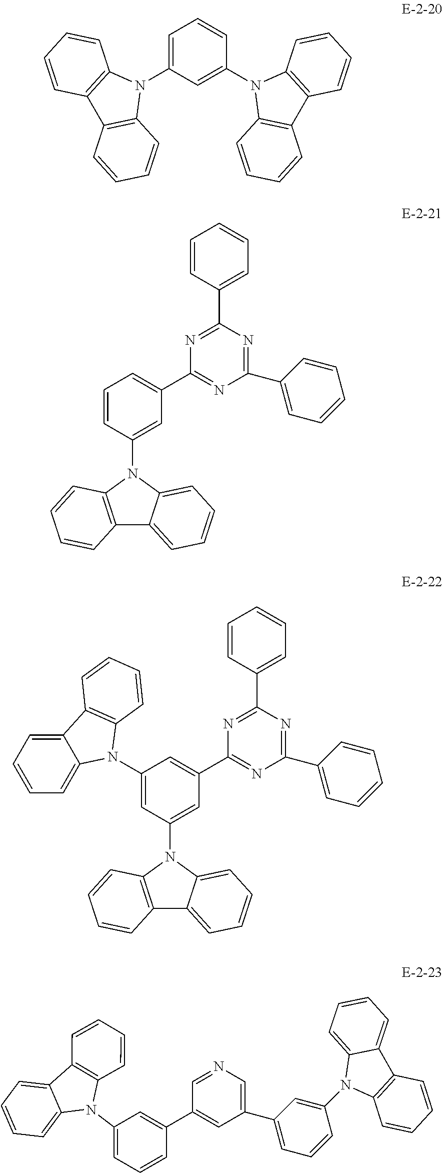 [SMILES: c1cc(-n2c3ccccc3c3ccccc32)cc(-n2c3ccccc3c3ccccc32)c1 ; c1ccc(-c2nc(-c3ccccc3)nc(-c3cccc(-n4c5ccccc5c5ccccc54)c3)n2)cc1 ; c1ccc(-c2nc(-c3ccccc3)nc(-c3cc(-n4c5ccccc5c5ccccc54)cc(-n4c5ccccc5c5ccccc54)c3)n2)cc1 ; c1cc(-c2cncc(-c3cccc(-n4c5ccccc5c5ccccc54)c3)c2)cc(-n2c3ccccc3c3ccccc32)c1]

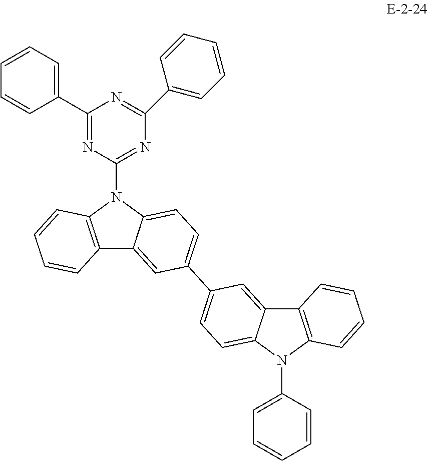 [SMILES: c1ccc(-c2nc(-c3ccccc3)nc(-n3c4ccccc4c4cc(-c5ccc6c(c5)c5ccccc5n6-c5ccccc5)ccc43)n2)cc1]

The light-emitting layer EML may further include any suitable material generally used in the art as a host material. For example, the light-emitting layer EML may include as a host material, at least one of bis(4-(9H-carbazol-9-yl) phenyl) diphenylsilane (BCPDS), (4-(1-(4-(diphenylamino) phenyl) cyclohexyl) phenyl) diphenyl-phosphine oxide (POPCPA), bis[2-(diphenylphosphino)phenyl]ether oxide (DPEPO), 4,4′-bis(N-carbazolyl)-1,1′-biphenyl (CBP), 1,3-bis(carbazol-9-yl) benzene (mCP), 2,8-bis(diphenylphosphoryl)dibenzo[b,d]furan (PPF), 4,4′,4″-tris(carbazol-9-yl)-triphenylamine (TCTA), or 1,3,5-tris(1-phenyl-1H-benzo[d]imidazole-2-yl)benzene (TPBi). However, an embodiment of the present disclosure is not limited thereto. For example, tris(8-hydroxyquinolinato)aluminum (Alq₃), 9,10-di(naphthalene-2-yl)anthracene (ADN), 2-tert-butyl-9,10-di(naphth-2-yl)anthracene (TBADN), distyrylarylene (DSA), 4,4′-bis(9-carbazolyl)-2,2′-dimethyl-biphenyl (CDBP), 2-methyl-9,10-bis(naphthalen-2-yl)anthracene (MADN), hexaphenyl cyclotriphosphazene (CP1), 1,4-bis(triphenylsilyl)benzene (UGH2), hexaphenylcyclotrisiloxane (DPSiO₃), octaphenylcyclotetra siloxane (DPSiO₄), etc. may be used as the host material.

The light-emitting layer EML may include a compound represented by Formula M-a or Formula M-b below. The compound represented by Formula M-a or Formula M-b may be used as a phosphorescence dopant material. In embodiments, the compound represented by Formula M-a or Formula M-b may be used as an auxiliary dopant material.

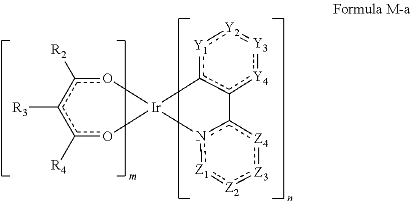

In Formula M-a, Y₁ to Y₄, and Z₁ to Z₄ may be each independently CR₁ or N, and R₁ to R₄ may be each independently a hydrogen atom, a deuterium atom, a substituted or unsubstituted amine group, a substituted or unsubstituted thio group, a substituted or unsubstituted oxy group, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring. In Formula M-a, “m” is 0 or 1, and “n” is 2 or 3. In Formula M-a, if “m” is 0, “n” is 3, and if “m” is 1, “n” is 2.

The compound represented by Formula M-a may be used as a phosphorescence dopant.

The compound represented by Formula M-a may be represented by any one among Compounds M-a1 to M-a25 below. However, Compounds M-a1 to M-a25 below are examples, and the compound represented by Formula M-a is not limited to the compounds represented by Compounds M-a1 to M-a25 below.

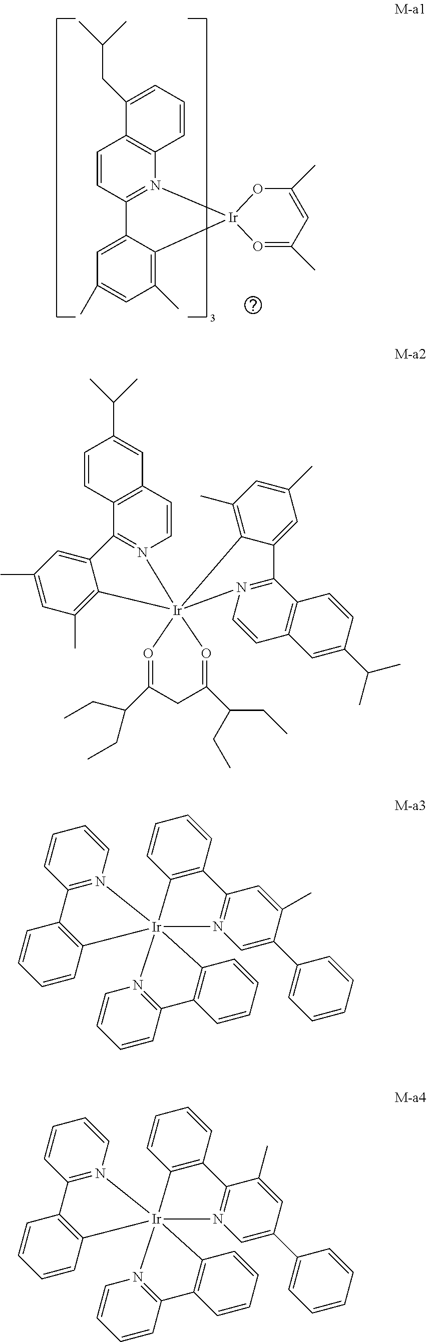

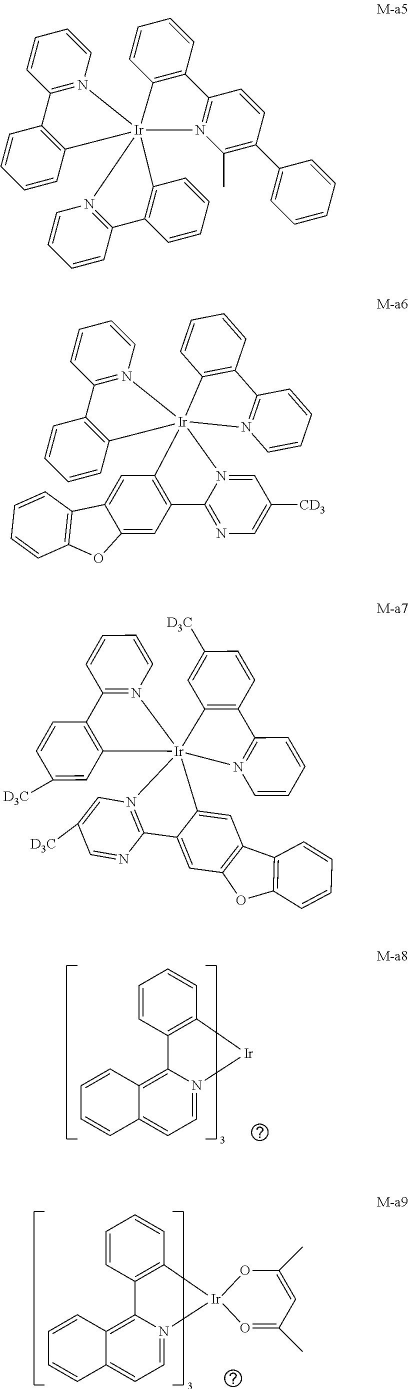

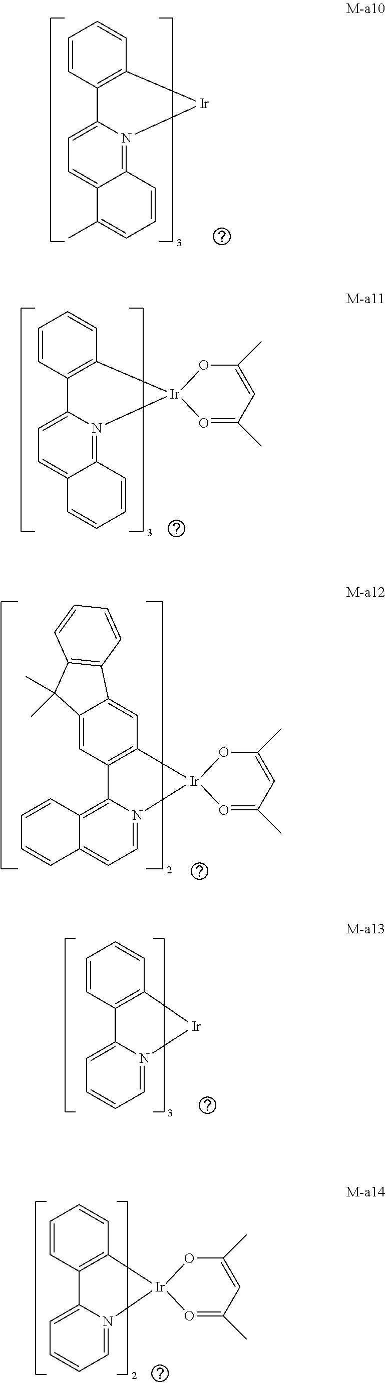

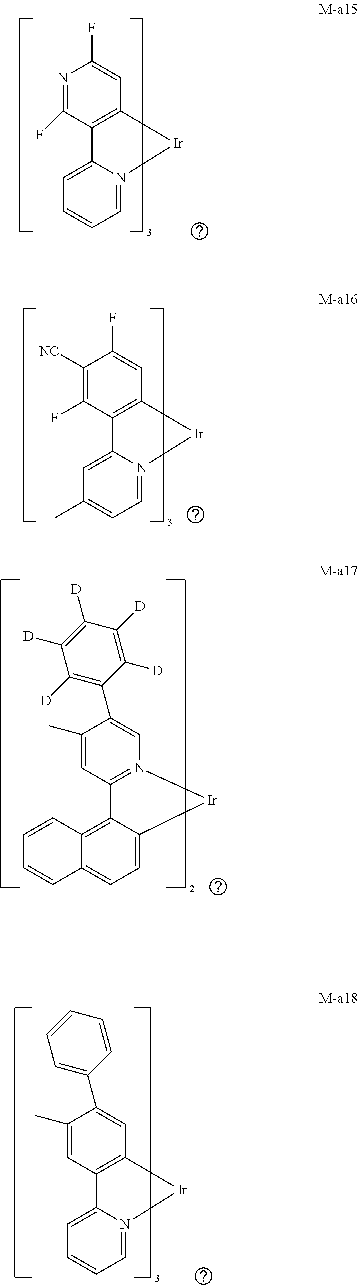

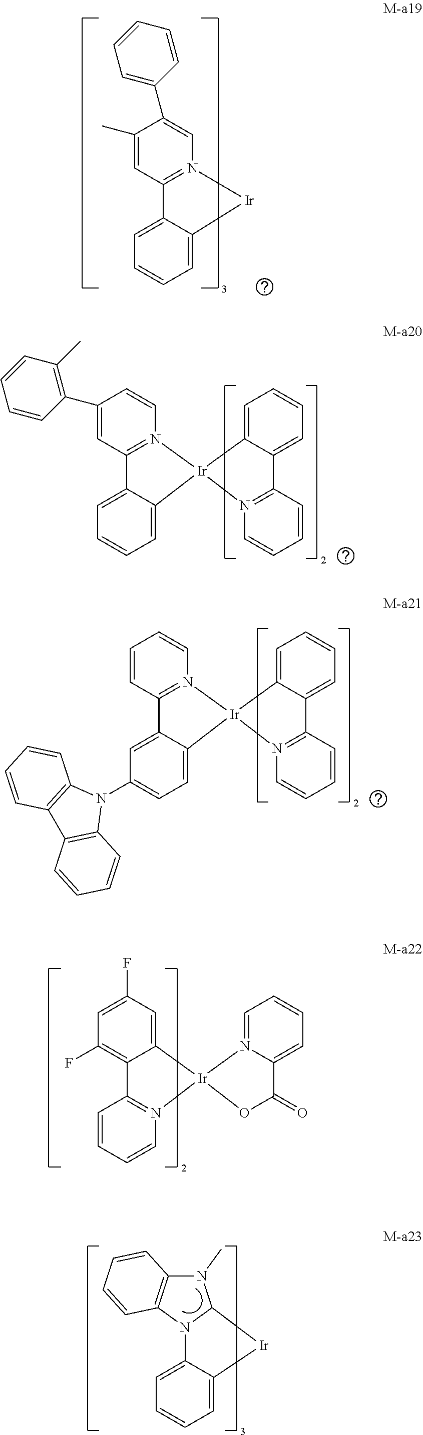

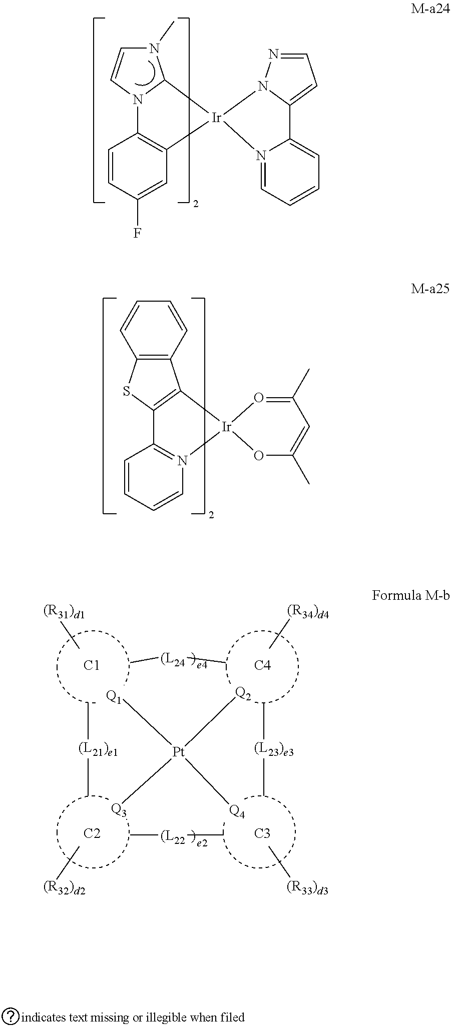

In Formula M-b, Q₁ to Q₄ are each independently C or N, C1 to C4 are each independently a substituted or unsubstituted hydrocarbon ring of 5 to 30 ring-forming carbon atoms, or a substituted or unsubstituted heterocycle of 2 to 30 ring-forming carbon atoms. L₂₁ to L₂₄ are each independently a direct linkage (e.g., a covalent bond),

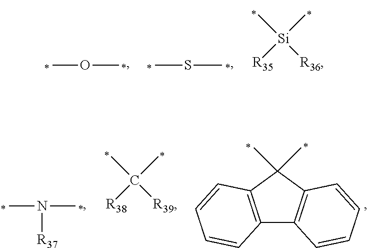

a substituted or unsubstituted divalent alkyl group of 1 to 20 carbon atoms, a substituted or unsubstituted arylene group of 6 to 30 ring-forming carbon atoms, or a substituted or unsubstituted heteroarylene group of 2 to 30 ring-forming carbon atoms, and e1 to e4 are each independently 0 or 1. R₃₁ to R₃₉ are each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring, and d1 to d4 are each independently an integer of 0 to 4.

The compound represented by Formula M-b may be used as a blue phosphorescence dopant or a green phosphorescence dopant. In embodiments, the compound represented by Formula M-b may be an auxiliary dopant in an embodiment and may be further included in the light-emitting layer EML.

The compound represented by Formula M-b may be represented by any one among Compound M-b-1 to Compound M-b-11 below. However, the compounds below are examples, and the compound represented by Formula M-b is not limited to Compound M-b-1 to Compound M-b-11 below.

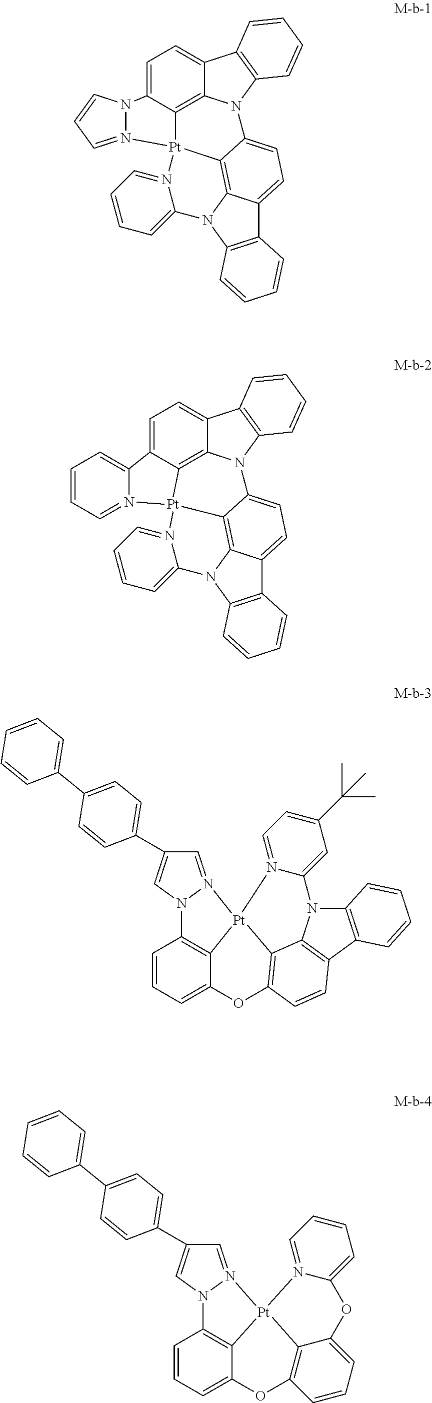

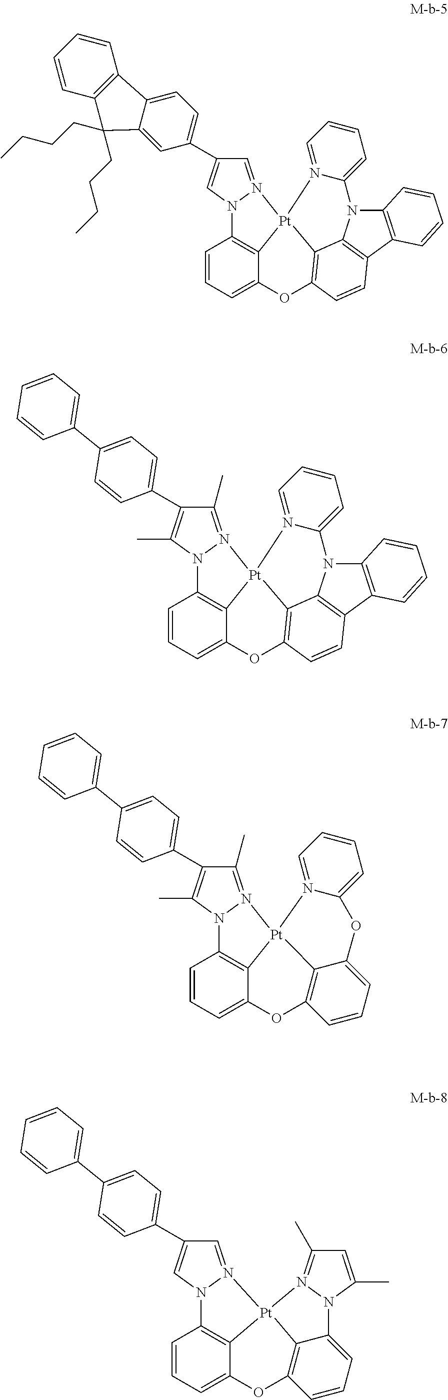

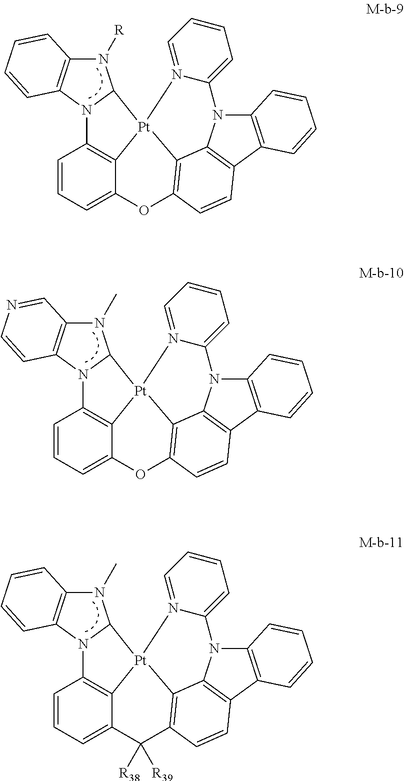

In the compounds above, R, R₃₈, and R₃₉ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

The light-emitting layer EML may contain a first compound represented by any one among Formulas F-a to F-c below, a second compound represented by Formula HT-1 below, a third compound represented by Formula ET-1 below, and a fourth compound represented by Formula D-1 below.

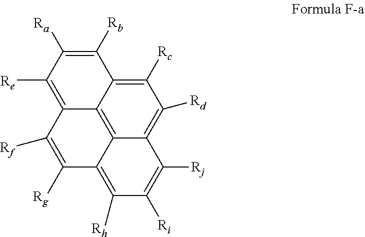

In Formula F-a, two selected from Rₐ to Rⱼ may be each independently substituted with *—NAr₁Ar₂. The remainder not substituted with *—NAr₁Ar₂ among Rₐ to Rⱼ may be each independently a hydrogen atom, a deuterium atom, a halogen atom, a cyano group, a substituted or unsubstituted amine group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. In *—NAr₁Ar₂, Ar₁ and Ar₂ may be each independently a substituted or unsubstituted aryl group of 6 to 30 ring-forming carbon atoms, or a substituted or unsubstituted heteroaryl group of 2 to 30 ring-forming carbon atoms. For example, at least one among Ar₁ and Ar₂ may be a heteroaryl group including O or S as a ring-forming atom.

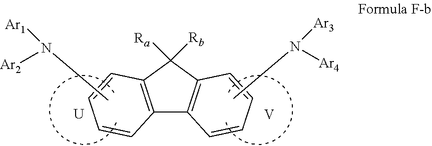

In Formula F-b, Rₐ and R_{b} may be each independently a hydrogen atom, a deuterium atom, a substituted or unsubstituted alkyl group of 1 to 20 carbon atoms, a substituted or unsubstituted alkenyl group of 2 to 20 carbon atoms, a substituted or unsubstituted aryl group of 6 to 30 ring-forming carbon atoms, or a substituted or unsubstituted heteroaryl group of 2 to 30 ring-forming carbon atoms, or may be combined with an adjacent group to form a ring.

In Formula F-b, Ar₁ to Ar₄ may be each independently a substituted or unsubstituted aryl group of 6 to 30 ring-forming carbon atoms, or a substituted or unsubstituted heteroaryl group of 2 to 30 ring-forming carbon atoms.

In Formula F-b, U and V may be each independently a substituted or unsubstituted hydrocarbon ring of 5 to 30 ring-forming carbon atoms, or a substituted or unsubstituted heterocycle of 2 to 30 ring-forming carbon atoms. At least one among Ar₁ to Ar₄ may be a heteroaryl group including O or S as a ring-forming atom.

In Formula F-b, the number of rings represented by U and V may be each independently 0 or 1. For example, in Formula F-b, if the number of U or V is 1, one ring forms a fused ring at the designated part by U or V, and if the number of U or V is 0, a ring is not present at the designated part by U or V. In embodiments, if the number of U is 0, and the number of V is 1, or if the number of U is 1, and the number of V is 0, a fused ring having the fluorene core of Formula F-b may be a ring compound with four rings. In embodiments, if the number of both U and V is 0, the fused ring of Formula F-b may be a ring compound with three rings. In embodiments, if the number of both U and V is 1, a fused ring having the fluorene core of Formula F-b may be a ring compound having five rings.

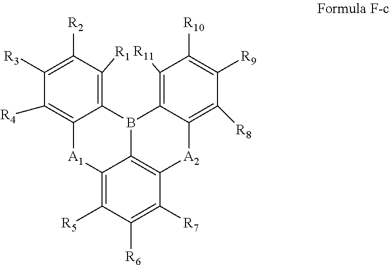

In Formula F-c, A₁ and A₂ may be each independently O, S, Se, or NRₘ, and Rₘ may be a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms. R₁ to R₁₁ are each independently a hydrogen atom, a deuterium atom, a halogen atom, a cyano group, a substituted or unsubstituted amine group, a substituted or unsubstituted boryl group, a substituted or unsubstituted oxy group, a substituted or unsubstituted thiol group, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms, or combined with an adjacent group to form a ring.

In Formula F-c, A₁ and A₂ may be each independently combined with the substituents of an adjacent ring to form a fused ring. For example, if A₁ and A₂ may be each independently NRₘ, A₁ may be combined with R₄ or R₅ to form a ring. In addition, A₂ may be combined with R₇ or R₈ to form a ring.

In an embodiment, the light-emitting layer EML may include as a dopant material, styryl derivatives (for example, 1,4-bis[2-(3-N-ethylcarbazoryl)vinyl]benzene (BCzVB), 4-(di-p-tolylamino)-4′-[(di-p-tolylamino)styryl]stilbene (DPAVB), N-(4-((E)-2-(6-((E)-4-(diphenylamino)styryl)naphthalen-2-yl)vinyl)phenyl)-N-phenylbenzenamine (N-BDAVBi), and/or 4,4′-bis[2-(4-(N,N-diphenylamino)phenyl)vinyl]biphenyl (DPAVBi)), perylene and/or the derivatives thereof (for example, 2,5,8,11-tetra-t-butylperylene (TBP)), pyrene and/or the derivatives thereof (for example, 1,1-dipyrene, 1,4-dipyrenylbenzene, and/or 1,4-bis(N,N-diphenylamino)pyrene), etc.

The light-emitting layer EML may include any suitable phosphorescence dopant material. For example, the phosphorescence dopant may use a metal complex including iridium (Ir), platinum (Pt), osmium (Os), gold (Au), titanium (Ti), zirconium (Zr), hafnium (Hf), europium (Eu), terbium (Tb) and/or thulium (Tm). In embodiments, iridium(III) bis(4,6-difluorophenylpyridinato-N,C2′)picolinate (Flrpic), bis(2,4-difluorophenylpyridinato)-tetrakis(1-pyrazolyl)borate iridium(III) (Fir6), and/or platinum octaethyl porphyrin (PtOEP) may be used as the phosphorescence dopant. However, an embodiment of the present disclosure is not limited thereto.

In embodiments, the light-emitting layer EML may include a hole transport host and an electron transport host. In embodiments, the light-emitting layer EML may include an auxiliary dopant and a light emitting dopant. In embodiments, the auxiliary dopant may include a phosphorescence dopant material or a thermally activated delayed fluorescence dopant. For example, in embodiments, the light-emitting layer EML may include a hole transport host, an electron transport host, an auxiliary dopant, and a light emitting dopant.

In embodiments, exciplex may be formed by the hole transport host and the electron transport host in the light-emitting layer EML. In embodiments, the triplet energy of the exciplex formed by the hole transport host and the electron transport host may correspond to T1 which is a gap between the LUMO energy level of the electron transport host and the HOMO energy level of the hole transport host.

In an embodiment, the triplet energy (T1) of the exciplex formed by the hole transport host and the electron transport host may be about 2.4 eV to about 3.0 eV. In embodiments, the triplet energy of the exciplex may be a value smaller than the energy gap of each host material. Accordingly, the exciplex may have a triplet energy of about 3.0 eV or less, which is the energy gap between the hole transport host and the electron transport host.

The light-emitting layer may include a quantum dot.

In the description, the quantum dot means the crystal of a semiconductor compound. The quantum dot may emit light of various suitable emission wavelengths according to the size of the crystal. The quantum dot may emit light of various suitable emission wavelengths by controlling the element ratio in the quantum dot compound.

The diameter of the quantum dot may be, for example, about 1 nm to about 10 nm.

The quantum dot may be synthesized by a chemical bath deposition, a metal organic chemical vapor deposition, a molecular beam epitaxy and/or a similar process therewith.

The chemical bath deposition is a method of mixing together an organic solvent and a precursor material and then, growing a quantum dot particle crystal. During the growing of the crystal, the organic solvent may naturally play the role of a dispersant which is coordinated on the surface of the quantum dot crystal and may control the growth of the crystal. Accordingly, the chemical bath deposition is more beneficial or advantageous when compared to a vapor deposition method including a metal organic chemical vapor deposition (MOCVD) and molecular beam epitaxy (MBE), and the growth of the quantum dot particle may be controlled through a low-cost process.

The light-emitting layer EML may include a quantum dot material. The core of the quantum dot may be selected from a II-VI group compound, a III-VI group compound, a I-III-VI group compound, a III-V group compound, a III-II-V group compound, a IV-VI group compound, a IV group element, a IV group compound, and combinations thereof.

The Group II-VI compound may be selected from the group consisting of a binary compound selected from the group consisting of CdSe, CdTe, CdS, ZnS, ZnSe, ZnTe, ZnO, HgS, HgSe, HgTe, MgSe, MgS, and a mixture thereof; a ternary compound selected from the group consisting of CdSeS, CdSeTe, CdSTe, ZnSeS, ZnSeTe, ZnSTe, HgSeS, HgSeTe, HgSTe, CdZnS, CdZnSe, CdZnTe, CdHgS, CdHgSe, CdHgTe, HgZnS, HgZnSe, HgZnTe, MgZnSe, MgZnS, and a mixture thereof; and a quaternary compound selected from the group consisting of HgZnTeS, CdZnSeS, CdZnSeTe, CdZnSTe, CdHgSeS, CdHgSeTe, CdHgSTe, HgZnSeS, HgZnSeTe, and a mixture thereof. In embodiments, the Group II-VI compound may further include a Group I metal and/or a Group IV element. The Group I-II-VI compound may be selected from CuSnS and/or CuZnS, and the Group II-IV-VI compound may be selected from ZnSnS and/or the like. The Group I-II-IV-VI compound may be selected from quaternary compounds selected from the group consisting of Cu₂ZnSnS₂, Cu₂ZnSnS₄, Cu₂ZnSnSe₄, Ag₂ZnSnS₂, and a mixture thereof.

The III-VI group compound may include a binary compound such as In₂S₃, and/or In₂Se₃, a ternary compound such as InGaS₃, and/or InGaSes, and/or any suitable combinations thereof.

The I-III-VI group compound may be selected from a ternary compound selected from the group consisting of AgInS, AgInS₂, CuInS, CuInS₂, AgGaS₂, CuGaS₂, CuGaO₂, AgGaO₂, AgAlO₂ and mixtures thereof, and/or a quaternary compound such as AgInGaS₂, and CuInGaS₂.

The III-V group compound may be selected from the group consisting of a binary compound selected from the group consisting of GaN, GaP, GaAs, GaSb, AlN, AlP, AlAs, AlSb, InN, InP, InAs, InSb, and mixtures thereof, a ternary compound selected from the group consisting of GaNP, GaNAs, GaNSb, GaPAs, GaPSb, AlNP, AlNAs, AlNSb, AlPAs, AlPSb, InGaP, InAlP, InNP, InNAs, InNSb, InPAs, InPSb, and mixtures thereof, and a quaternary compound selected from the group consisting of GaAlNP, GaAlNAs, GaAlNSb, GaAlPAs, GaAlPSb, GaInNP, GaInNAs, GaInNSb, GaInPAs, GaInPSb, InAlNP, InAlNAs, InAlNSb, InAlPAs, InAlPSb, and mixtures thereof. In embodiments, the III-V group compound may further include a II group metal. For example, InZnP, etc. may be selected as a III-II-V group compound.

The Group IV-VI compound may be selected from the group consisting of a binary compound selected from the group consisting of SnS, SnSe, SnTe, PbS, PbSe, PbTe, and a mixture thereof, a ternary compound selected from the group consisting of SnSeS, SnSeTe, SnSTe, PbSeS, PbSeTe, PbSTe, SnPbS, SnPbSe, SnPbTe, and a mixture thereof, and a quaternary compound selected from the group consisting of SnPbSSe, SnPbSeTe, SnPbSTe, and a mixture thereof.

The Group II-IV-V compound may be selected from a ternary compound selected from the group consisting of ZnSnP, ZnSnP₂, ZnSnAs₂, ZnGeP₂, ZnGeAs₂, CdSnP₂, and CdGeP₂ and a mixture thereof.

The Group IV element may be selected from the group consisting of Si, Ge, and a mixture thereof. The Group IV compound may be a binary compound selected from the group consisting of SiC, SiGe, and a mixture thereof.

Each element included in the multi-element compound such as the binary compound, ternary compound, and quaternary compound may be present in particles at a uniform concentration or a non-uniform concentration. For example, Formula above indicates the types (or kinds) of elements included in a compound, and element ratios in the compound may be different. For example, AgInGaS₂ may indicate AgInₓGa₁₋ₓS₂ (x is a real number between 0 and 1).

In this case, the binary compound, the ternary compound and/or the quaternary compound may be present at uniform concentration in a particle or may be present at a partially different concentration distribution state in the same particle. In embodiments, a core/shell structure in which one quantum dot wraps another quantum dot may be possible. The interface of the core and the shell may have a concentration gradient in which the concentration of an element present in the shell is decreased along a direction toward the center of the core.

In some embodiments, the quantum dot may have the above-described core-shell structure including a core including a nanocrystal and a shell wrapping (e.g., surrounding) the core. The shell of the quantum dot may play the role of a protection layer for preventing or reducing the chemical deformation of the core to maintain semiconductor properties and/or a charging layer for imparting the quantum dot with electrophoretic properties. The shell may have a single layer or a multilayer. Examples of the shell of the quantum dot may include a metal and/or non-metal oxide, a semiconductor compound, or combinations thereof.

For example, the metal and/or non-metal oxide may include a binary compound such as SiO₂, Al₂O₃, TiO₂, ZnO, MnO, Mn₂O₃, Mn₃O₄, CuO, FeO, Fe₂O₃, Fe₃O₄, CoO, Co₃O₄ and/or NiO, and/or a ternary compound such as MgAl₂O₄, CoFe₂O₄, NiFe₂O₄ and/or CoMn₂O₄, but an embodiment of the present disclosure is not limited thereto.

Also, the semiconductor compound may include CdS, CdSe, CdTe, ZnS, ZnSe, ZnTe, ZnSeS, ZnTeS, GaAs, GaP, GaSb, HgS, HgSe, HgTe, InAs, InP, InGaP, InSb, AlAs, AlP, AlSb, etc., but an embodiment of the present disclosure is not limited thereto.

The quantum dot may have a full width of half maximum (FWHM) of emission wavelength spectrum of about 45 nm or less, for example, about 40 nm or less, or, about 30 nm or less. Within the above ranges, color purity and/or color reproducibility may be improved. In embodiments, light emitted via such quantum dot is emitted in all (e.g., substantially all) directions, and light view angle properties may be improved.

In embodiments, the shape of the quantum dot may be any suitable generally used shapes in the art, without specific limitation. For example, the shape of spherical, pyramidal, multi-arm, and/or cubic nanoparticle, nanotube, nanowire, nanofiber, nanoplate particle, etc. may be used.

As the size of the quantum dot and/or the ratio of elements in the quantum dot compound is regulated, the energy band gap may be accordingly controlled to obtain light of various suitable wavelengths from the quantum dot emission layer. Therefore, by using the quantum dots as described above (using quantum dots of different sizes and/or having different element ratios in the quantum dot compound), a light emitting element that emits light of various suitable wavelengths may be obtained. For example, the size of the quantum dots and/or the ratio of elements in the quantum dot compound may be regulated to emit red, green, and/or blue light. In embodiments, the quantum dots may be configured to emit white light by combining light of various suitable colors.

In the light emitting elements ED of embodiments, as shown in FIG. 3 to FIG. 7, the electron transport region ETR is provided on the light-emitting layer EML. The electron transport region ETR may include at least one of an electron blocking layer HBL, an electron transport layer ETL or an electron injection layer EIL. However, an embodiment of the present disclosure is not limited thereto.

The electron transport region ETR may have a single layer formed using a single material, a single layer formed using a plurality of different materials, or a multilayer structure having a plurality of layers formed using a plurality of different materials.

For example, the electron transport region ETR may have a single layer structure of an electron injection layer EIL or an electron transport layer ETL, or a single layer structure formed using an electron injection material and an electron transport material. Further, the electron transport region ETR may have a single layer structure formed using a plurality of different materials, or a structure stacked from the light-emitting layer EML of electron transport layer ETL/electron injection layer EIL, or hole blocking layer HBL/electron transport layer ETL/electron injection layer EIL, without limitation. The thickness of the electron transport region ETR may be, for example, from about 1,000 Å to about 1,500 Å.

The electron transport region ETR may be formed using various suitable methods such as a vacuum deposition method, a spin coating method, a cast method, a Langmuir-Blodgett (LB) method, an inkjet printing method, a laser printing method, and/or a laser induced thermal imaging (LITI) method.

The electron transport region ETR may include a compound represented by Formula ET-1 below.

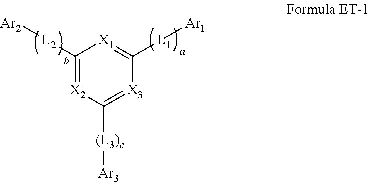

In Formula ET-1, at least one among X₁ to X₃ is N, and the remainder are CRₐ. Rₐ may be a hydrogen atom, a deuterium atom, a substituted or unsubstituted alkyl of 1 to 20 carbon atoms, a substituted or unsubstituted aryl group of 6 to 30 ring-forming carbon atoms, or a substituted or unsubstituted heteroaryl group of 2 to 30 ring-forming carbon atoms. Ar₁ to Ar₃ may be each independently a hydrogen atom, a deuterium atom, a substituted or unsubstituted alkyl group of 1 to 20 carbon atoms, a substituted or unsubstituted aryl group of 6 to 30 ring-forming carbon atoms, or a substituted or unsubstituted heteroaryl group of 2 to 30 ring-forming carbon atoms.

In Formula ET-2, “a” to “c” may be each independently an integer of 0 to 10. In Formula ET-2, L₁ to L₃ may be each independently a direct linkage (e.g., a covalent bond), a substituted or unsubstituted arylene group of 6 to 30 ring-forming carbon atoms, or a substituted or unsubstituted heteroarylene group of 2 to 30 ring-forming carbon atoms. In embodiments, if “a” to “c” are integers of 2 or more, L₁ to L₃ may be each independently a substituted or unsubstituted arylene group of 6 to 30 ring-forming carbon atoms, or a substituted or unsubstituted heteroarylene group of 2 to 30 ring-forming carbon atoms.

The electron transport region ETR may include an anthracene-based compound. However, an embodiment of the present disclosure is not limited thereto, and the electron transport region ETR may include, for example, tris(8-hydroxyquinolinato)aluminum (Alq₃), 1,3,5-tri[(3-pyridyl)-phen-3-yl]benzene, 2,4,6-tris(3′-(pyridin-3-yl)biphenyl-3-yl)-1,3,5-triazine, 2-(4-(N-phenylbenzoimidazolyl-1-yl)phenyl)-9,10-dinaphthylanthracene, 1,3,5-tri(1-phenyl-1H-benzo[d]imidazol-2-yl)benzene (TPBi), 2,9-dimethyl-4,7-diphenyl-1,10-phenanthroline (BCP), 4,7-diphenyl-1,10-phenanthroline (Bphen), 3-(4-biphenylyl)-4-phenyl-5-tert-butylphenyl-1,2,4-triazole (TAZ), 4-(naphthalen-1-yl)-3,5-diphenyl-4H-1,2,4-triazole (NTAZ), 2-(4-biphenylyl)-5-(4-tert-butylphenyl)-1,3,4-oxadiazole (tBu-PBD), bis(2-methyl-8-quinolinolato-N1,O8)-(1,1′-biphenyl-4-olato)aluminum (BAlq), berylliumbis(benzoquinolin-10-olate (Bebq₂), 9,10-di(naphthalene-2-yl)anthracene (ADN), 1,3-bis[3,5-di(pyridin-3-yl)phenyl]benzene (BmPyPhB), CNNPTRZ(4′-(4-(4-(4,6-diphenyl-1,3,5-triazin-2-yl)phenyl)naphthalen-1-yl)-[1,1′-biphenyl]-4-carbonitrile) and/or mixtures thereof, without limitation.

The electron transport region ETR may include at least one among Compounds ET1 to ET36 below.

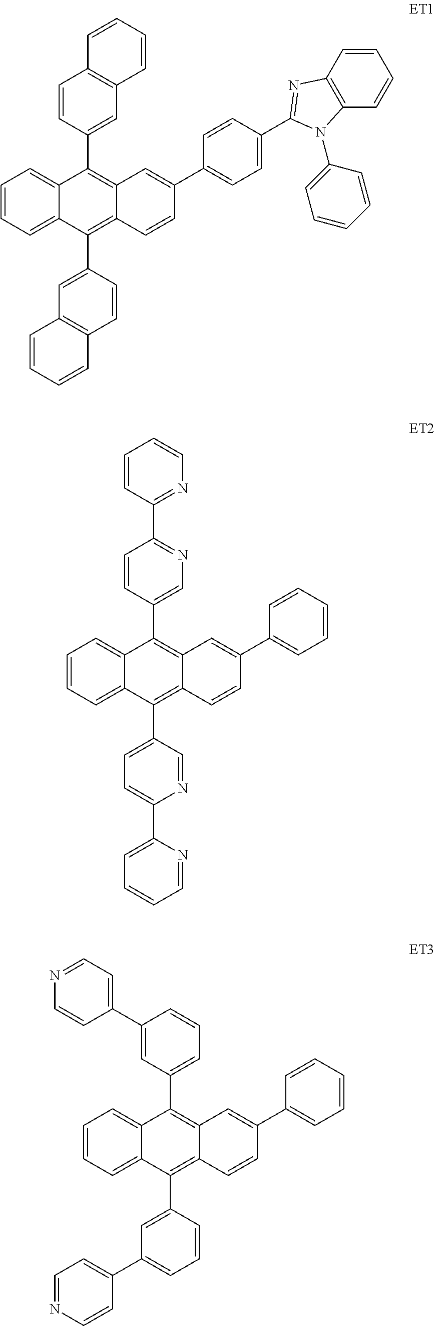 [SMILES: c1ccc(-n2c(-c3ccc(-c4ccc5c(-c6ccc7ccccc7c6)c6ccccc6c(-c6ccc7ccccc7c6)c5c4)cc3)nc3ccccc32)cc1 ; c1ccc(-c2ccc3c(-c4ccc(-c5ccccn5)nc4)c4ccccc4c(-c4ccc(-c5ccccn5)nc4)c3c2)cc1 ; c1ccc(-c2ccc3c(-c4cccc(-c5ccncc5)c4)c4ccccc4c(-c4cccc(-c5ccncc5)c4)c3c2)cc1]

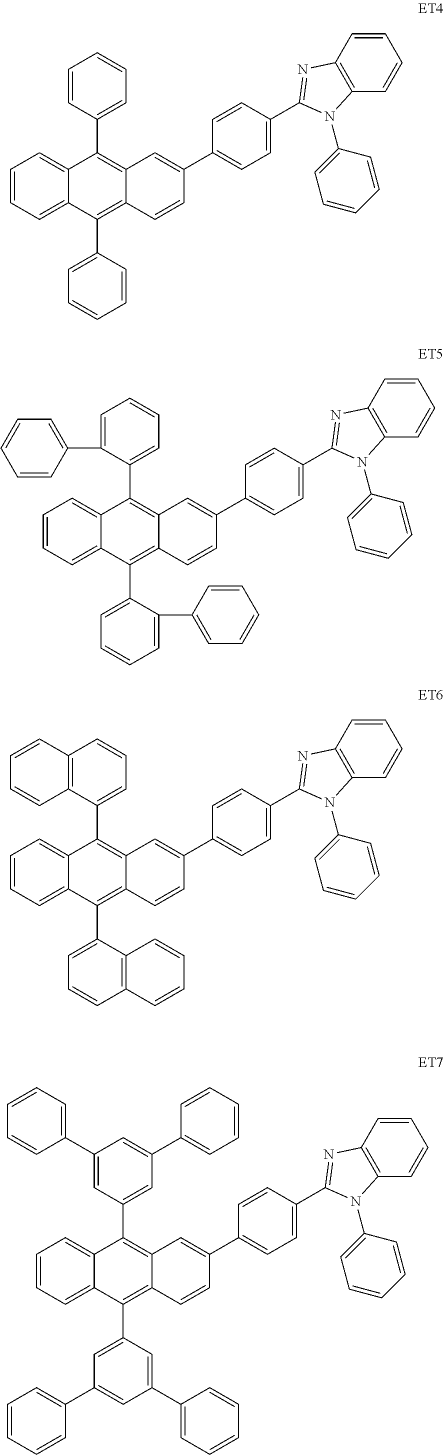 [SMILES: c1ccc(-c2c3ccccc3c(-c3ccccc3)c3cc(-c4ccc(-c5nc6ccccc6n5-c5ccccc5)cc4)ccc23)cc1 ; c1ccc(-c2ccccc2-c2c3ccccc3c(-c3ccccc3-c3ccccc3)c3cc(-c4ccc(-c5nc6ccccc6n5-c5ccccc5)cc4)ccc23)cc1 ; c1ccc(-n2c(-c3ccc(-c4ccc5c(-c6cccc7ccccc67)c6ccccc6c(-c6cccc7ccccc67)c5c4)cc3)nc3ccccc32)cc1 ; c1ccc(-c2cc(-c3ccccc3)cc(-c3c4ccccc4c(-c4cc(-c5ccccc5)cc(-c5ccccc5)c4)c4cc(-c5ccc(-c6nc7ccccc7n6-c6ccccc6)cc5)ccc34)c2)cc1]

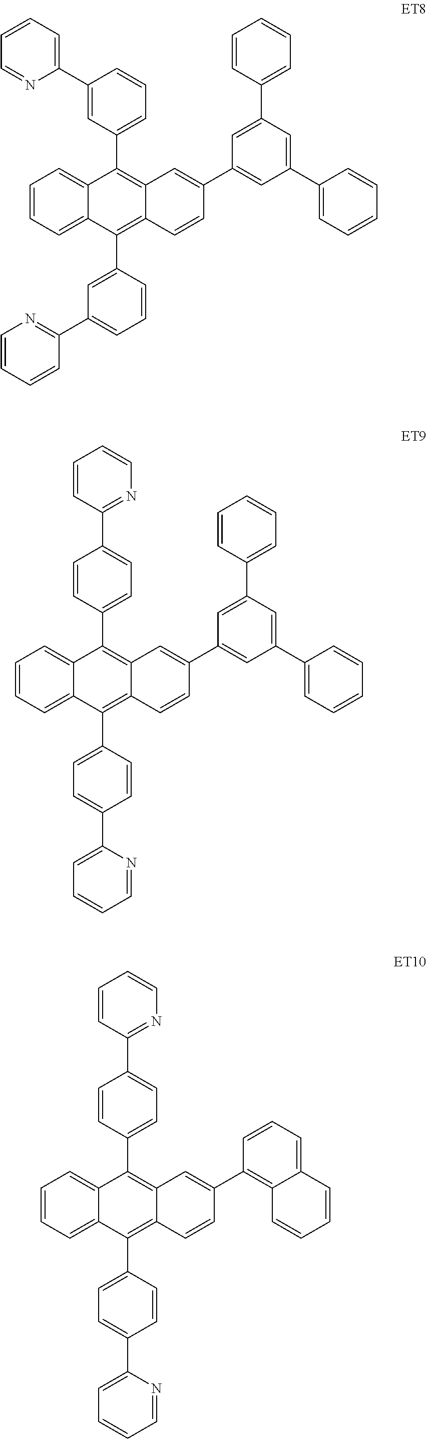 [SMILES: c1ccc(-c2cc(-c3ccccc3)cc(-c3ccc4c(-c5cccc(-c6ccccn6)c5)c5ccccc5c(-c5cccc(-c6ccccn6)c5)c4c3)c2)cc1 ; c1ccc(-c2cc(-c3ccccc3)cc(-c3ccc4c(-c5ccc(-c6ccccn6)cc5)c5ccccc5c(-c5ccc(-c6ccccn6)cc5)c4c3)c2)cc1 ; c1ccc(-c2ccc(-c3c4ccccc4c(-c4ccc(-c5ccccn5)cc4)c4cc(-c5cccc6ccccc56)ccc34)cc2)nc1]

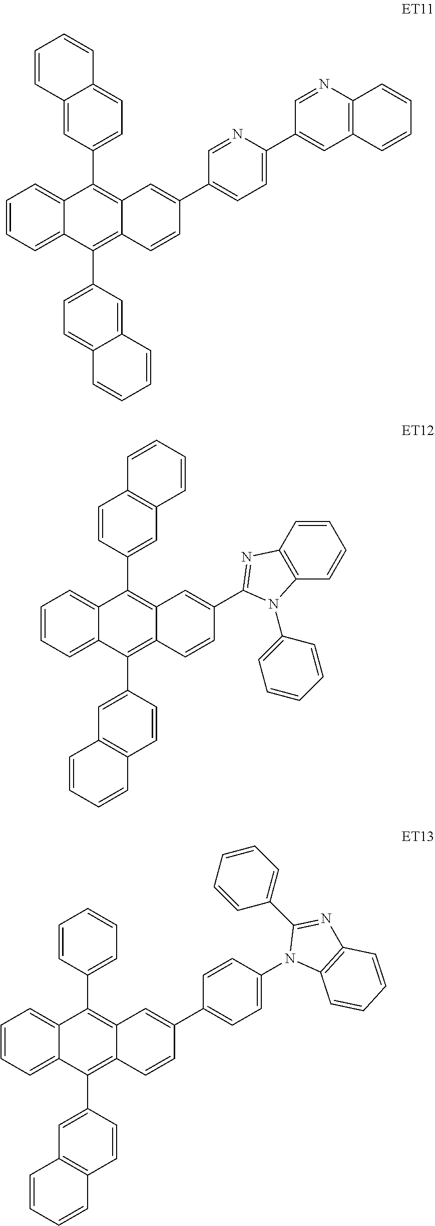 [SMILES: c1ccc2cc(-c3c4ccccc4c(-c4ccc5ccccc5c4)c4cc(-c5ccc(-c6cnc7ccccc7c6)nc5)ccc34)ccc2c1 ; c1ccc(-n2c(-c3ccc4c(-c5ccc6ccccc6c5)c5ccccc5c(-c5ccc6ccccc6c5)c4c3)nc3ccccc32)cc1 ; c1ccc(-c2c3ccccc3c(-c3ccc4ccccc4c3)c3ccc(-c4ccc(-n5c(-c6ccccc6)nc6ccccc65)cc4)cc23)cc1]

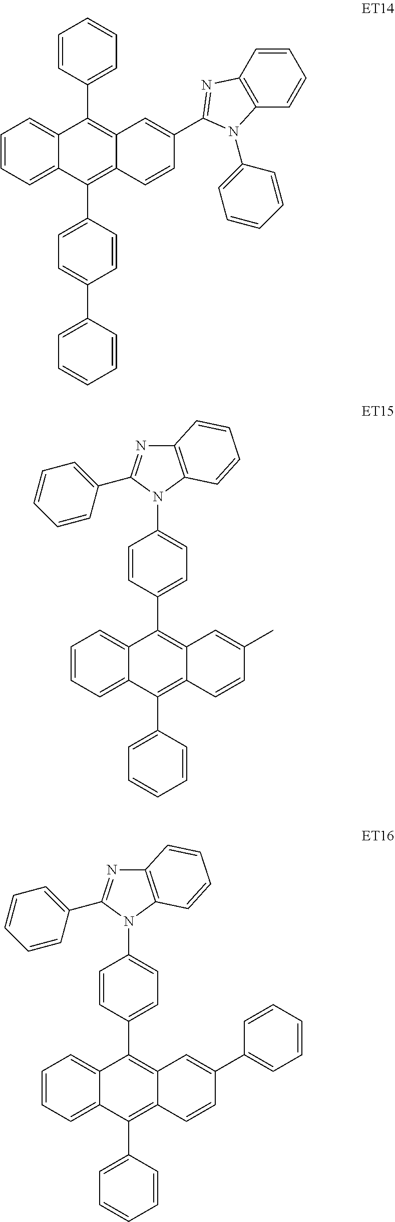 [SMILES: c1ccc(-c2ccc(-c3c4ccccc4c(-c4ccccc4)c4cc(-c5nc6ccccc6n5-c5ccccc5)ccc34)cc2)cc1 ; Cc1ccc2c(-c3ccccc3)c3ccccc3c(-c3ccc(-n4c(-c5ccccc5)nc5ccccc54)cc3)c2c1 ; c1ccc(-c2ccc3c(-c4ccccc4)c4ccccc4c(-c4ccc(-n5c(-c6ccccc6)nc6ccccc65)cc4)c3c2)cc1]

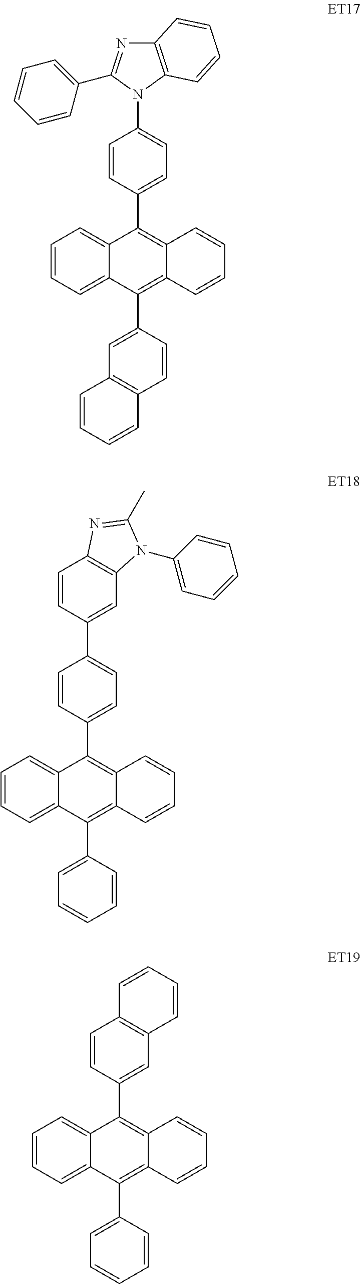

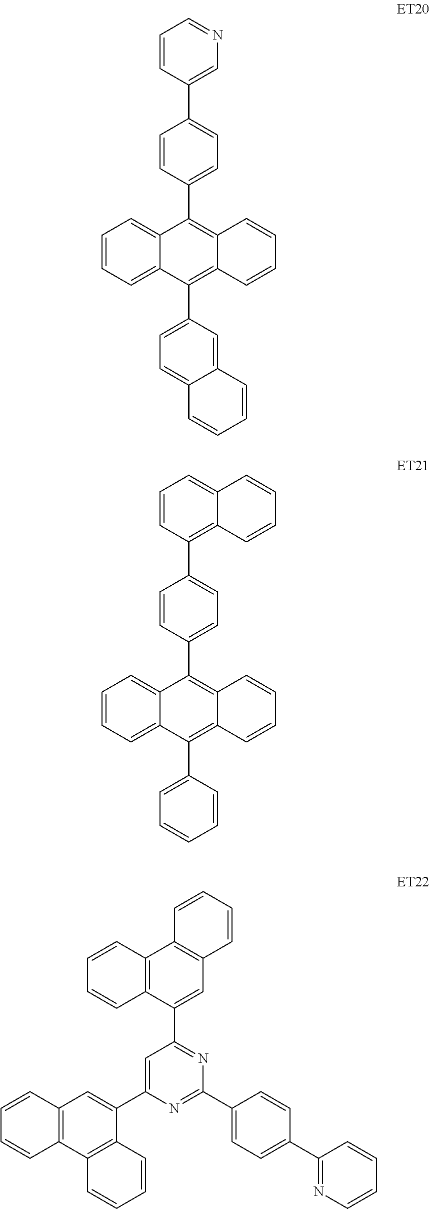

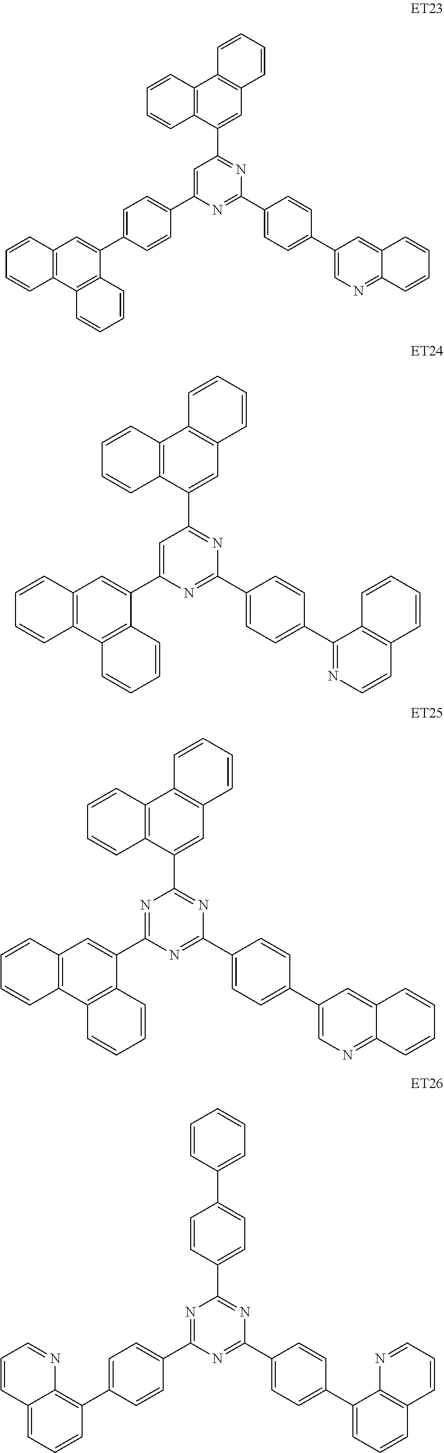 [SMILES: c1ccc2ncc(-c3ccc(-c4nc(-c5ccc(-c6cc7ccccc7c7ccccc67)cc5)cc(-c5cc6ccccc6c6ccccc56)n4)cc3)cc2c1 ; c1ccc2c(-c3ccc(-c4nc(-c5cc6ccccc6c6ccccc56)cc(-c5cc6ccccc6c6ccccc56)n4)cc3)nccc2c1 ; c1ccc2ncc(-c3ccc(-c4nc(-c5cc6ccccc6c6ccccc56)nc(-c5cc6ccccc6c6ccccc56)n4)cc3)cc2c1 ; c1ccc(-c2ccc(-c3nc(-c4ccc(-c5cccc6cccnc56)cc4)nc(-c4ccc(-c5cccc6cccnc56)cc4)n3)cc2)cc1]

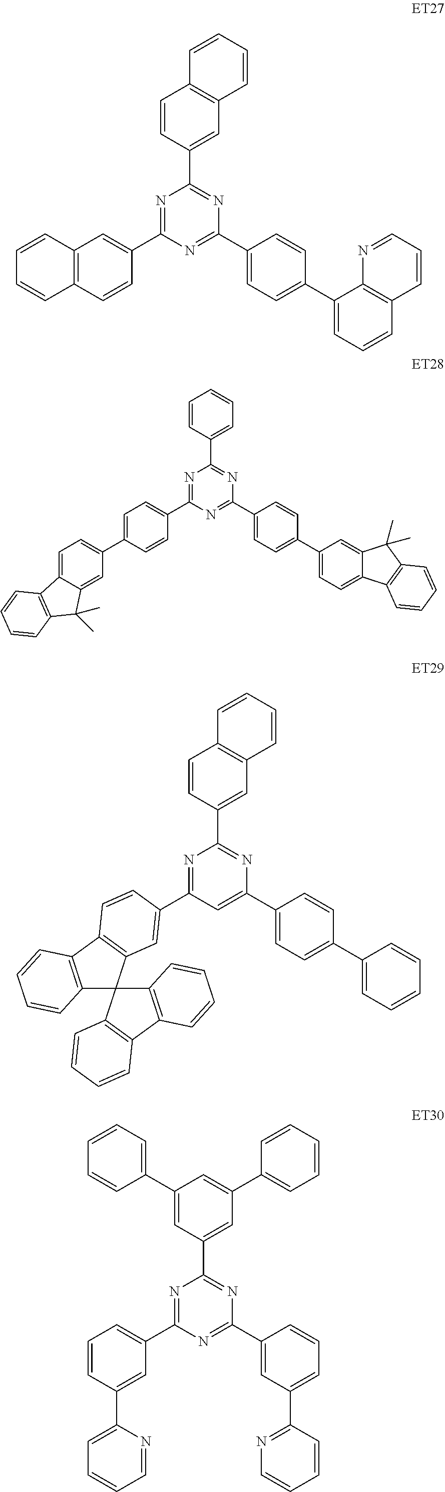

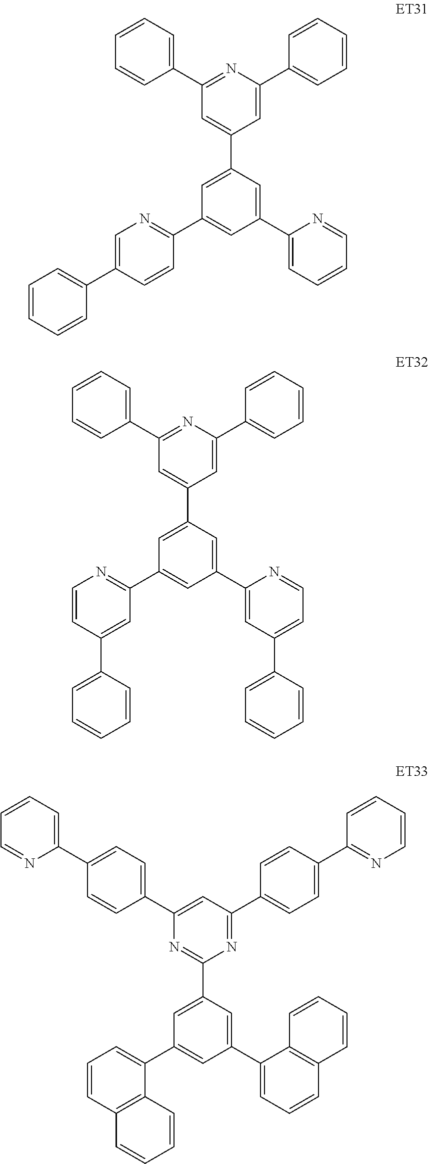 [SMILES: c1ccc(-c2ccc(-c3cc(-c4cc(-c5ccccc5)nc(-c5ccccc5)c4)cc(-c4ccccn4)c3)nc2)cc1 ; c1ccc(-c2ccnc(-c3cc(-c4cc(-c5ccccc5)nc(-c5ccccc5)c4)cc(-c4cc(-c5ccccc5)ccn4)c3)c2)cc1 ; c1ccc(-c2ccc(-c3cc(-c4ccc(-c5ccccn5)cc4)nc(-c4cc(-c5cccc6ccccc56)cc(-c5cccc6ccccc56)c4)n3)cc2)nc1]

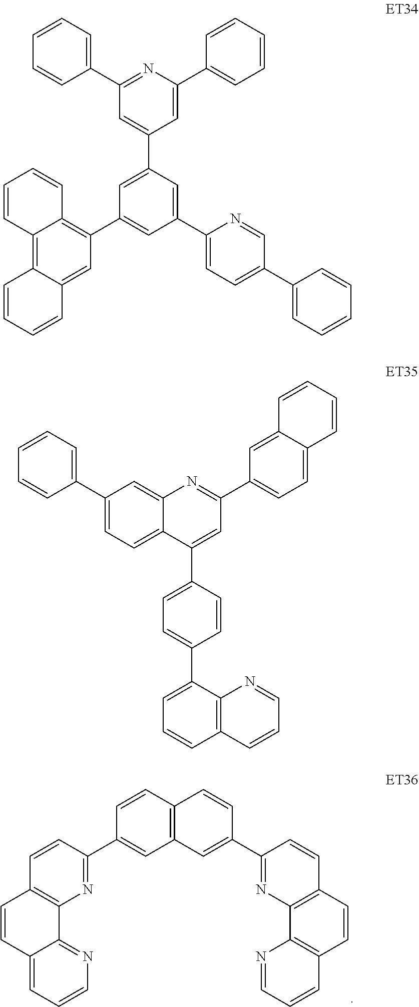

In embodiments, the electron transport region ETR may include a metal halide such as LiF, NaCl, CsF, RbCl, RbI, CuI and/or KI, a metal of the lanthanoides such as Yb, and/or a co-depositing material of the metal halide and the metal in lanthanoides. For example, the electron transport region ETR may include KI:Yb, RbI:Yb, LiF:Yb, etc., as the co-depositing material. In embodiments, the electron transport region ETR may use a metal oxide such as Li₂O and/or BaO, and/or 8-hydroxy-lithium quinolate (Liq). However, an embodiment of the present disclosure is not limited thereto. The electron transport region ETR also may be formed using a mixture material of an electron transport material and an insulating organo metal salt (e.g., an electrically insulating organo metal salt). The organo metal salt may be a material having an energy band gap of about 4 eV or more. In embodiments, the organo metal salt may include, for example, metal acetates, metal benzoates, metal acetoacetates, metal acetylacetonates, and/or metal stearates.

The electron transport region ETR may include at least one of 2,9-dimethyl-4,7-diphenyl-1,10-phenanthroline (BCP), diphenyl(4-(triphenylsilyl)phenyl)phosphine oxide (TSPO1) or 4,7-diphenyl-1,10-phenanthroline (Bphen) in addition to the aforementioned materials. However, an embodiment of the present disclosure is not limited thereto.

The electron transport region ETR may include the compounds of the electron transport region in at least one among an electron injection layer EIL, an electron transport layer ETL, and a hole blocking layer HBL.

If the electron transport region ETR includes the electron transport layer ETL, the thickness of the electron transport layer ETL may be from about 100 Å to about 1,000 Å, for example, from about 150 Å to about 500 Å. If the thickness of the electron transport layer ETL satisfies the above-described ranges, suitable or satisfactory electron transport properties may be obtained without substantial increase of a driving voltage. If the electron transport region ETR includes the electron injection layer EIL, the thickness of the electron injection layer EIL may be from about 1 Å to about 100 Å, or from about 3 Å to about 90 Å. If the thickness of the electron injection layer EIL satisfies the above described ranges, suitable or satisfactory electron injection properties may be obtained without inducing substantial increase of a driving voltage.

The second electrode EL2 is provided on the electron transport region ETR. The second electrode EL2 may be a common electrode. The second electrode EL2 may be a cathode or an anode, but an embodiment of the present disclosure is not limited thereto. For example, if the first electrode EL1 is an anode, the second cathode EL2 may be a cathode, and if the first electrode EL1 is a cathode, the second electrode EL2 may be an anode. The second electrode EL2 may include at least one selected among Ag, Mg, Cu, Al, Pt, Pd, Au, Ni, Nd, Ir, Cr, Li, Ca, LiF, Mo, Ti, W, In, Sn, and Zn, compounds of two or more selected therefrom, mixtures of two or more selected therefrom, and/or oxides thereof.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

The second electrode EL2 may be a transmissive electrode, a transflective electrode or a reflective electrode. If the second electrode EL2 is the transmissive electrode, the second electrode EL2 may include a transparent metal oxide, for example, ITO, IZO, ZnO, ITZO, etc.

If the second electrode EL2 is the transflective electrode or the reflective electrode, the second electrode EL2 may include Ag, Mg, Cu, Al, Pt, Pd, Au, Ni, Nd, Ir, Cr, Li, Ca, LiF/Ca (stacked structure of LiF and Ca), LiF/Al (stacked structure of LiF and Al), Mo, Ti, Yb, W, compounds including thereof, and/or mixtures thereof (for example, AgMg, AgYb, or MgAg). In embodiments, the second electrode EL2 may have a multilayered structure including a reflective layer or a transflective layer formed using the above-described materials and a transparent conductive layer formed using ITO, IZO, ZnO, ITZO, etc. For example, the second electrode EL2 may include the aforementioned metal materials, combinations of two or more metal materials selected from the aforementioned metal materials, and/or oxides of the aforementioned metal materials.

In embodiments, the second electrode EL2 may be connected with an auxiliary electrode. If the second electrode EL2 is connected with the auxiliary electrode, the resistance (e.g., electrical resistance) of the second electrode EL2 may decrease.

In embodiments, on the second electrode EL2 in the light emitting element ED of an embodiment, a capping layer CPL may be further provided. The capping layer CPL may include a multilayer or a single layer.

In an embodiment, the capping layer CPL may be an organic layer and/or an inorganic layer. For example, if the capping layer CPL includes an inorganic material, the inorganic material may include an alkali metal compound such as LiF, an alkaline earth metal compound such as MgF₂, SiON, SiNx, SiOy, etc.

For example, if the capping layer CPL includes an organic material, the organic material may include 2,2′-dimethyl-N,N′-di-[(1-naphthyl)-N,N′-diphenyl]-1,1′-biphenyl-4,4′-diamine (α-NPD), NPB, TPD, m-MTDATA, Alq₃, CuPc, N4,N4,N4′,N4′-tetra(biphenyl-4-yl) biphenyl-4,4′-diamine (TPD15), 4,4′,4″-tris(carbazol sol-9-yl) triphenylamine (TCTA), etc., and/or includes an epoxy resin, and/or acrylate such as methacrylate. In embodiments, a capping layer CPL may include at least one among Compounds P1 to P5 below, but an embodiment of the present disclosure is not limited thereto.

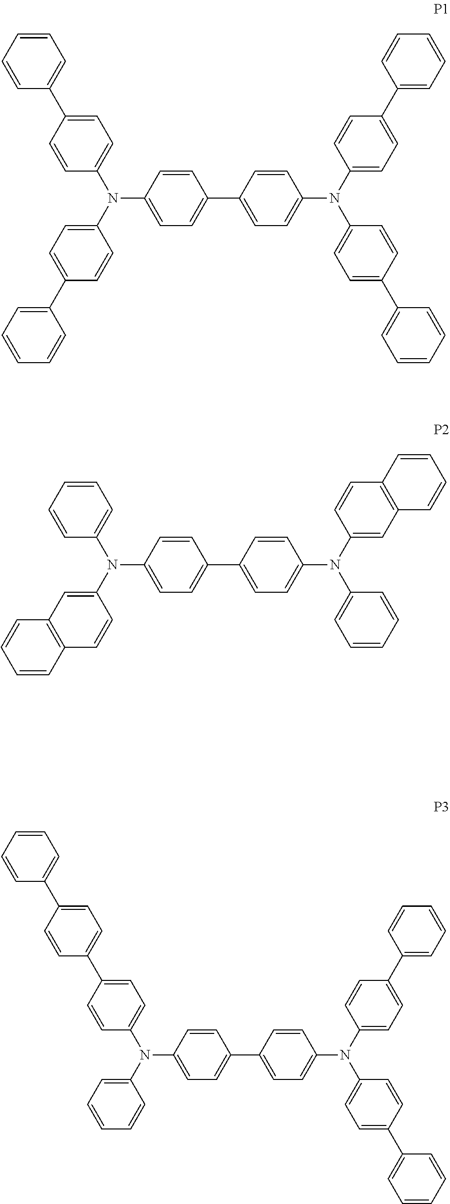 [SMILES: c1ccc(-c2ccc(N(c3ccc(-c4ccccc4)cc3)c3ccc(-c4ccc(N(c5ccc(-c6ccccc6)cc5)c5ccc(-c6ccccc6)cc5)cc4)cc3)cc2)cc1 ; c1ccc(N(c2ccc(-c3ccc(N(c4ccccc4)c4ccc5ccccc5c4)cc3)cc2)c2ccc3ccccc3c2)cc1 ; c1ccc(-c2ccc(-c3ccc(N(c4ccccc4)c4ccc(-c5ccc(N(c6ccc(-c7ccccc7)cc6)c6ccc(-c7ccccc7)cc6)cc5)cc4)cc3)cc2)cc1]

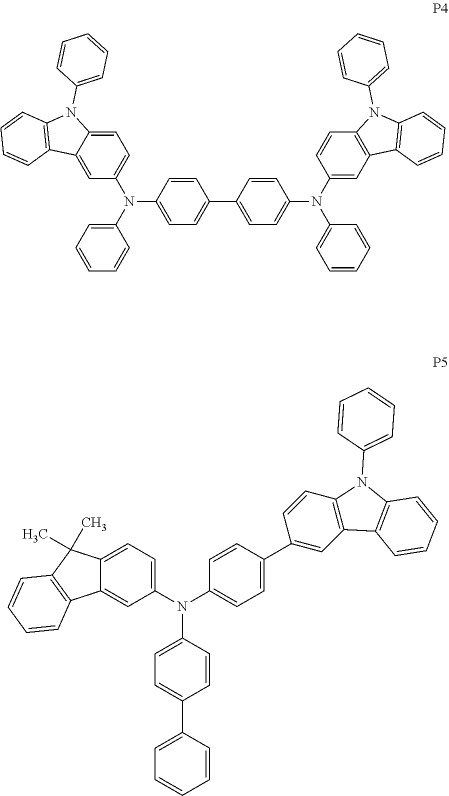 [SMILES: c1ccc(N(c2ccc(-c3ccc(N(c4ccccc4)c4ccc5c(c4)c4ccccc4n5-c4ccccc4)cc3)cc2)c2ccc3c(c2)c2ccccc2n3-c2ccccc2)cc1 ; CC1(C)c2ccccc2-c2cc(N(c3ccc(-c4ccccc4)cc3)c3ccc(-c4ccc5c(c4)c4ccccc4n5-c4ccccc4)cc3)ccc21]

In embodiments, the refractive index of the capping layer CPL may be about 1.6 or more. For example, the refractive index of the capping layer CPL with respect to light in a wavelength range of about 550 nm to about 660 nm may be about 1.6 or more.

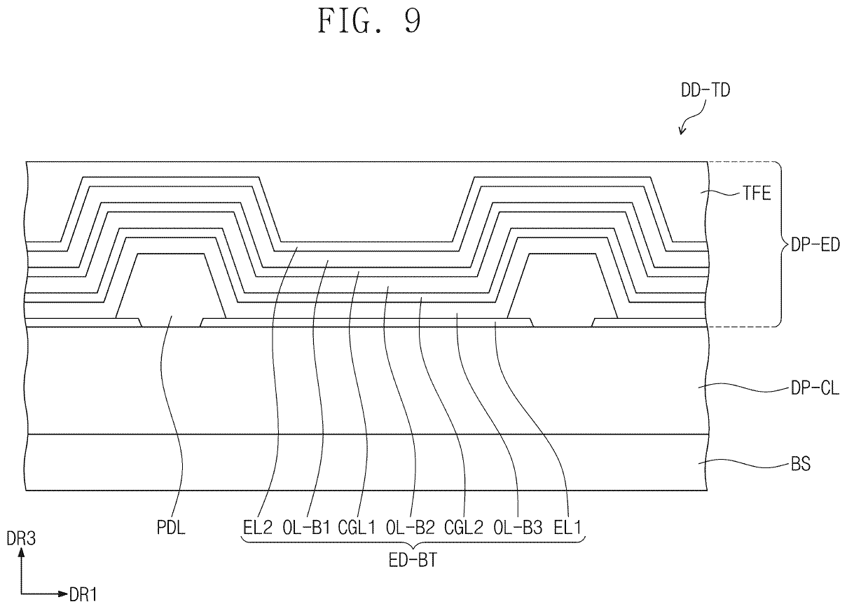

FIG. 8 to FIG. 11 are cross-sectional views of display apparatuses according to embodiments, respectively. In the explanation of the display apparatuses of embodiments referring to FIG. 8 to FIG. 11, the overlapping parts with the explanation on FIG. 1 to FIG. 7 will not be explained again, and the different features will be explained chiefly.

Referring to FIG. 8, the display apparatus DD-a according to an embodiment may include a display panel DP including a display device layer DP-ED, a light controlling layer CCL on the display panel DP and a color filter layer CFL.

In an embodiment shown in FIG. 8, the display panel DP includes a base layer BS, a circuit layer DP-CL provided on the base layer BS and a display device layer DP-ED, and the display device layer DP-ED may include a light emitting element ED.

The light emitting element ED may include a first electrode EL1, a hole transport region HTR on the first electrode EL1, a light-emitting layer EML on the hole transport region HTR, an electron transport region ETR on the light-emitting layer EML, and a second electrode EL2 on the electron transport region ETR. In embodiment, the same structures as the light emitting elements of FIG. 3 to FIG. 7 may be applied to the structure of the light emitting element ED shown in FIG. 8.

The hole transport region HTR of the light emitting element ED included in the display device DD-a according to an embodiment may include the first hole transport layer HTL1 including the first compound and the second compound of an embodiment described above, and the second hole transport layer HTL2 including the second compound.

Referring to FIG. 8, the light-emitting layer EML may be provided in an opening part OH defined in a pixel definition layer PDL. For example, the light-emitting layer EML divided by the pixel definition layer PDL and correspondingly provided to each of light emitting regions PXA-R, PXA-G and PXA-B may emit light in the same wavelength region. In the display apparatus DD-a of an embodiment, the light-emitting layer EML may emit blue light. In embodiments, different from the drawings, the light-emitting layer EML may be provided as a common layer for all light emitting regions PXA-R, PXA-G and PXA-B.

The light controlling layer CCL may be on the display panel DP. The light controlling layer CCL may include a light converter. The light converter may be a quantum dot and/or a phosphor. The light converter may transform the wavelength of light provided and then emit different light. For example, the light controlling layer CCL may be a layer including a quantum dot and/or a layer including a phosphor.

The light controlling layer CCL may include a plurality of light controlling parts CCP1, CCP2 and CCP3. The light controlling parts CCP1, CCP2 and CCP3 may be separated from one another.

Referring to FIG. 8, a partition pattern BMP may be between the separated light controlling parts CCP1, CCP2 and CCP3, but an embodiment of the present disclosure is not limited thereto. In FIG. 8, the partition pattern BMP is shown not to be overlapped with the light controlling parts CCP1, CCP2 and CCP3, but at least a portion of the edge of the light controlling parts CCP1, CCP2 and CCP3 may be overlapped with the partition pattern BMP.

The light controlling layer CCL may include a first light controlling part CCP1 including a first quantum dot QD1 that converts a first color light provided from the light emitting element ED into a second color light, a second light controlling part CCP2 including a second quantum dot QD2 that converts the first color light into a third color light, and a third light controlling part CCP3 that transmits the first color light.

In an embodiment, the first light controlling part CCP1 may provide red light which is the second color light, and the second light controlling part CCP2 may provide green light which is the third color light. The third color controlling part CCP3 may transmit and provide blue light which is the first color light provided from the light emitting element ED. For example, the first quantum dot QD1 may be a red quantum dot, and the second quantum dot QD2 may be a green quantum dot. On the quantum dots QD1 and QD2, the same contents as those described above may be applied.

In embodiments, the light controlling layer CCL may further include a scatterer SP (e.g., a light scatterer SP). The first light controlling part CCP1 may include the first quantum dot QD1 and the scatterer SP, the second light controlling part CCP2 may include the second quantum dot QD2 and the scatterer SP, and the third light controlling part CCP3 may not include a quantum dot but include the scatterer SP.

The scatterer SP may be an inorganic particle. For example, the scatterer SP may include at least one among TiO₂, ZnO, Al₂O₃, SiO₂, and hollow silica. The scatterer SP may include at least one among TiO₂, ZnO, Al₂O₃, SiO₂, and hollow silica, or may be a mixture of two or more materials selected among TiO₂, ZnO, Al₂O₃, SiO₂, and hollow silica.

Each of the first light controlling part CCP1, the second light controlling part CCP2, and the third light controlling part CCP3 may include base resins BR1, BR2 and BR3 that disperse the quantum dots QD1 and QD2 and the scatterer SP. In an embodiment, the first light controlling part CCP1 may include the first quantum dot QD1 and the scatterer SP dispersed in the first base resin BR1, the second light controlling part CCP2 may include the second quantum dot QD2 and the scatterer SP dispersed in the second base resin BR2, and the third light controlling part CCP3 may include the scatterer particle SP dispersed in the third base resin BR3.

The base resins BR1, BR2 and BR3 are mediums in which the quantum dots QD1 and QD2 and the scatterer SP are dispersed, and may be composed of various suitable resin compositions which may be generally referred to as a binder. For example, the base resins BR1, BR2 and BR3 may be acrylic resins, urethane-based resins, silicone-based resins, epoxy-based resins, etc. The base resins BR1, BR2 and BR3 may be transparent resins. In an embodiment, the first base resin BR1, the second base resin BR2 and the third base resin BR3 may be the same or different from each other.

The light controlling layer CCL may include a barrier layer BFL1. The barrier layer BFL1 may play the role of blocking or reducing the penetration of moisture and/or oxygen (hereinafter, may be referred to as “humidity/oxygen”). The barrier layer BFL1 may block or reduce the exposure of the light controlling parts CCP1, CCP2 and CCP3 to humidity/oxygen. In embodiments, the barrier layer BFL1 may cover the light controlling parts CCP1, CCP2 and CCP3. In embodiments, a color filter layer CFL, which will be further explained below, may include a barrier layer BFL2 on the light controlling parts CCP1, CCP2 and CCP3.

The barrier layers BFL1 and BFL2 may include at least one inorganic layer. In embodiments, the barrier layers BFL1 and BFL2 may be formed by including an inorganic material. For example, the barrier layers BFL1 and BFL2 may be formed by including silicon nitride, aluminum nitride, zirconium nitride, titanium nitride, hafnium nitride, tantalum nitride, silicon oxide, aluminum oxide, titanium oxide, tin oxide, cerium oxide and/or silicon oxynitride and/or a metal thin film to secure light transmittance. In embodiments, the barrier layers BFL1 and BFL2 may further include an organic layer. The barrier layers BFL1 and BFL2 may be composed of a single layer or a plurality of layers.

In the display apparatus DD-a of an embodiment, the color filter layer CFL may be on the light controlling layer CCL. For example, the color filter layer CFL may be directly on the light controlling layer CCL. In this case, the barrier layer BFL2 may be omitted.

The color filter layer CFL may include filters CF1, CF2 and CF3. Each of the first to third filters CF1, CF2 and CF3 may be provided corresponding to a red light emitting region PXA-R, a green light emitting region PXA-G, and a blue light emitting region PXA-B, respectively.

The color filter layer CFL may include a first filter CF1 that transmits the second color light, a second filter CF2 that transmits the third color light, and a third filter CF3 that transmits the first color light. For example, the first filter CF1 may be a red filter, the second filter CF2 may be a green filter, and the third filter CF3 may be a blue filter. Each of the filters CF1, CF2 and CF3 may include a polymer photosensitive resin and a pigment and/or dye. The first filter CF1 may include a red pigment and/or dye, the second filter CF2 may include a green pigment and/or dye, and the third filter CF3 may include a blue pigment and/or dye.

An embodiment of the present disclosure is not limited thereto, and the third filter CF3 may not include the pigment or dye. The third filter CF3 may include a polymer photosensitive resin and not include a pigment or dye. The third filter CF3 may be transparent. The third filter CF3 may be formed using a transparent photosensitive resin.

In an embodiment, the first filter CF1 and the second filter CF2 may be yellow filters. The first filter CF1 and the second filter CF2 may be provided in one body without distinction.

In embodiments, the color filter layer CFL may further include a light blocking part. The color filter layer CFL may include the light blocking part to overlap the boundaries of neighboring filters CF1, CF2, and CF3. The light blocking part may be a black matrix. The light blocking part may be formed by including an organic light blocking material and/or an inorganic light blocking material including a black pigment and/or black dye. The light blocking part may prevent or reduce light leakage phenomenon and divide the boundaries among adjacent filters CF1, CF2 and CF3.

On the color filter layer CFL, a base substrate BL may be provided. The base substrate BL may be a member providing a base surface on which the color filter layer CFL, the light controlling layer CCL, etc. are provided. The base substrate BL may be a glass substrate, a metal substrate, a plastic substrate, etc. However, an embodiment of the present disclosure is not limited thereto, and the base substrate BL may be an inorganic layer, an organic layer or a composite material layer (e.g., a composite layer including an inorganic material and an organic material). In embodiments, different from the drawing, the base substrate BL may be omitted.

FIG. 9 is a cross-sectional view showing a portion of the display apparatus according to an embodiment. In a display apparatus DD-TD of an embodiment, the light emitting element ED-BT may include a plurality of light emitting structures OL-B1, OL-B2 and OL-B3. The light emitting element ED-BT may include oppositely provided first electrode EL1 and second electrode EL2, and the plurality of light emitting structures OL-B1, OL-B2 and OL-B3 stacked in order in a thickness direction and provided between the first electrode EL1 and the second electrode EL2. Each of the light emitting structures OL-B1, OL-B2 and OL-B3 may include a light-emitting layer EML (FIG. 7), and a hole transport region HTR and an electron transport region ETR provided with the light-emitting layer EML (FIG. 8) therebetween.

In embodiments, the light emitting element ED-BT included in the display apparatus DD-TD of an embodiment may be a light emitting element of a tandem structure including a plurality of light-emitting layers.

In an embodiment shown in FIG. 9, light emitted from the light emitting structures OL-B1, OL-B2 and OL-B3 may be all blue light. However, an embodiment of the present disclosure is not limited thereto, and the wavelength regions of light emitted from the light emitting structures OL-B1, OL-B2 and OL-B3 may be different from each other. For example, the light emitting element ED-BT including the plurality of light emitting structures OL-B1, OL-B2 and OL-B3 emitting light in different wavelength regions may emit white light.

Between neighboring light emitting structures OL-B1, OL-B2 and OL-B3, charge generating layers CGL1 and CGL2 may be provided. The charge generating layers CGL1 and CGL2 may include a p-type charge generating layer and/or an n-type charge generating layer.

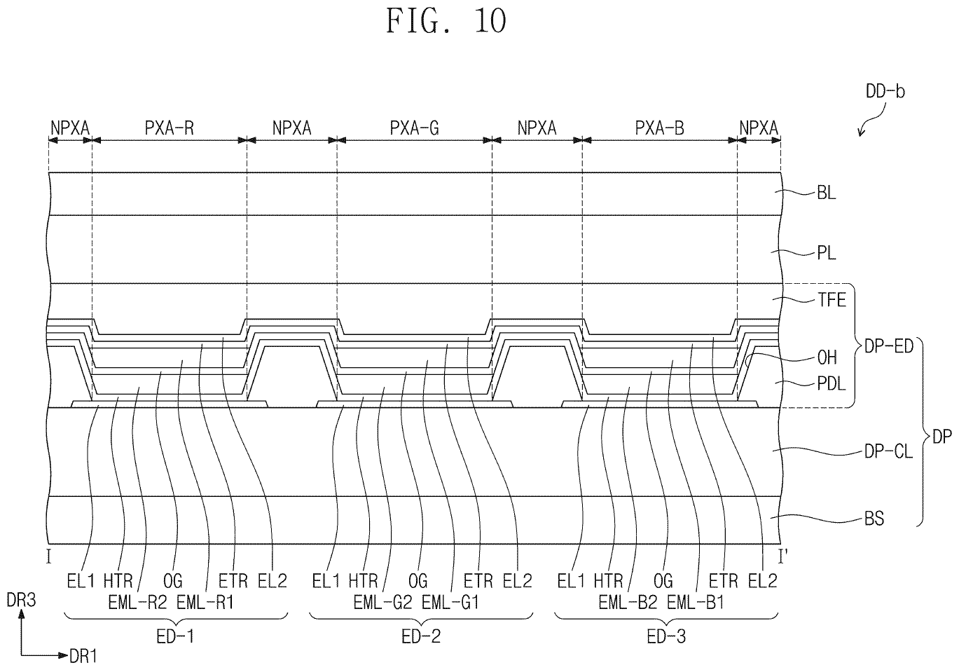

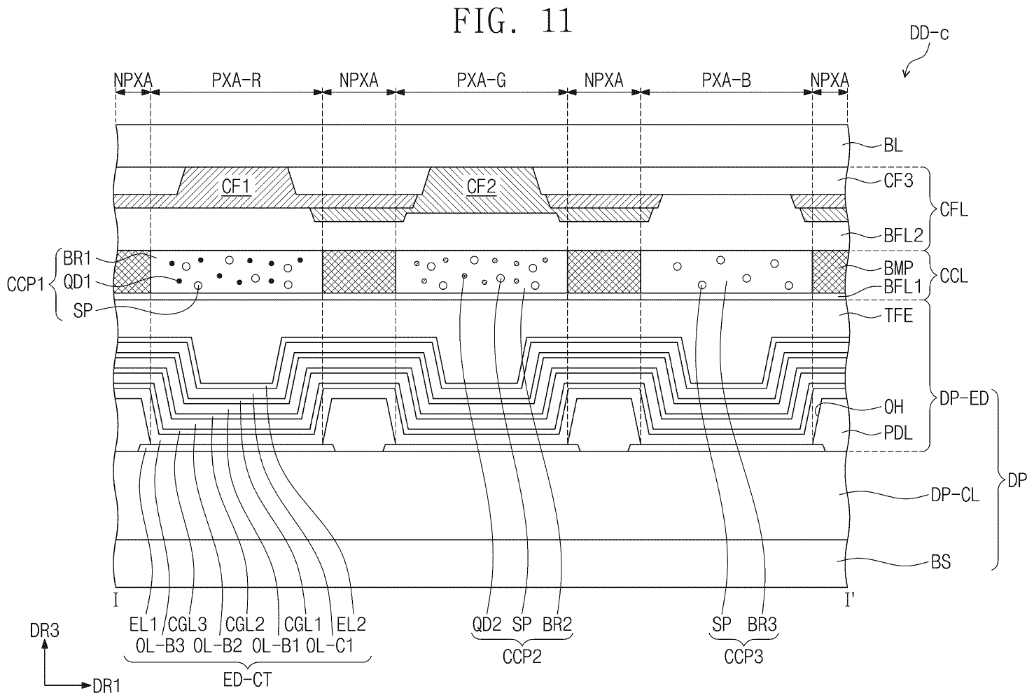

FIG. 10 is a cross-sectional view showing a display apparatus according to an embodiment of the present disclosure. FIG. 11 is a cross-sectional view showing a display apparatus according to an embodiment of the present disclosure.

Referring to FIG. 10, a display apparatus DD-b according to an embodiment may include light emitting elements ED-1, ED-2 and ED-3, formed by stacking two light-emitting layers. Compared to the display apparatus DD of an embodiment, shown in FIG. 2, an embodiment shown in FIG. 9 is different in that first to third light emitting elements ED-1, ED-2 and ED-3 include two light-emitting layers stacked in a thickness direction, each. In the first to third light emitting elements ED-1, ED-2 and ED-3, two light-emitting layers may emit light in the same wavelength region.

The first light emitting element ED-1 may include a first red light-emitting layer EML-R1 and a second red light-emitting layer EML-R2. The second light emitting element ED-2 may include a first green light-emitting layer EML-G1 and a second green light-emitting layer EML-G2. In embodiments, the third light emitting element ED-3 may include a first blue light-emitting layer EML-B1 and a second blue light-emitting layer EML-B2. Between the first red light-emitting layer EML-R1 and the second red light-emitting layer EML-R2, between the first green light-emitting layer EML-G1 and the second green light-emitting layer EML-G2, and between the first blue light-emitting layer EML-B1 and the second blue light-emitting layer EML-B2, an emission auxiliary part OG may be provided.

The emission auxiliary part OG may include a single layer or a multilayer. The emission auxiliary part OG may include a charge generating layer. In embodiments, the emission auxiliary part OG may include an electron transport region, a charge generating layer, and a hole transport region stacked in order. The emission auxiliary part OG may be provided as a common layer in all of the first to third light emitting elements ED-1, ED-2 and ED-3. However, an embodiment of the present disclosure is not limited thereto, and the emission auxiliary part OG may be patterned and provided in an opening part OH defined in a pixel definition layer PDL.

The first red light-emitting layer EML-R1, the first green light-emitting layer EML-G1 and the first blue light-emitting layer EML-B1 may be between the electron transport region ETR and the emission auxiliary part OG. The second red light-emitting layer EML-R2, the second green light-emitting layer EML-G2 and the second blue light-emitting layer EML-B2 may be between the emission auxiliary part OG and the hole transport region HTR.

In embodiments, the first light emitting element ED-1 may include a first electrode EL1, a hole transport region HTR, a second red light-emitting layer EML-R2, an emission auxiliary part OG, a first red light-emitting layer EML-R1, an electron transport region ETR, and a second electrode EL2, stacked in order. The second light emitting element ED-2 may include a first electrode EL1, a hole transport region HTR, a second green light-emitting layer EML-G2, an emission auxiliary part OG, a first green light-emitting layer EML-G1, an electron transport region ETR, and a second electrode EL2, stacked in order. The third light emitting element ED-3 may include a first electrode EL1, a hole transport region HTR, a second blue light-emitting layer EML-B2, an emission auxiliary part OG, a first blue light-emitting layer EML-B1, an electron transport region ETR, and a second electrode EL2, stacked in order.

In embodiments, an optical auxiliary layer PL may be on a display device layer DP-ED. The optical auxiliary layer PL may include a polarization layer. The optical auxiliary layer PL may be on a display panel DP and may control reflected light at the display panel DP by external light. Different from the drawings, the optical auxiliary layer PL may be omitted from the display apparatus according to an embodiment.

Different from FIG. 9 and FIG. 10, a display apparatus DD-c in FIG. 11 is shown to include four light emitting structures OL-B1, OL-B2, OL-B3 and OL-C1. A light emitting element ED-CT may include oppositely provided first electrode EL1 and second electrode EL2, and first to fourth light emitting structures OL-B1, OL-B2, OL-B3 and OL-C1 stacked in order in a thickness direction between the first electrode EL1 and the second electrode EL2. The third light emitting structures OL-B3, the second light emitting structures OL-B2, the first light emitting structures OL-B1, and the fourth light emitting structures OL-C1 are stacked in order in a thickness direction. Between the first to fourth light emitting structures OL-B1, OL-B2, OL-B3 and OL-C1, charge generating layers CGL1, CGL2 and CGL3 may be provided. For example, A first charge generating layer CGL1 is between the first light emitting structures OL-B1 and the fourth light emitting structures OL-C1. A second charge generating layer CGL2 is between the first light emitting structures OL-B1 and the second light emitting structures OL-B2. A third charge generating layer CGL3 is between the second light emitting structures OL-B2 and the third light emitting structures OL-B3.

Among the four light emitting structures, the first to third light emitting structures OL-B1, OL-B2 and OL-B3 emit blue light, and the fourth light emitting structure OL-C1 may emit green light. However, an embodiment of the present disclosure is not limited thereto, and the first to fourth light emitting structures OL-B1, OL-B2, OL-B3 and OL-C1 may emit different wavelengths of light.

Charge generating layers CGL1, CGL2 and CGL3 provided among neighboring light emitting structures OL-B1, OL-B2, OL-B3 and OL-C1 may include a p-type charge generating layer and/or an n-type charge generating layer.

The hole transport region HTR of the light-emitting element ED according to an embodiment of the present disclosure may include a first hole transport layer including the first compound and the second compound, and a second hole transport layer on the first hole transport layer and including the second compound. Accordingly, the light-emitting element ED according to an embodiment may exhibit improved luminous efficiency and improved lifespan characteristics.

In an embodiment, an electronic apparatus may include a display device including a plurality of light emitting elements and a control part controlling the display device. The electronic apparatus of an embodiment may be an apparatus activated according to electrical signals. The electronic apparatus may include display devices of various embodiments. For example, the electronic apparatus may include televisions, monitors, large-size display devices such as outside billboards, personal computers, laptop computers, personal digital terminals, display devices for automobiles, game consoles, portable electronic devices, and/or medium- and small-size display devices such as cameras.

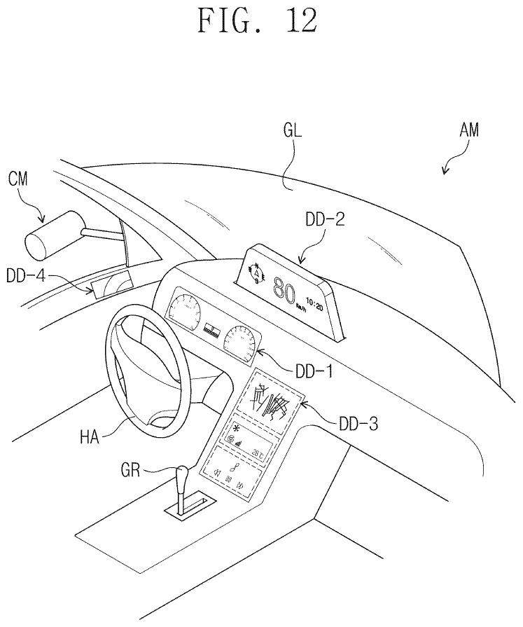

FIG. 12 is a diagram showing an automobile AM in which first to fourth display devices DD-1, DD-2, DD-3 and DD-4 are provided. At least one among the first to fourth display devices DD-1, DD-2, DD-3 and DD-4 may include the same configurations of the display devices DD, DD-TD, DD-a, DD-b and DD-c of embodiments, explained referring to FIGS. 1, 2, and 8 to 11.

In FIG. 12, a vehicle is shown as an automobile AM, but this is an example illustration, and the first to fourth display devices DD-1, DD-2, DD-3 and DD-4 may be on other transport means such as bicycles, motorcycles, trains, ships and/or airplanes. In addition, at least one among the first to fourth display devices DD-1, DD-2, DD-3 and DD-4 including the same configurations of the display devices DD, DD-TD, DD-a, DD-b and DD-c may be introduced in personal computers, laptop computers, personal digital terminals, game consoles, portable electronic devices, televisions, monitors, external billboards, and/or the like. In embodiments, these are suggested as examples, and the display device may be introduced in other electronic devices as long as not deviated from the spirit and scope of the present disclosure.

At least one among the first to fourth display devices DD-1, DD-2, DD-3, and DD-4 may include the light emitting element ED of an embodiment as described with reference to FIGS. 3-7. The light emitting element ED of an embodiment may include the hole transport region HTR including the first hole transport layer HTL1 including the first compound and the second compound, and the second hole transport layer HTL2 on the first hole transport layer and including the second compound. At least one among the first to fourth display devices DD-1, DD-2, DD-3, and DD-4 may include the light emitting element ED of an embodiment, thereby improving a display service life.

Referring to FIG. 12, an automobile AM may include a steering wheel HA for the operation of the automobile AM and a gear GR. In embodiments, the automobile AM may include a front window GL provided to face a driver.

A first display device DD-1 may be provided in a first region overlapping with the steering wheel HA. For example, the first display device DD-1 may be a digital cluster that displays the first information of the automobile AM. The first information may include a first graduation that shows the running speed of the automobile AM, a second graduation showing the number of revolution of an engine (e.g., revolutions per minute (RPM)), and images that show a fuel state. First graduation and second graduation may be represented by digital images.

A second display device DD-2 may be in a second region facing a driver's seat and overlapping with the front window GL. The driver's seat may be a seat where the steering wheel HA is provided. For example, the second display device DD-2 may be a head up display (HUD) that shows the second information of the automobile AM. The second display device DD-2 may be optically clear. The second information may include digital numbers that show the running speed of the automobile AM and may further include information including the current time. Different from the drawing, the second information of the second display device DD-2 may be projected and displayed on the front window GL.

A third display device DD-3 may be in a third region adjacent to the gear GR. For example, the third display device DD-3 may be a center information display (CID) for an automobile, between a driver's seat and a passenger seat and showing third information. The passenger seat may be a seat separated from the driver's seat with the gear GR therebetween. The third information may include information on road conditions (for example, navigation information), on playing music and/or radio, on playing a dynamic image (or image), on the temperature in the automobile AM, and/or the like.

A fourth display device DD-4 may be in a fourth region separated from the steering wheel HA and the gear GR and adjacent to the side of the automobile AM. For example, the fourth display device DD-4 may be a digital wing mirror that displays fourth information. The fourth display device DD-4 may display the external image of the automobile AM, taken by a camera module CM at the outside of the automobile AM. The fourth information may include the external image of the automobile AM.

The above-described first to fourth information is for illustration, and the first to fourth display devices DD-1, DD-2, DD-3 and DD-4 may further display information on the inside and outside of the automobile. The first to fourth information may include different information from each other. However, an embodiment of the present disclosure is not limited thereto, and a portion of the first to fourth information may include the same information.

Hereinafter, a light-emitting element according to an embodiment of the present disclosure will be specifically described with reference to Examples and Comparative Examples. The Examples described are examples to help understand the subject matter of the present disclosure, and a range of the present disclosure is not limited thereto.

### Example

### 1. Manufacturing and Evaluation of Light-Emitting Element.

A light-emitting element according to an embodiment including a hole transport region including a first hole transport layer including a first compound and a second compound, and a second hole transport layer including the second compound was manufactured by a method below. Light-emitting elements according to Examples 1 to 6 were manufactured using Compounds A1 to A6, which were each the first compound described above, and Compounds B1 to B3, which were each the second compound described above. Light-emitting elements according to Comparative Examples 1 to 3 have the same structure as the light-emitting elements according to Examples 1 to 6, but do not include, in the first hole transport layer, the first compound according to an embodiment. That is, the light-emitting elements according to Comparative Examples 1 to 6 correspond to light-emitting elements in which a layer corresponding to the first hole transport layer was formed of a single material of the second compound. The light-emitting elements according to Comparative Examples 4 and 5 have the same structure as the light-emitting elements according to Examples 1 to 6, but do not include the second compound according to an embodiment in the first hole transport layer. That is, the light-emitting elements according to Comparative Examples 4 and 5 correspond to light-emitting elements in which a layer corresponding to the first hole transport layer was formed of a single material of the first compound.

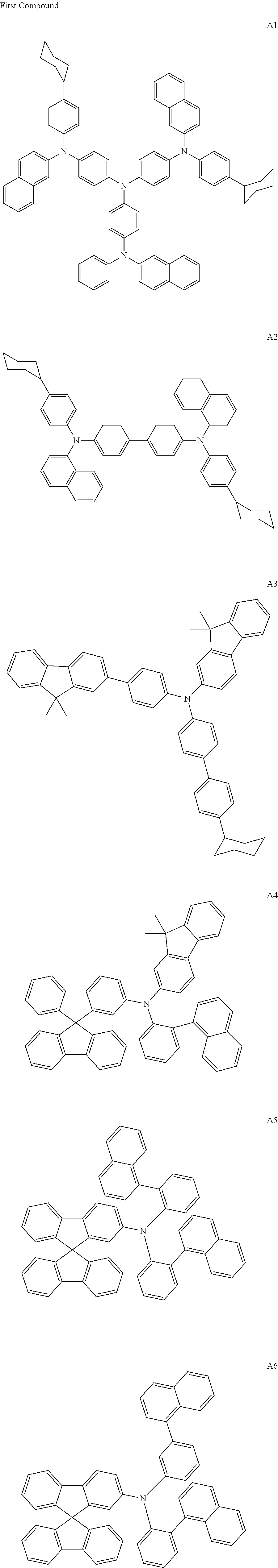

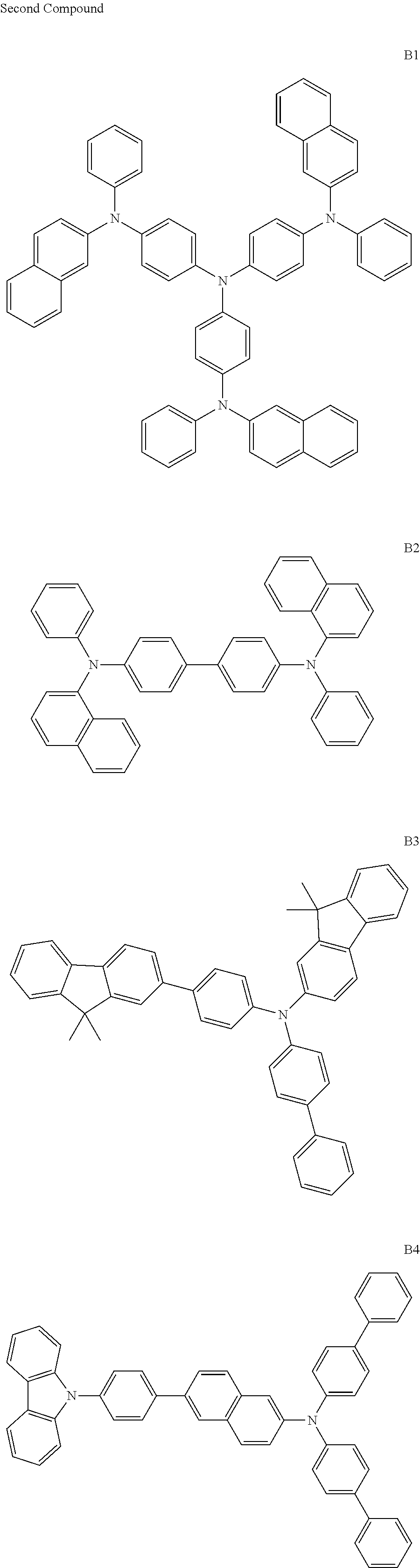 [SMILES: c1ccc(N(c2ccc(N(c3ccc(N(c4ccccc4)c4ccc5ccccc5c4)cc3)c3ccc(N(c4ccccc4)c4ccc5ccccc5c4)cc3)cc2)c2ccc3ccccc3c2)cc1 ; c1ccc(N(c2ccc(-c3ccc(N(c4ccccc4)c4cccc5ccccc45)cc3)cc2)c2cccc3ccccc23)cc1 ; CC1(C)c2ccccc2-c2ccc(-c3ccc(N(c4ccc(-c5ccccc5)cc4)c4ccc5c(c4)C(C)(C)c4ccccc4-5)cc3)cc21 ; c1ccc(-c2ccc(N(c3ccc(-c4ccccc4)cc3)c3ccc4cc(-c5ccc(-n6c7ccccc7c7ccccc76)cc5)ccc4c3)cc2)cc1]

### Manufacturing of Light-Emitting Element According to Example 1

After a glass substrate (a Corning product) on which an ITO electrode of 15 Ω/cm² (1200 Å) had been formed as an anode was cut at a size of about 50 mm×about 50 mm×about 0.5 mm, each cut glass substrate was ultrasonically cleaned using isopropyl alcohol and pure water for about 5 minutes, was cleaned by irradiating with ultraviolet light for about 30 minutes and being exposed to ozone, and then was installed in a vacuum deposition apparatus.

A first hole transport layer having a thickness of about 110 nm was formed by depositing, on the anode, Compound A1 and Compound A2 in a weight ratio of 1:1, and then a second hole transport layer having a thickness of about 10 nm was formed by depositing Compound B4 on the first hole transport layer.

Thereafter, a light-emitting layer having a thickness of about 30 nm was formed by co-depositing E2 and BD1 in a weight ratio of about 97:3, an auxiliary light-emitting layer having a thickness of about 10 nm was formed by depositing ET1 on the light-emitting layer, and then an electron transport layer having a thickness of about 20 nm was formed by depositing ET2 on the auxiliary light-emitting layer. Next, an electron injection layer was formed by depositing LiF of about 1 nm on the electron transport layer. A second electrode of aluminum having a thickness of about 100 nm was formed on the electron injection layer. Each layer was all formed by a vacuum deposition method.

### Manufacturing of Light-Emitting Element According to Example 2

A light-emitting element according to Example 2 was manufactured by the same method as the method for manufacturing the light-emitting element according to Example 1, except that compared to the light-emitting element according to Example 1, when the first hole transport layer was formed, Compound A2 was used instead of Compound A1, and Compound B2 was used instead of Compound B1.

### Manufacturing of Light-Emitting Element According to Example 3

A light-emitting element according to Example 3 was manufactured by the same method as the method for manufacturing the light-emitting element according to Example 1, except that compared to the light-emitting element according to Example 1, when the first hole transport layer was formed, Compound A3 was used instead of Compound A1, and Compound B3 was used instead of Compound B1.

### Manufacturing of Light-Emitting Element According to Example 4

A light-emitting element according to Example 4 was manufactured by the same method as the method for manufacturing the light-emitting element according to Example 1, except that compared to the light-emitting element according to Example 1, when the first hole transport layer was formed, Compound A4 was used instead of Compound A1, and Compound B3 was used instead of Compound B1.

### Manufacturing of Light-Emitting Element According to Example 5

A light-emitting element according to Example 5 was manufactured by the same method as the method for manufacturing the light-emitting element according to Example 1, except that compared to the light-emitting element according to Example 1, when the first hole transport layer was formed, Compound A5 was used instead of Compound A1, and Compound B3 was used instead of Compound B1.

### Manufacturing of Light-Emitting Element According to Example 6

A light-emitting element according to Example 6 was manufactured by the same method as the method for manufacturing the light-emitting element according to Example 1, except that compared to the light-emitting element according to Example 1, when the first hole transport layer was formed, Compound A6 was used instead of Compound A1, and Compound B3 was used instead of Compound B1.

### Manufacturing of Light-Emitting Element According to Comparative Example 1

After a glass substrate (a Corning product) on which an ITO electrode of 15 Ω/cm² (1200 Å) had been formed as an anode was cut at a size of about 50 mm×about 50 mm×about 0.5 mm, each cut glass substrate was ultrasonically cleaned using isopropyl alcohol and pure water for about 5 minutes, was cleaned by irradiating with ultraviolet light for about 30 minutes and being exposed to ozone, and then was installed in a vacuum deposition apparatus.

A first hole transport layer having a thickness of about 110 nm was formed by depositing Compound B1 on the anode, and then a second hole transport layer having a thickness of about 10 nm was formed by depositing Compound B4 on the first hole transport layer.

Thereafter, a light-emitting layer having a thickness of about 30 nm was formed by co-depositing E2 and BD1 in a weight ratio of about 97:3, an auxiliary light-emitting layer having a thickness of about 10 nm was formed by depositing ET1 on the light-emitting layer, and then an electron transport layer having a thickness of about 20 nm was formed by depositing ET2 on the auxiliary light-emitting layer. Next, an electron injection layer was formed by depositing LiF of about 1 nm on the electron transport layer. A second electrode of aluminum having a thickness of about 100 nm was formed on the electron injection layer. Each layer was all formed by a vacuum deposition method.

### Manufacturing of Light-Emitting Element According to Comparative Example 2

A light-emitting element according to Comparative Example 2 was manufactured by the same method as the method for manufacturing the light-emitting element according to Example 1, except that compared to the light-emitting element according to Comparative Example 1, when the first hole transport layer was formed, Compound B2 was used instead of Compound B1.

### Manufacturing of Light-Emitting Element According to Comparative Example 4

After a glass substrate (a Corning product) on which an ITO electrode of 15 Ω/cm² (1200 Å) had been formed as an anode was cut at a size of about 50 mm×about 50 mm×about 0.5 mm, each cut glass substrate was ultrasonically cleaned using isopropyl alcohol and pure water for about 5 minutes, was cleaned by irradiating with ultraviolet light for about 30 minutes and being exposed to ozone, and then was installed in a vacuum deposition apparatus.

A first hole transport layer having a thickness of about 110 nm was formed by depositing Compound A1 on the anode, and then a second hole transport layer having a thickness of about 10 nm was formed by depositing Compound B4 on the first hole transport layer.

Thereafter, a light-emitting layer having a thickness of about 30 nm was formed by co-depositing E2 and BD1 in a weight ratio of about 97:3, an auxiliary light-emitting layer having a thickness of about 10 nm was formed by depositing ET1 on the light-emitting layer, and then an electron transport layer having a thickness of about 20 nm was formed by depositing ET2 on the auxiliary light-emitting layer. Next, an electron injection layer was formed by depositing LiF of about 1 nm on the electron transport layer. A second electrode of aluminum having a thickness of about 100 nm was formed on the electron injection layer. Each layer was all formed by a vacuum deposition method.

### Manufacturing of Light-Emitting Element According to Comparative Example 5

A light-emitting element according to Comparative Example 5 was manufactured by the same method as the method for manufacturing the light-emitting element according to Example 1, except that compared to the light-emitting element according to Comparative Example 4, when the first hole transport layer was formed, Compound A5 was used instead of Compound A1.

Compounds used in manufacturing the light-emitting elements according to Examples and Comparative Examples are disclosed. The following materials were purified by sublimation of commercial products and used so as to manufacture the elements.

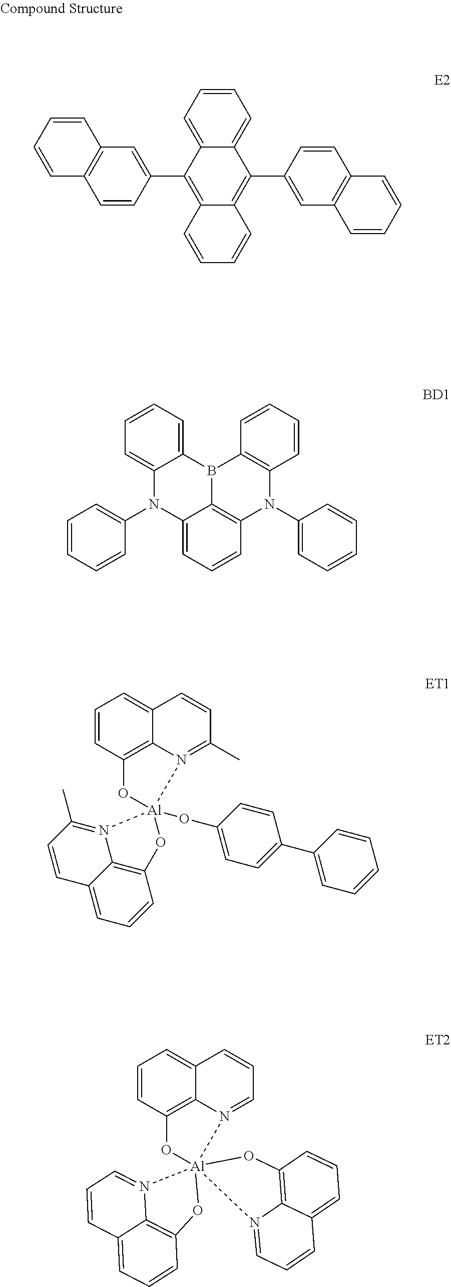

Evaluation of Properties of Compounds according to Examples and Comparative Examples

Table 1 below shows evaluation of properties of Compounds A₁ to A₆, which are the first compound, and Compounds B1 to B3, which are the second compound. Table 1 below shows results of measuring refractive indexes, HOMO energy levels, and LUMO energy levels of the first compound and the second compound. The refractive index was measured by using an ellipsometer apparatus for a thin-film including a compound in Table 1 below, and having a thickness of about 1000 Å. The refractive index values were measured utilizing a light source having a wavelength of about 460 nm. The HOMO and LUMO energy levels were measured using a Smart Manager software of a ZIVE LAB's SP2 electrochemical workstation apparatus.

TABLE 1

| Compound | Refractive Index | HOMO (eV) | LUMO (eV) |
|---|---|---|---|
| Compound A1 | 1.82 | −5.0 | −1.2 |
| Compound A2 | 1.76 | −5.3 | −2.2 |
| Compound A3 | 1.84 | −5.0 | −1.2 |
| Compound A4 | 1.83 | −5.0 | −1.2 |
| Compound A5 | 1.81 | −5.1 | −1.2 |
| Compound A6 | 1.80 | −5.1 | −1.1 |
| Compound B1 | 1.92 | −5.1 | −2.0 |
| Compound B2 | 1.91 | −5.3 | −2.2 |
| Compound B3 | 1.99 | −5.0 | −1.2 |

### Evaluation of Characteristics of Light-Emitting Elements

Element efficiency and element lifespan of light-emitting elements manufactured according to the element manufacturing-examples described above were evaluated. Table 2 shows evaluation results of the light-emitting elements according to Examples 1 to 6, and Comparative Examples 1 to 5. A driving voltage, efficiency (Cd/A), and lifespan in the evaluation results of characteristics of the light-emitting elements according to Examples and Comparative Examples shown in Table 2 were measured using a Keithley SMU 236, and a luminance meter, SR3AR and PR 650. In order to evaluate the characteristics of the light-emitting elements according to Examples 1 to 6, and Comparative Examples 1 to 5, the driving voltage at a current density of about 10 mA/cm², and the efficiency (Cd/A) were measured, and time taken to reach about 97% of initial luminance compared to the initial luminance when continuously driven at the current density of about 10 mA/cm² was measured. A relative comparison value was shown as the element lifespan with respect to 100% of the element lifespan according to Comparative Example 1. A progressive driving voltage in Table 2 was measured by calculating a difference between a driving voltage measured when the lifespan evaluation was started, and a driving voltage measured when the lifespan evaluation lasted for about 200 hours. For example, the progressive driving voltage may be calculated by Equation 1 below.

$$Progresive driving voltage = {V}_{1} - {V}_{2} \qquad Equation 1$$

In Equation 1, V₂ means the initial driving voltage measured when the lifespan evaluation was started, and V₁ means the driving voltage measured when the lifespan evaluation lasted for about 200 hours.

TABLE 2

| | | Second | | | | |
|---|---|---|---|---|---|---|
| | First hole | hole | Driving | | | |
| | transport | transport | voltage | Efficiency | Lifespan | Progressive |
| | layer | layer | (V) | (Cd/A) | (%) | driving |
| Example 1 | Compound | Compound | 4.9 | 6.4 | 101% | +0.14 |
| | A1 | B4 | | | | |
| | Compound | | | | | |
| | B1 | | | | | |
| Example 2 | Compound | Compound | 4.7 | 6.2 | 112% | +0.15 |
| | A2 | B4 | | | | |
| | Compound | | | | | |
| | B2 | | | | | |
| Example 3 | Compound | Compound | 4.9 | 6.2 | 120% | +0.15 |
| | A3 | B4 | | | | |
| | Compound | | | | | |
| | B3 | | | | | |
| Example 4 | Compound | Compound | 4.8 | 6.3 | 122% | +0.11 |
| | A4 | 4 | | | | |
| | Compound | | | | | |
| | B3 | | | | | |
| Example 5 | Compound | Compound | 4.8 | 6.1 | 125% | +0.11 |
| | A5 | B4 | | | | |
| | Compound | | | | | |
| | B3 | | | | | |
| Example 6 | Compound | Compound | 4.8 | 6.1 | 121% | +0.12 |
| | A6 | B4 | | | | |
| | Compound | | | | | |
| | B3 | | | | | |
| Comparative | Compound | Compound | 4.7 | 5.9 | 100% | +0.05 |
| Example 1 | B1 | B4 | | | | |
| Comparative | Compound | Compound | 4.6 | 5.7 | 113% | +0.07 |
| Example 2 | B2 | B4 | | | | |
| Comparative | Compound | Compound | 4.8 | 5.7 | 122% | +0.07 |
| Example 3 | B3 | B4 | | | | |
| Comparative | Compound | Compound | 5.3 | 6.7 | 62% | +0.51 |
| Example 4 | A1 | B4 | | | | |
| Comparative | Compound | Compound | 5.1 | 6.8 | 79% | +0.35 |
| Example 5 | A5 | B4 | | | | |

Referring to Tables 1 and 2, it can be seen that the light-emitting elements according to Examples including the first hole transport layer in which the first compound and the second compound according to an embodiment of the present disclosure are mixed together, and the second hole transport layer on the first hole transport layer, and including the second compound have more improved luminous efficiency and lifespan characteristics than the light-emitting elements according to Comparative Examples. The light-emitting elements according to Comparative Examples 1 to 3 exhibit more deteriorated luminous efficiency than the light-emitting elements according to Examples. It is thought that a layer corresponding to the first hole transport layer of each of the light-emitting elements according to Comparative Examples 1 to 3 is formed of a single material of the second compound, unlike a layer corresponding to the first hole transport layer of each of the light-emitting elements according to Examples, to increase a refractive index difference between the first hole transport layer and the first electrode, thereby deteriorating the luminous efficiency of the light-emitting elements according to Comparative Examples 1 to 3.

It can be seen that the light-emitting elements according to Comparative Examples 4 and 5 exhibit more improved luminous efficiency but remarkably more reduced element lifespan than the light-emitting elements according to Examples. It is thought that a layer corresponding to the first hole transport layer of each of the light-emitting elements according to Comparative Examples 4 and 5 is formed of a single material of the first compound, unlike a layer corresponding to the first hole transport layer of each of the light-emitting elements according to Examples, to prevent or reduce light loss caused in a light extraction process by reducing a refractive index difference between the thin-films caused by introduction of the first compound, but the light-emitting elements according to Comparative Examples 4 and 5 have deteriorated thin-film stability compared the light-emitting elements according to Examples in which mixed materials are introduced, thereby deteriorating lifespan characteristics. The first compound represented by Chemical Formula 1 may include an alkyl group to have a structure of which a form itself is twisted. Accordingly, in cases of the light-emitting elements according to Comparative Examples 4 and 5 including only the first compound in the first hole transport layer, when the elements are driven, the material may be easily modified due to the structural feature of the first compound so that the light-emitting elements each have a short lifespan. However, it can be seen that in cases of the light-emitting elements according to Examples, the first hole transport layer may include a mixture of the first compound and the second compound to reduce an energy loaded on the material and to mitigate material modification, thereby improving the element lifespan.

Referring to the results of Table 1 and 2, it can be seen that the light-emitting elements according to Examples including the first hole transport layer including the first compound and the second compound having different refractive indexes, and the second hole transport layer including the second compound show more improved element characteristics such as luminous efficiency and element lifespan than the light-emitting elements according to Comparative Examples. The light-emitting element according to an embodiment may include the hole transport region having a stack structure of the first hole transport layer including the first compound and the second compound, and the second hole transport layer including the second compound, thereby exhibiting a high light extraction effect, and thus exhibiting excellent luminous efficiency characteristics.

A light-emitting element according to an embodiment may exhibit improved element characteristics such as high efficiency and long lifespan.

A display device according to an embodiment may include a light-emitting element having excellent efficiency and lifespan.

In the above, description has been made with reference to example embodiments of the present disclosure, but those skilled in the art or those of ordinary skill in the relevant technical field may understand that various suitable modifications and changes may be made to the present disclosure within the scope not departing from the spirit and the technology scope of the present disclosure described in the claims below.

Therefore, the technical scope of the present disclosure is not limited to the contents described in the detailed description of the specification, but should be determined by the appended claims, and equivalents thereof.

What is claimed is:

1. A light-emitting element comprising:
a first electrode;
a hole transport region on the first electrode;
a light-emitting layer on the hole transport region;
an electron transport region on the light-emitting layer; and
a second electrode on the electron transport region,
wherein the hole transport region comprises:
a first hole transport layer between the first electrode and the light-emitting layer, and comprising a first compound represented by Chemical Formula 1 below, and a second compound different from the first compound, and represented by Chemical Formula 2-1 or Chemical Formula 2-2 below; and
a second hole transport layer between the first hole transport layer and the light-emitting layer, and comprising the second compound, 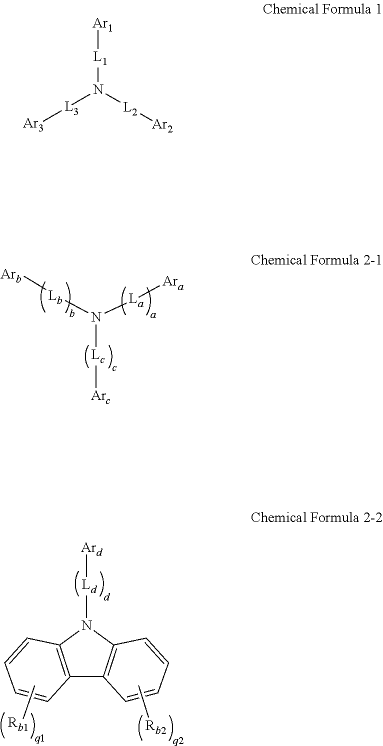
where in Chemical Formula 1, Chemical Formula 2-1, and Chemical Formula 2-2 above,
Ar₁ to Ar₃, and Arₐ to Ar_{c} are each independently a substituted or unsubstituted amine group, a substituted or unsubstituted aryl group having a ring-forming carbon number of 6 to 30, or a substituted or unsubstituted heteroaryl group having a ring-forming carbon number of 2 to 30,
Ar_{d} is a substituted or unsubstituted aryl group having a ring-forming carbon number of 6 to 30, or a substituted or unsubstituted heteroaryl group having a ring-forming carbon number of 2 to 30,
R_{b1} and R_{b2} are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or bonded to an adjacent group to form a ring,
q1 and q2 are each independently an integer of 0 to 4,
L₁ to L₃, and Lₐ to L_{d} are each independently a direct linkage, a substituted or unsubstituted arylene group having a ring-forming carbon number of 6 to 30, or a substituted or unsubstituted heteroarylene group having a ring-forming carbon number of 2 to 30,
a to d are each independently an integer of 0 to 10,
in Chemical Formula 1, at least one among L₁ to L₃ is a phenylene group represented by Chemical Formula A-1 below, or Chemical Formula A-2 below, or a substituted or unsubstituted divalent naphthyl group, or at least one among Ar₁ to Ar₃ is substituted for a substituted or unsubstituted cycloalkyl group having a carbon number of 3 to 20, 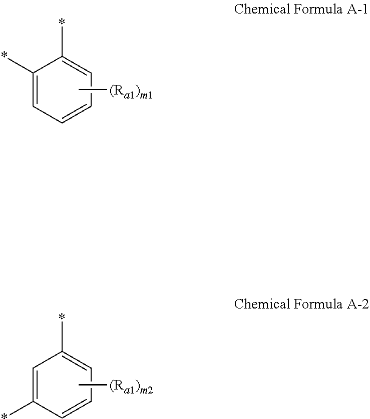
where in Chemical Formula A-1 and Chemical Formula A-2 above,
Rₐ₁ and Rₐ₂ are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
m1 and m2 are each independently an integer of 0 to 4.

2. The light-emitting element of claim 1, wherein the first compound has a first refractive index, and the second compound has a second refractive index greater than the first refractive index.

3. The light-emitting element of claim 2, wherein the first refractive index is about 1.20 to about 1.85 at a wavelength of about 460 nm, and the second refractive index is about 1.90 to about 2.50 at a wavelength of about 460 nm.

4. The light-emitting element of claim 2, wherein a difference between the first refractive index and the second refractive index is greater than about 0.1.

5. The light-emitting element of claim 1, wherein the first hole transport layer is directly on the first electrode.

6. The light-emitting element of claim 1, wherein the first electrode is a reflective electrode, and the second electrode is a transmissive electrode or a semi-transmissive electrode.

7. The light-emitting element of claim 1, wherein in the first hole transport layer, a content of the first compound is equal to or more than about 10% by weight of the total weight of the first compound and the second compound.

8. The light-emitting element of claim 1, wherein the first hole transport layer comprises the first compound and the second compound.

9. The light-emitting element of claim 1, wherein an absolute value of a difference between a HOMO energy level of the first compound and a HOMO energy level of the second compound is equal to or less than about 0.5 eV.

10. The light-emitting element of claim 1, wherein the first compound is represented by Chemical Formula 1-1 or Chemical Formula 1-2 below. 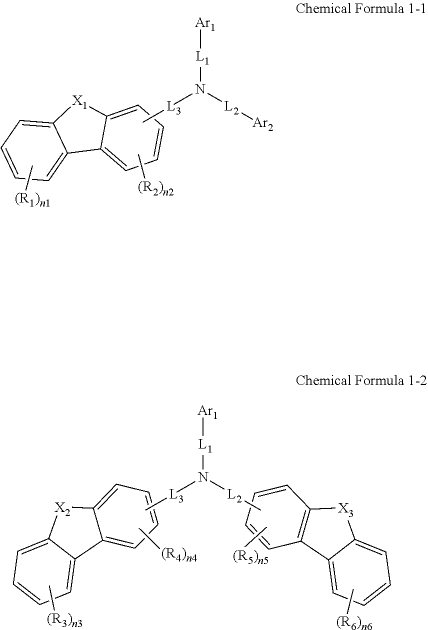
where in Chemical Formula 1-1 and Chemical Formula 1-2 above,
X₁ to X₃ are each independently CR₇R₈, NR₉, O, S, or Se,
R₁ to R₉ are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, or bonded to an adjacent group to form a ring,
n1, n3, and n6 are each independently an integer of 0 to 4,
n2, n4, and n5 are each independently an integer of 0 to 3, and
Ar₁, Ar₂, and L₁ to L₃ are the same as what is defined with respect to Chemical Formula 1 above.

11. The light-emitting element of claim 1, wherein the first compound is represented by any one among Chemical Formula 1-4 to Chemical Formula 1-6 below, 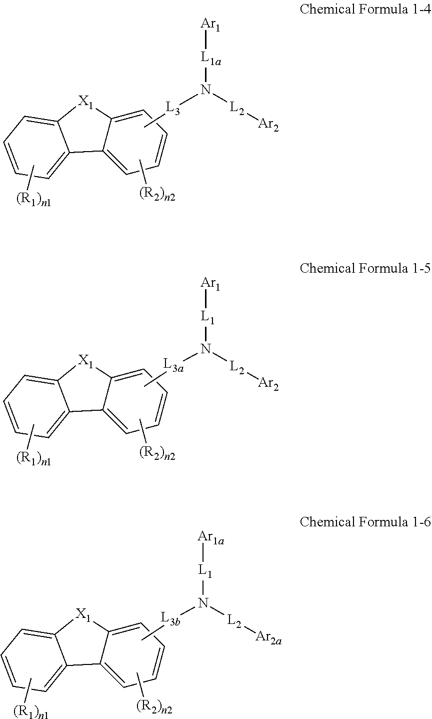
where in Chemical Formula 1-4 to Chemical Formula 1-6 above,
X₁ is CR₇R₈, NR₉, O, S, or Se,
R₁, R₂, and R₇ to R₉ are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, or bonded to an adjacent group to form a ring,
L₁ₐ and L₃a are each independently represented by Chemical Formula A-1 above,
L_{3b} is a saturated or unsaturated arylene group having a ring-forming carbon number of 6 to 30, or a saturated or unsaturated heteroarylene group having a ring-forming carbon number of 2 to 30,
Ar₁ₐ and Ar₂ₐ are each independently a saturated or unsaturated aryl group having a ring-forming carbon number of 6 to 30, or a saturated or unsaturated heteroaryl group having a ring-forming carbon number of 2 to 30,
at least one among Ar₁ₐ and Ar₂ₐ is substituted for a saturated or unsaturated cyclohexyl group, a saturated or unsaturated bicycloheptyl group, or a saturated or unsaturated adamantyl group,
n1 is an integer of 0 to 4,
n2 is an integer of 0 to 3, and
Ar₁, Ar₂, and L₁ to L₃ are the same as what is defined with respect to Chemical Formula 1 above.

12. The light-emitting element of claim 1, wherein in Chemical Formula 1 above, Ar₁ is represented by Chemical Formula B-1 below,
L₁ is a direct linkage,
L₂ and L₃ are each independently a saturated or unsaturated phenylene group, and
at least one among L₂ and L₃ is represented by Chemical Formula A-1 above, 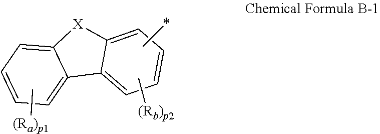
where in Chemical Formula B-1 above,
Rₐ and R_{b} are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30,
p1 is an integer of 0 to 4, and
p2 is an integer of 0 to 3.

13. The light-emitting of claim 1, wherein in Chemical Formula 1 above,
Ar₁ to Ar₃ are each independently a saturated or unsaturated arylamine group, a saturated or unsaturated phenyl group, a saturated or unsaturated biphenyl group, a saturated or unsaturated naphthyl group, or a saturated or unsaturated fluorenyl group, and
at least one among Ar₁ to Ar₃ is substituted for a saturated or unsaturated cyclohexyl group.

14. The light-emitting element of claim 1, wherein the first compound comprises at least one among compounds of Compound Group 1 below,

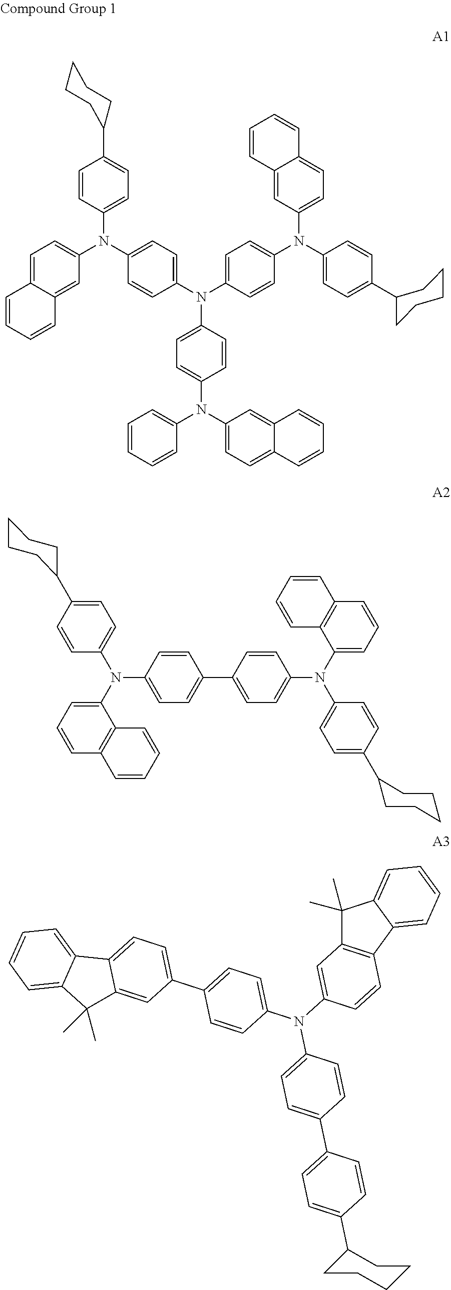 [SMILES: c1ccc(N(c2ccc(N(c3ccc(N(c4ccc(C5CCCCC5)cc4)c4ccc5ccccc5c4)cc3)c3ccc(N(c4ccc(C5CCCCC5)cc4)c4ccc5ccccc5c4)cc3)cc2)c2ccc3ccccc3c2)cc1 ; c1ccc2c(N(c3ccc(-c4ccc(N(c5ccc(C6CCCCC6)cc5)c5cccc6ccccc56)cc4)cc3)c3ccc(C4CCCCC4)cc3)cccc2c1 ; CC1(C)c2ccccc2-c2ccc(-c3ccc(N(c4ccc(-c5ccc(C6CCCCC6)cc5)cc4)c4ccc5c(c4)C(C)(C)c4ccccc4-5)cc3)cc21]

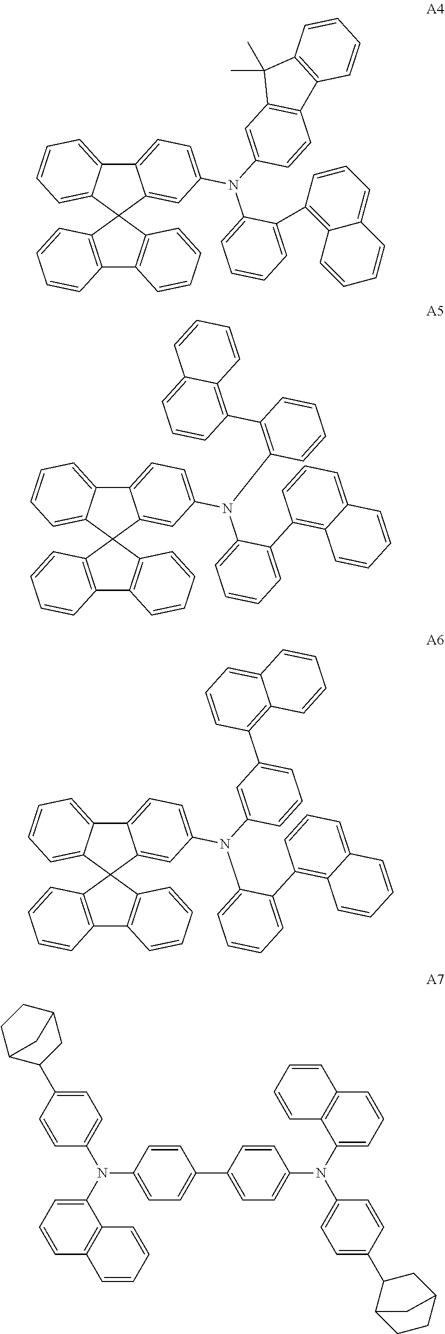

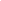

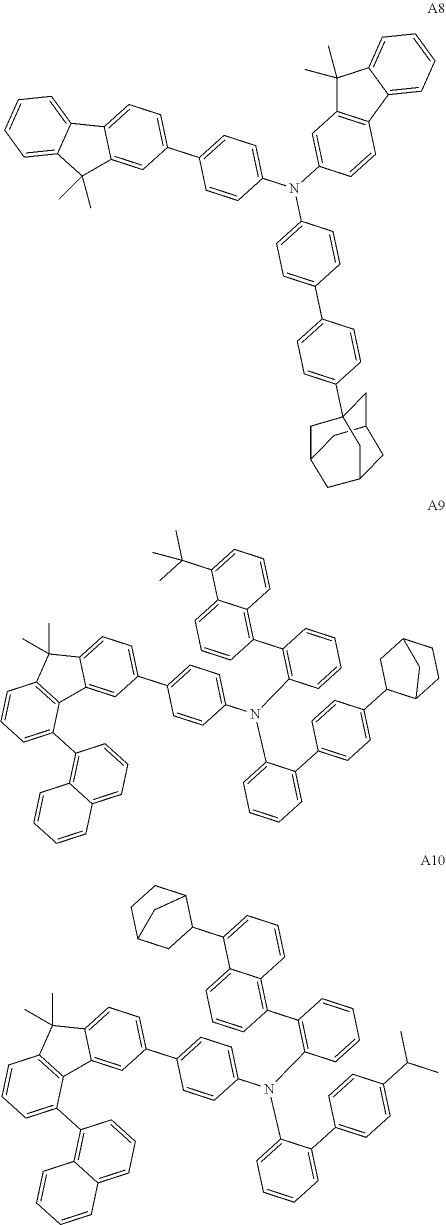 [SMILES: CC1(C)c2ccccc2-c2ccc(-c3ccc(N(c4ccc(-c5ccc(C67CC8CC(CC(C8)C6)C7)cc5)cc4)c4ccc5c(c4)C(C)(C)c4ccccc4-5)cc3)cc21 ; CC(C)(C)c1cccc2c(-c3ccccc3N(c3ccc(-c4ccc5c(c4)-c4c(-c6cccc7ccccc67)cccc4C5(C)C)cc3)c3ccccc3-c3ccc(C4CC5CCC4C5)cc3)cccc12 ; CC(C)c1ccc(-c2ccccc2N(c2ccc(-c3ccc4c(c3)-c3c(-c5cccc6ccccc56)cccc3C4(C)C)cc2)c2ccccc2-c2cccc3c(C4CC5CCC4C5)cccc23)cc1]

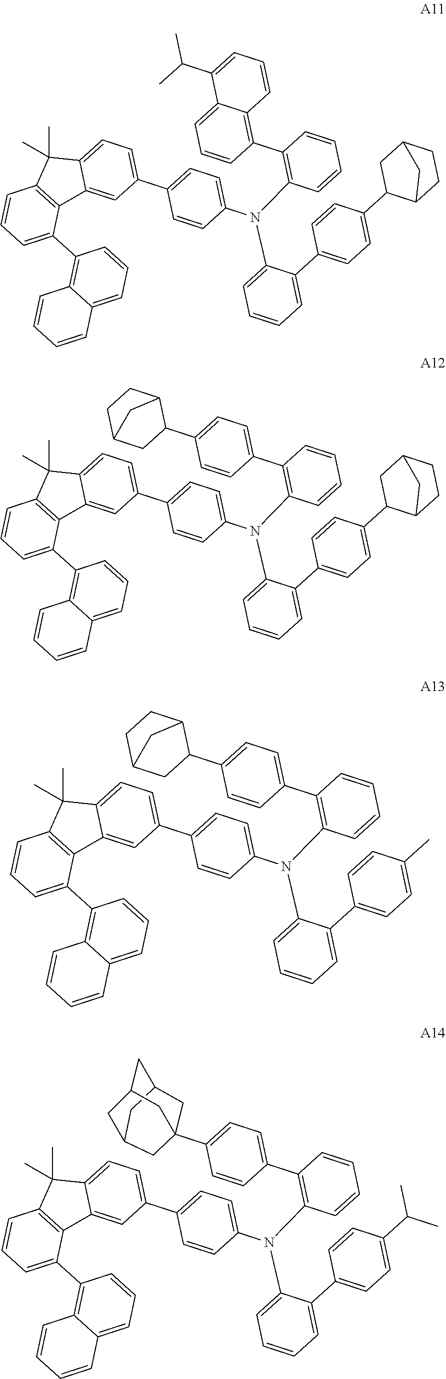 [SMILES: CC(C)c1cccc2c(-c3ccccc3N(c3ccc(-c4ccc5c(c4)-c4c(-c6cccc7ccccc67)cccc4C5(C)C)cc3)c3ccccc3-c3ccc(C4CC5CCC4C5)cc3)cccc12 ; CC1(C)c2ccc(-c3ccc(N(c4ccccc4-c4ccc(C5CC6CCC5C6)cc4)c4ccccc4-c4ccc(C5CC6CCC5C6)cc4)cc3)cc2-c2c(-c3cccc4ccccc34)cccc21 ; Cc1ccc(-c2ccccc2N(c2ccc(-c3ccc4c(c3)-c3c(-c5cccc6ccccc56)cccc3C4(C)C)cc2)c2ccccc2-c2ccc(C3CC4CCC3C4)cc2)cc1 ; CC(C)c1ccc(-c2ccccc2N(c2ccc(-c3ccc4c(c3)-c3c(-c5cccc6ccccc56)cccc3C4(C)C)cc2)c2ccccc2-c2ccc(C34CC5CC(CC(C5)C3)C4)cc2)cc1]

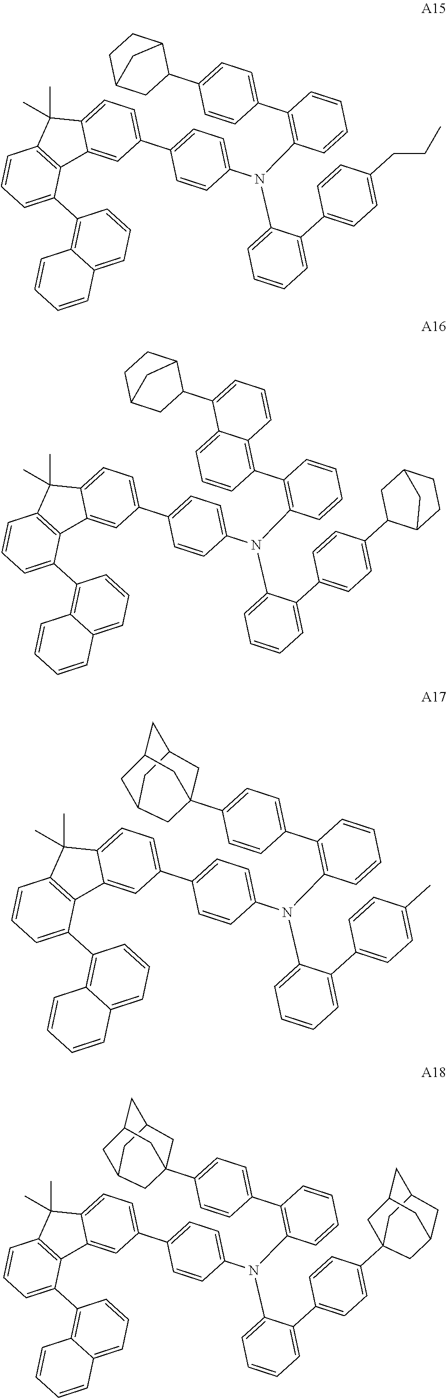 [SMILES: CCCc1ccc(-c2ccccc2N(c2ccc(-c3ccc4c(c3)-c3c(-c5cccc6ccccc56)cccc3C4(C)C)cc2)c2ccccc2-c2ccc(C3CC4CCC3C4)cc2)cc1 ; CC1(C)c2ccc(-c3ccc(N(c4ccccc4-c4ccc(C5CC6CCC5C6)cc4)c4ccccc4-c4cccc5c(C6CC7CCC6C7)cccc45)cc3)cc2-c2c(-c3cccc4ccccc34)cccc21 ; Cc1ccc(-c2ccccc2N(c2ccc(-c3ccc4c(c3)-c3c(-c5cccc6ccccc56)cccc3C4(C)C)cc2)c2ccccc2-c2ccc(C34CC5CC(CC(C5)C3)C4)cc2)cc1 ; CC1(C)c2ccc(-c3ccc(N(c4ccccc4-c4ccc(C56CC7CC(CC(C7)C5)C6)cc4)c4ccccc4-c4ccc(C56CC7CC(CC(C7)C5)C6)cc4)cc3)cc2-c2c(-c3cccc4ccccc34)cccc21]

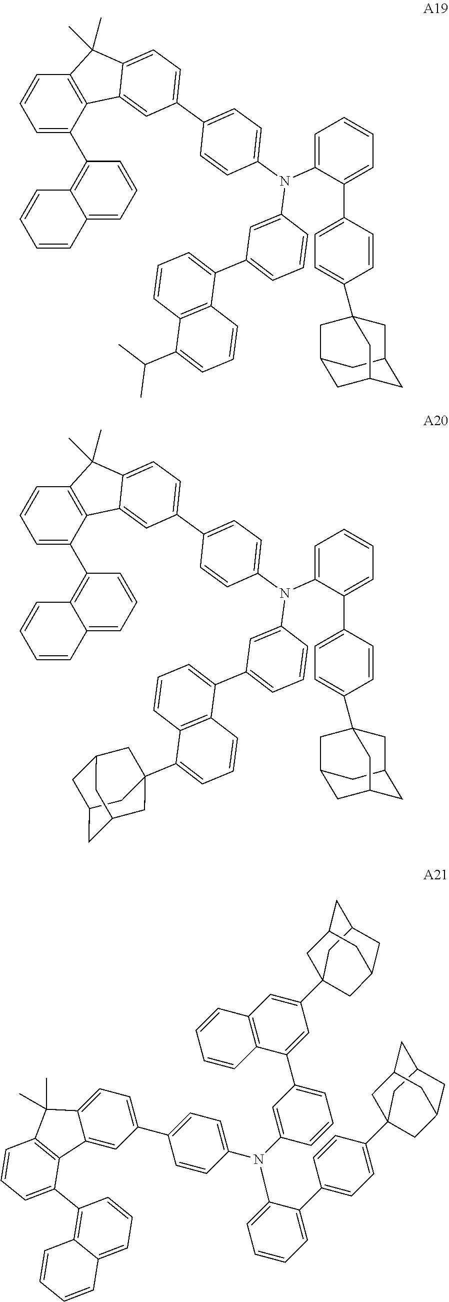 [SMILES: CC(C)c1cccc2c(-c3cccc(N(c4ccc(-c5ccc6c(c5)-c5c(-c7cccc8ccccc78)cccc5C6(C)C)cc4)c4ccccc4-c4ccc(C56CC7CC(CC(C7)C5)C6)cc4)c3)cccc12 ; CC1(C)c2ccc(-c3ccc(N(c4cccc(-c5cccc6c(C78CC9CC(CC(C9)C7)C8)cccc56)c4)c4ccccc4-c4ccc(C56CC7CC(CC(C7)C5)C6)cc4)cc3)cc2-c2c(-c3cccc4ccccc34)cccc21 ; CC1(C)c2ccc(-c3ccc(N(c4cccc(-c5cc(C67CC8CC(CC(C8)C6)C7)cc6ccccc56)c4)c4ccccc4-c4ccc(C56CC7CC(CC(C7)C5)C6)cc4)cc3)cc2-c2c(-c3cccc4ccccc34)cccc21]

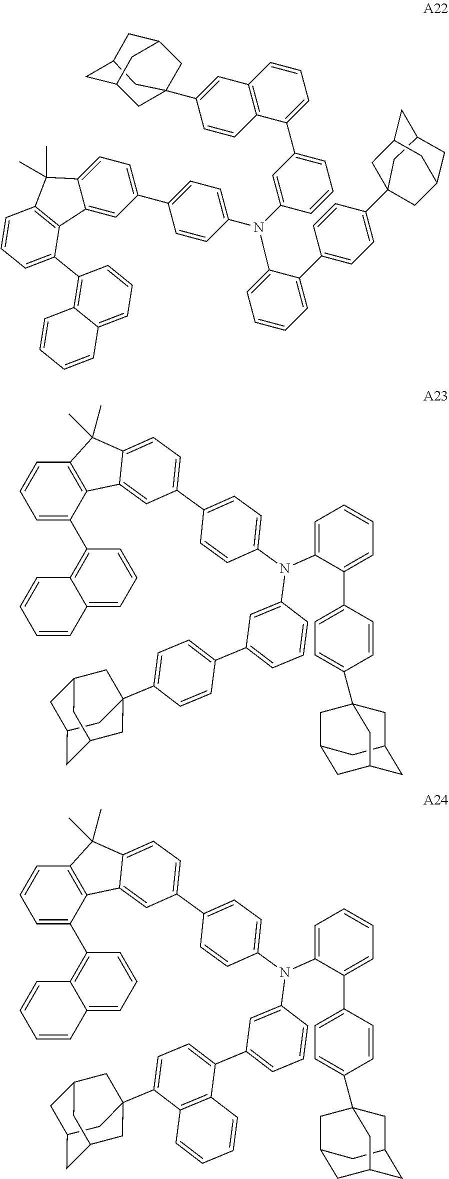

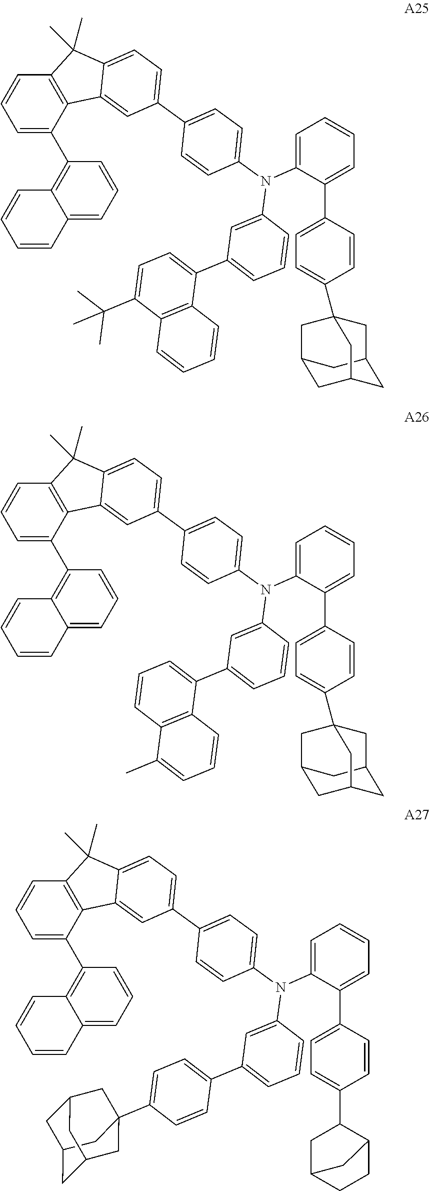 [SMILES: CC(C)(C)c1ccc(-c2cccc(N(c3ccc(-c4ccc5c(c4)-c4c(-c6cccc7ccccc67)cccc4C5(C)C)cc3)c3ccccc3-c3ccc(C45CC6CC(CC(C6)C4)C5)cc3)c2)c2ccccc12 ; Cc1cccc2c(-c3cccc(N(c4ccc(-c5ccc6c(c5)-c5c(-c7cccc8ccccc78)cccc5C6(C)C)cc4)c4ccccc4-c4ccc(C56CC7CC(CC(C7)C5)C6)cc4)c3)cccc12 ; CC1(C)c2ccc(-c3ccc(N(c4cccc(-c5ccc(C67CC8CC(CC(C8)C6)C7)cc5)c4)c4ccccc4-c4ccc(C5CC6CCC5C6)cc4)cc3)cc2-c2c(-c3cccc4ccccc34)cccc21]

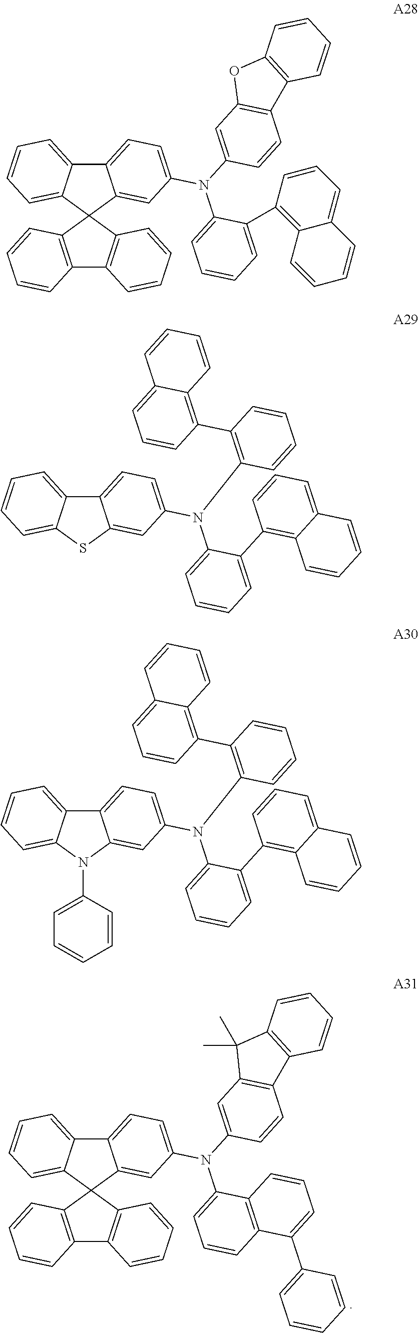

15. A light-emitting element comprising:
a first electrode;
a first hole transport layer on the first electrode;
a second hole transport layer on the first hole transport layer;
a light-emitting layer on the second hole transport layer;
an electron transport region on the light-emitting layer; and
a second electrode on the electron transport region,
wherein the first hole transport layer comprises a first compound having a first refractive index, and a second compound different from the first compound, and having a second refractive index greater than the first refractive index,
the second hole transport layer comprises the second compound,
the first refractive index is about 1.50 to about 1.85 at a wavelength of about 460 nm, and
the second refractive index is about 1.90 to about 2.50 at a wavelength of about 460 nm.

16. The light-emitting element of claim 15, wherein the first compound comprises a core nitrogen atom, a first substituent, a second substituent, and a third substituent, each of the first substituent, the second substituent, and the third substituent being connected to the core nitrogen atom,
the first substituent to the third substituent are each independently a saturated or unsaturated aryl group having a ring-forming carbon number of 6 to 30, or a saturated or unsaturated heteroaryl group having a ring-forming carbon number of 2 to 30,
at least one among the first substituent to the third substituent is substituted for a saturated or unsaturated cycloalkyl group having a carbon number of 3 to 20, or is connected to the core nitrogen atom through a first linker, and
the first linker is a phenylene group represented by Chemical Formula A-1 or Chemical Formula A-2 below, or a saturated or unsaturated naphthylene group, 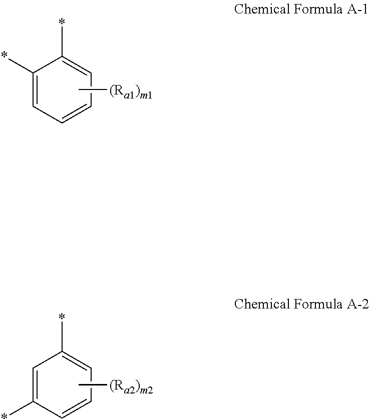
wherein, in Chemical Formula A-1 and Chemical Formula A-2 above,
Rₐ₁ and Rₐ₂ are each independently a hydrogen atom, a deuterium atom, a halogen atom, a saturated or unsaturated alkyl group having a carbon number of 1 to 20, a saturated or unsaturated aryl group having a ring-forming carbon number of 6 to 30, or a saturated or unsaturated heteroaryl group having a ring-forming carbon number of 2 to 30, and
m1 and m2 are each independently an integer of 0 to 4.

17. The light-emitting element of claim 16, wherein the first substituent is directly bonded to the core nitrogen atom,
at least one among the second substituent and the third substituent is connected to the core nitrogen atom through the first linker, and
the first linker is represented by Chemical Formula A-1 above.

18. The light-emitting element of claim 15, wherein the first compound comprises, in a molecular structure thereof, 1 to 5 of at least one substituent selected from a saturated or unsaturated cyclohexyl group, a saturated or unsaturated bicyclohexyl group, and a saturated or unsaturated adamantyl group.

19. The light-emitting element of claim 15, wherein the first compound is represented by Chemical Formula 1 below, and
the second compound is represented by Chemical Formula 2-1 or Chemical Formula 2-2 below, 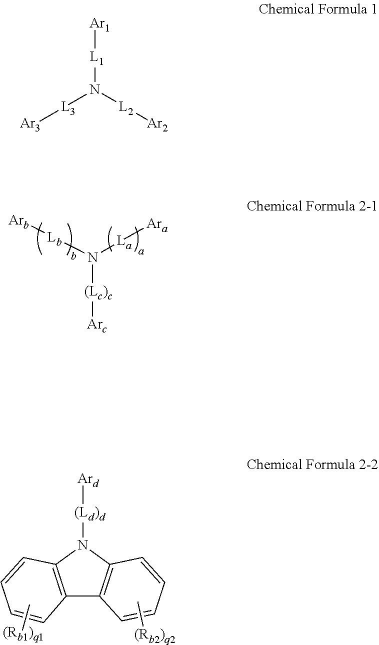
where in Chemical Formula 1, Chemical Formula 2-1, and Chemical Formula 2-2 above,
Ar₁ to Ar₃, and Arₐ to Ar_{c} are each independently a substituted or unsubstituted amine group, a substituted or unsubstituted aryl group having a ring-forming carbon number of 6 to 30, or a substituted or unsubstituted heteroaryl group having a ring-forming carbon number of 2 to 30,
Ar_{d} is a substituted or unsubstituted aryl group having a ring-forming carbon number of 6 to 30, or a substituted or unsubstituted heteroaryl group having a ring-forming carbon number of 2 to 30,
R_{b1} and R_{b2} are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or bonded to an adjacent group to form a ring,
q1 and q2 are each independently an integer of 0 to 4,
L₁ to L₃, and Lₐ to L_{d} are each independently a direct linkage, a substituted or unsubstituted arylene group having a ring-forming carbon number of 6 to 30, or a substituted or unsubstituted heteroarylene group having a ring-forming carbon number of 2 to 30,
a to d are each independently an integer of 0 to 10,
in Chemical Formula 1 above, at least one among L₁ to L₃ is a phenylene group represented by Chemical Formula A-1 below, or Chemical Formula A-2 below, or a substituted or unsubstituted divalent naphthyl group, or at least one among Ar₁ to Ar₃ is substituted for a substituted or unsubstituted cycloalkyl group having a carbon number of 3 to 20, 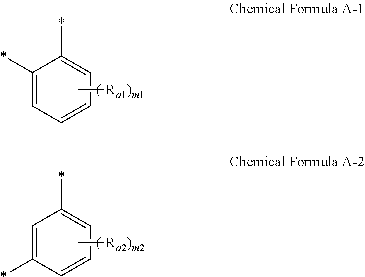
where in Chemical Formula A-1 and Chemical Formula A-2 above,
Rₐ₁ and Rₐ₂ are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
m1 and m2 are each independently an integer of 0 to 4.

20. A display device comprising:
a base layer comprising a plurality of light-emitting regions, and a non-light-emitting region adjacent to the plurality of light-emitting regions; and
a plurality of light-emitting elements on the base layer, and respectively corresponding to the plurality of light-emitting regions,
wherein at least some of the plurality of light-emitting elements comprises:
a first electrode;
a hole transport region on the first electrode;
a light-emitting layer on the hole transport region;
an electron transport region on the light-emitting layer; and
a second electrode on the electron transport region,
the hole transport region comprises:
a first hole transport layer between the first electrode and the light-emitting layer, and comprising a first compound represented by Chemical Formula 1 below, and a second compound different from the first compound and represented by Chemical Formula 2-1 or Chemical Formula 2-2 below; and
a second hole transport layer between the first hole transport layer and the light-emitting layer, and comprising the second compound, 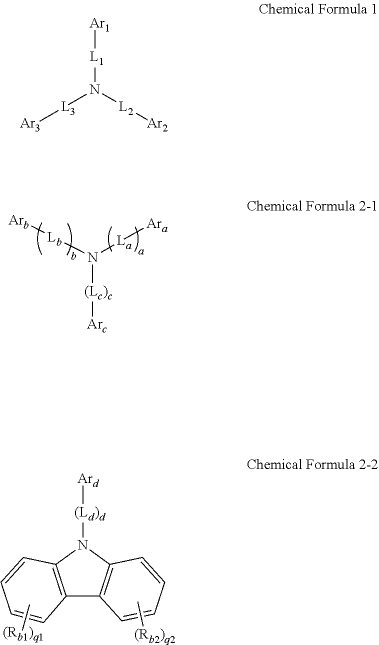
where in Chemical Formula 1, Chemical Formula 2-1, and Chemical Formula 2-2 above,
Ar₁ to Ar₃, and Arₐ to Ar_{c} are each independently a substituted or unsubstituted amine group, a substituted or unsubstituted aryl group having a ring-forming carbon number of 6 to 30, or a substituted or unsubstituted heteroaryl group having a ring-forming carbon number of 2 to 30,
Ar_{d} is a substituted or unsubstituted aryl group having a ring-forming carbon number of 6 to 30, or a substituted or unsubstituted heteroaryl group having a ring-forming carbon number of 2 to 30,
R_{b1} and R_{b2} are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, or bonded to an adjacent group to form a ring,
q1 and q2 are each independently an integer of 0 to 4,
L₁ to L₃, and Lₐ to L_{d} are each independently a direct linkage, a substituted or unsubstituted arylene group having a ring-forming carbon number of 6 to 30, or a substituted or unsubstituted heteroarylene group having a ring-forming carbon number of 2 to 30,
a to d are each independently an integer of 0 to 10,
in Chemical Formula 1 above, at least one among L₁ to L₃ is a phenylene group represented by Chemical Formula A-1 below, or Chemical Formula A-2 below, or a substituted or unsubstituted divalent naphthyl group, or at least one among Ar₁ to Ar₃ is substituted for a substituted or unsubstituted cycloalkyl group having a carbon number of 3 to 20, 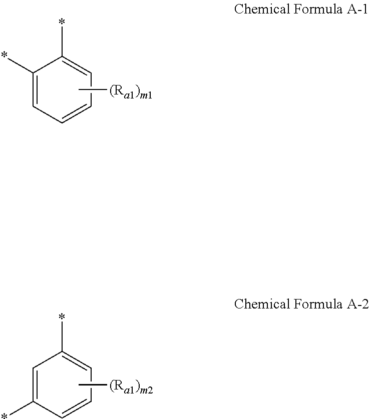
where in Chemical Formula A-1 and Chemical Formula A-2 above,
Rₐ₁ and Rₐ₂ are each independently a hydrogen atom, a deuterium atom, a halogen atom, a substituted or unsubstituted alkyl group having a carbon number of 1 to 20, a substituted or unsubstituted aryl group having a ring-forming carbon number of 6 to 30, or a substituted or unsubstituted heteroaryl group having a ring-forming carbon number of 2 to 30, and
m1 and m2 are each independently an integer of 0 to 4.
